(19) United States
(12) Patent Application Publication
(10) Pub. No.: US 2012/0007165 A1
(43) Pub. Date: Jan. 12, 2012

(54) SEMICONDUCTOR DEVICES

(75) Inventors: Myoung-Bum LEE, Seoul (KR); Jae-Hwang SIM, Seoul (KR); In-Sun PARK, Seoul (KR); Jin-Gi HONG, Yongin-si (KR); Ju-Seon GOO, Suwon-si (KR); Seung-Bae PARK, Yongin-si (KR); Seung-Yup LEE, Seongnam-si (KR); Du-Heon SONG, Seongnam-si (KR); Jeong-Dong CHOE, Anyang-si (KR); Seok-Won LEE, Yongin-si (KR)

(73) Assignee: Samsung Electronics Co., Ltd.

(21) Appl. No.: 13/181,281

(22) Filed: Jul. 12, 2011

(30) Foreign Application Priority Data
Jul. 12, 2010 (KR) 10-2010-0066772
Sep. 9, 2010 (KR) 10-2010-0088199

(51) Int. Cl. H01L 29/788; H01L 27/088

(52) U.S. Cl. 257/316; 257/390; 257/E29.3; 257/E27.06

(57) ABSTRACT

A semiconductor device includes a substrate, a plurality of gate structures, a first insulating interlayer pattern, and a second insulation layer pattern. The substrate has an active region and a field region, each of the active region and the field region extends in a first direction, and the active region and the field region are alternately and repeatedly arranged in a second direction substantially perpendicular to the first direction. The gate structures are spaced apart from each other in the first direction, each of the gate structures extends in the second direction. The first insulation layer pattern is formed on a portion of a sidewall of each gate structure. The second insulation layer pattern covers the gate structures and the first insulation layer pattern, and has an air tunnel between the gate structures, the air tunnel extending in the second direction.

### CLAIM OF PRIORITY

This application claims priority under 35 USC § 119 to Korean Patent Application No. 10-2010-0066772 filed on Jul. 12, 2010 and No. 10-2010-0088199 filed on Sep. 9, 2010 in the Korean Intellectual Property Office (KIPO), the contents of which are herein incorporated by reference in their entirety.

### BACKGROUND

1. Field

Example embodiments relate to semiconductor devices and methods of manufacturing semiconductor devices. More particularly, example embodiments relate to semiconductor devices having air gaps and methods of manufacturing semiconductor devices having air gaps.

2. Description of the Related Art

As semiconductor devices have become more highly integrated, a threshold voltage may be changed due to the parasitic capacitance between word lines. Thus, a method of manufacturing a semiconductor device in which the parasitic capacitance may be reduced may be desired, and a method of forming an air gap between word lines has been developed. However, a method of forming an air gap effectively at a desired position has not been developed. Particularly, a process for forming air gaps in a semiconductor device having different densities of gate structures is not easily performed.

### SUMMARY

Example embodiments provide a semiconductor device including an air gap having a desired size.

Example embodiments provide a method of manufacturing a semiconductor device including an air gap having a desired size.

Example embodiments provide a semiconductor device including air gaps having a desired size at regions in which the density of gate structures is different.

Example embodiments provide a method of manufacturing a semiconductor device including air gaps having a desired size at regions in which the density of gate structures is different.

According to example embodiments, there is provided a semiconductor device. The semiconductor device includes a substrate, a plurality of gate structures, a first insulating interlayer pattern, and a second insulation layer pattern. The substrate has an active region and a field region, each of the active region and the field region extends in a first direction, and the active region and the field region are alternately and repeatedly arranged in a second direction substantially perpendicular to the first direction. The gate structures are spaced apart from each other in the first direction, each of the gate structures extends in the second direction. The first insulation layer pattern is formed on a portion of a sidewall of each gate structure. The second insulation layer pattern covers the gate structures and the first insulation layer pattern, and has an air tunnel between the gate structures, the air tunnel extending in the second direction.

In example embodiments, the air tunnel may have a top surface higher than those of the gate structures.

In example embodiments, the first insulation layer pattern may be formed also on a top surface of the substrate between the gate structures.

In example embodiments, each gate structure may include a tunnel insulation layer pattern, a floating gate, a dielectric layer pattern and a control gate sequentially stacked on the substrate. The tunnel insulation layer patterns may have an island shape from each other in the active region, and the floating gates may also have an island shape from each other in the active region. Each of the dielectric layer patterns and the control gates may extend in the second direction and may be formed on the floating gates and the field region.

In example embodiments, the control gates may include polysilicon, and the first insulation layer pattern may cover at least a sidewall of the tunnel insulation layer pattern, a sidewall of the floating gate and a sidewall of the dielectric layer pattern.

In example embodiments, each control gate may include a lower conductive pattern and an upper conductive pattern sequentially stacked on the dielectric layer pattern, and the lower and upper conductive patterns may include polysilicon and a metal silicide, respectively.

In example embodiments, the upper conductive pattern may have a bottom surface substantially coplanar with a top surface of the first insulation layer pattern.

In example embodiments, the upper conductive pattern may include cobalt.

In example embodiments, the upper conductive pattern may have a bottom surface lower than a top surface of the first insulation layer pattern.

In example embodiments, the upper conductive pattern may include nickel.

In example embodiments, each gate structure may include a first tunnel insulation layer pattern, a floating gate, a dielectric layer pattern and a control gate sequentially stacked on the substrate. The first tunnel insulation layer patterns may have an island shape from each other in the active region, and the floating gates may also have an island shape from each other in the active region. Each of the dielectric layer patterns and the control gates may extend in the second direction and may be formed on the floating gates and the field region. The semiconductor device may further include a second tunnel insulation layer pattern on a portion of the active region that is not covered by the gate structures. The second tunnel insulation layer pattern may be covered by the second insulation layer pattern and connected to the first tunnel insulation layer pattern.

In example embodiments, the first and second tunnel insulation layer patterns may include substantially the same material, and the first tunnel insulation layer pattern may have a thickness greater than that of the second tunnel insulation layer pattern.

In example embodiments, each gate structure may include a tunnel insulation layer pattern, a charge trapping layer pattern, a blocking layer pattern and a gate electrode sequentially stacked on the substrate, and the gate electrodes may include polysilicon. The first insulation layer pattern may cover at least a sidewall of the tunnel insulation layer pattern, a sidewall of the charge trapping layer pattern and a sidewall of the blocking layer pattern.

In example embodiments, the air tunnel may be defined only by the second insulation layer pattern.

In example embodiments, the second insulation layer pattern may partially cover the first insulation layer pattern, and the air tunnel may be defined by both of the first and second insulation layer patterns.

According to example embodiments, there is provided a semiconductor device. The semiconductor device includes a plurality of gate structures, a first insulation layer pattern and a second insulation layer pattern. The gate structures are spaced apart from each other on a substrate. The first insulation layer pattern is formed on a portion of a sidewall of each gate structure. The second insulation layer pattern covers the gate structures and the first insulation layer pattern, and has an air gap between the gate structures. The air gap includes a lower portion and an upper portion. The lower portion has a first width and being adjacent to the first insulation layer pattern, and the upper portion has a second width greater than the first width and is adjacent to a portion of the sidewall of each gate structure that is not covered by the first insulation layer pattern.

In example embodiments, the lower portion of the air gap may have a linear shape, and the upper portion of the air gap may have an oval shape of which a top surface is sharp.

In example embodiments, the air gap may have a top surface higher than that of the gate structures.

In example embodiments, the first insulation layer pattern may be further formed on a portion of the substrate between the gate structures.

In example embodiments, each gate structure may include a tunnel insulation layer pattern, a floating gate, a dielectric layer pattern and a control gate sequentially stacked on the substrate, the control gate including polysilicon. The first insulation layer pattern may cover at least a sidewall of the tunnel insulation layer pattern, a sidewall of the floating gate and a sidewall of the dielectric layer pattern.

In example embodiments, each control gate may include a lower conductive pattern and an upper conductive pattern sequentially stacked on the dielectric layer pattern, and the lower and upper conductive patterns may include polysilicon and a metal silicide, respectively.

In example embodiments, the upper conductive pattern may have a bottom surface substantially coplanar with a top surface of the first insulation layer pattern, and the upper conductive pattern may include cobalt.

In example embodiments, the upper conductive pattern may have a bottom surface lower than a top surface of the first insulation layer pattern, and the upper conductive pattern includes nickel.

In example embodiments, each gate structure may include a first tunnel insulation layer pattern, a floating gate, a dielectric layer pattern and a control gate sequentially stacked on the substrate. The semiconductor device may further include a second tunnel insulation layer pattern on a portion of the substrate that is not covered by the gate structures. The second tunnel insulation layer pattern may be covered by the second insulation layer pattern and have a thickness less than that of the first tunnel insulation layer pattern.

In example embodiments, the air gap may be defined only by the second insulation layer pattern.

In example embodiments, the second insulation layer pattern partially may cover the first insulation layer pattern, and the air tunnel may be defined by both of the first and second insulation layer patterns.

According to example embodiments, there is provided a semiconductor device. The semiconductor device includes a plurality of first gate structures, a second gate structure, a third gate structure, a first insulation layer pattern, and a second insulation layer pattern. The first gate structures are spaced apart from each other on a substrate in a first direction at a first distance therebetween. The second gate structure are spaced apart from a first outermost of the first gate structures in the first direction at a second distance. The third gate structure is spaced apart from a second outermost of the first gate structures in a second direction opposite to the first direction at a third distance. The first insulation layer pattern is formed on a portion of each of the first, second and third gate structures. The second insulation layer pattern covers the first, second and third gate structures and the first insulation layer pattern, and has a second air gap between the first outermost of the first gate structures and the second gate structure or between the second outermost of the first gate structures and the third gate structures.

In example embodiments, the second and third distances may be greater than the first distance, and wherein the first air gap may have a width equal to or greater than that of the second air gap.

In example embodiments, the first air gap may have a lower portion and an upper portion. The lower portion may have a first width and be adjacent to the first insulation layer pattern, and the upper portion may have a second width greater than the first width and be adjacent to portions of sidewalls of the first through third gate structures that are not covered by the first insulation layer pattern.

In example embodiments, the lower potion of the first air gap may have a linear shape, and the upper portion of the first air gap may have an oval shape of which a top surface is sharp.

In example embodiments, the second insulation layer pattern may include Middle temperature oxide (MTO).

According to example embodiments, there is provided a method of manufacturing a semiconductor device. In the method, a plurality of gate structures spaced apart from each other is formed on a substrate. A first insulation layer pattern is formed on portions of sidewalls of the gate structures. A conductive layer is formed on portions of the gate structures that are not covered by the first insulation layer pattern. The conductive layer is reacted with the gate structures. A portion of the conductive layer that is not reacted with the gate structures is removed. A second insulation layer is formed on the substrate to form an air gap between the gate structures.

In example embodiments, the air gap may be formed to have a top surface higher than those of the gate structures.

In example embodiments, when he first insulation layer pattern is formed, a first insulation layer covering the gate structures may be formed on the substrate, a sacrificial layer filing spaces between the gate structures may be formed on the first insulation layer, upper portions of the sacrificial layer and the first insulation layer may be removed to form a sacrificial layer pattern and a first insulation layer pattern, respectively, and the sacrificial layer pattern may be removed.

In example embodiments, each gate structure may include a tunnel insulation layer pattern, a floating gate, a dielectric layer pattern and a control gate sequentially stacked on the substrate. The first insulation layer pattern may cover at least a sidewall of the tunnel insulation layer pattern, a sidewall of the floating gate and a sidewall of the dielectric layer pattern.

In example embodiments, the conductive layer may be formed using a metal, and the conductive layer may be reacted with the gate structures to form a metal silicide layer.

In example embodiments, the metal silicide layer may be formed to have a bottom surface lower than a top surface of the first insulation layer pattern.

In example embodiments, each gate structure may include a tunnel insulation layer pattern, a charge trapping layer pattern, a blocking layer pattern and a gate electrode sequentially stacked on the substrate, and the gate electrodes include polysilicon. The first insulation layer pattern may cover at least a sidewall of the tunnel insulation layer pattern, a sidewall of the charge trapping layer pattern and a sidewall of the blocking layer pattern.

According to example embodiments, there is provided a method of manufacturing a semiconductor device. In the method, a plurality of gate structures including silicon spaced apart from each other is formed on a substrate. A reaction prevention layer is formed on portions of sidewalls of the gate structures. A metal layer is formed on portions of the gate structures that are not covered by the reaction prevention layer. The metal layer is reacted with the gate structures to form a metal silicide layer. A portion of the metal layer that is not reacted with the gate structures is removed. An insulation layer is formed on the substrate to form an air gap between the gate structures. The air gap has a top surface higher than those of the gate structures.

According to example embodiments, there is provided a semiconductor device. The semiconductor device includes a plurality of first gate structures, a second gate structure, a first insulation layer pattern, a second insulation layer pattern, and a third insulation layer pattern. The plurality of first gate structures is in a first region on a substrate, and each of the gate structures has an upper portion including a metal silicide. The second gate structure is in a second region on the substrate, and the second gate structure has an upper portion including a metal silicide. The first insulation layer pattern is formed on a portion of a sidewall of each gate structure. The second insulation layer pattern covers a sidewall of the second gate structure, and the second insulation layer pattern has a top surface higher than that of the first insulation layer pattern. The third insulation layer pattern covers the first and second gate structures and the first and second insulation layer patterns, and the third insulation layer pattern has an air gap between the first gate structures.

In example embodiments, the first and second insulation layer patterns may be further formed on a portion of the substrate adjacent to the first and second gate structures.

In example embodiments, the second insulation layer pattern may further cover a portion of the second gate structure.

In example embodiments, each first gate structure may include a first tunnel insulation layer pattern, a first floating gate, a first dielectric layer pattern and a first control gate sequentially stacked on the substrate. The second gate structure may include a second tunnel insulation layer pattern, a second floating gate, a second dielectric layer pattern, a second control gate and a gate mask sequentially stacked on the substrate. The gate mask may be formed on a portion of the second control gate, and the second insulation layer pattern may cover a top surface of the gate mask.

In example embodiments, the first control gate may include a first lower conductive pattern and an upper conductive pattern sequentially stacked on the first dielectric layer pattern, and the second control gate may include a second lower conductive pattern and an upper conductive pattern sequentially stacked on the second dielectric layer pattern.

In example embodiments, the first and second conductive patterns may include polysilicon, and the first and second upper conductive patterns may include a metal silicide.

In example embodiments, the second conductive pattern may not be covered by the gate mask and the second insulation layer pattern.

In example embodiments, the second insulation layer pattern may have a top surface higher than that of the second gate structure.

In example embodiments, each first gate structure may include a first tunnel insulation layer pattern, a first floating gate, a first dielectric layer pattern and a first control gate sequentially stacked on the substrate, and the second gate structure may include a second tunnel insulation layer pattern, a second floating gate, a second dielectric layer pattern and a second control gate sequentially stacked on the substrate. The first control gate may include a first lower conductive pattern and a second upper conductive pattern sequentially stacked on the first dielectric layer pattern, and the second control gate may include a second lower conductive pattern and a second upper conductive pattern sequentially stacked on the second dielectric layer pattern. The first and second upper conductive patterns may include the metal silicide, and the second upper conductive pattern may have a thickness less than that of the first conductive pattern.

In example embodiments, the first region may be a cell region and the second region may be a peripheral circuit region.

According to example embodiments, there is provided a semiconductor device. The semiconductor device includes a plurality of first gate structures, a second gate structure, a first insulation layer pattern, a second insulation layer pattern, and a third insulation layer pattern. The plurality of first gate structures are formed in a first region on a substrate, and each of the gate structures has an upper portion including a metal silicide. The second gate structure is formed in a second region on the substrate, and the second gate structure has an upper portion including a metal silicide and has a sidewall slanted to a top surface of the substrate. The first insulation layer pattern is formed on a portion of a sidewall of each gate structure. The second insulation layer pattern covers a portion of the sidewall of the second gate structure, and the second insulation layer pattern has a top surface higher than that of the first insulation layer pattern. The third insulation layer pattern covers the first and second gate structures and the first and second insulation layer patterns, the third insulation layer pattern has an air gap between the first gate structures.

In example embodiments, the second insulation layer pattern may have a top surface lower than that of the first insulation layer pattern.

In example embodiments, each first gate structure may include a first tunnel insulation layer pattern, a first floating gate, a first dielectric layer pattern and a first control gate sequentially stacked on the substrate, and the second gate structure may include a second tunnel insulation layer pattern, a second floating gate, a second dielectric layer pattern and a second control gate sequentially stacked on the substrate. The second insulation layer pattern may have a top surface higher than that of the second dielectric layer pattern.

According to example embodiments, there is provided a semiconductor device. The semiconductor device includes a plurality of first gate structures, a second gate structure, a third gate structure, a fourth gate structure, a first insulation layer pattern, a second insulation layer pattern, a third insulation layer pattern, and a fourth insulation layer pattern. The plurality of first gate structures, the second gate structure and the third gate structure are formed on a substrate in a cell region. The first gate structures are formed between the second and third gate structures, and each of the first through third gate structures has an upper portion including a metal silicide. The fourth gate structure is formed on the substrate in a peripheral circuit region, and includes the metal silicide. The first insulation layer pattern covers a portion of a sidewall of each gate structure and a portion of a first sidewall of each of the second and third gate structures. The second insulation layer pattern covers a second sidewall of each of the second and third gate structures, and the second insulation layer pattern has a top surface higher than that of the first insulation layer pattern. The third insulation layer pattern covers a sidewall of the fourth gate structure, and the third insulation layer pattern has a top surface higher than that of the first insulation layer pattern. The fourth insulation layer pattern covers the first through fourth gate structures and the first through third insulation layer patterns, and the fourth insulation layer pattern has an air gap between the first through third gate structures.

In example embodiments, the second and third insulation layer patterns may have a top surface substantially coplanar with each other.

In example embodiments, the second and third insulation layer patterns may further cover top surfaces of the second and third gate structures, respectively, and the fourth insulation layer pattern may further cover a portion of a top surface of the fourth gate structure.

In example embodiments, the second through fourth insulation layer patterns may have top surfaces higher than that of the fourth gate structure.

According to example embodiments, there is provided a method of manufacturing a semiconductor device. In the method, a plurality of gate structures and a second gate structure are formed in a first region and a second region, respectively, on a substrate. A first insulation layer pattern covering a portion of a sidewall of each gate structure and a second insulation layer pattern covering the second gate structure are formed. The second insulation layer pattern has a top surface higher than that of the first insulation layer pattern. A conductive layer is reacted with portions of the gate structures that are not covered by the first and second insulation layer patterns. A third insulation layer is formed on the substrate to form an air gap between the first gate structures.

In example embodiments, when the first and second insulation layer patterns are formed, a first insulation layer and a sacrificial layer covering the first and second gate structures may be sequentially formed on the substrate. A mask partially overlapping a lateral portion of the second gate structure may be formed on the sacrificial layer. Upper portions of the sacrificial layer and the first insulation layer may be removed using the mask as an etching mask to form a first sacrificial layer pattern and a first insulation layer pattern in the first region and a second sacrificial layer pattern and a second insulation layer pattern in the second region.

In example embodiments, the second insulation layer pattern may cover a portion of a top surface of the second gate structure.

According to example embodiments, there is provided a method of manufacturing a semiconductor device. In the method, second and third gate structures and a plurality of first gate structures therebetween are formed in a cell region on a substrate and a fourth gate structure is formed in a peripheral circuit region on the substrate. First, second and third insulation layer patterns are formed. The first insulation layer pattern covers a portion of a sidewall of each gate structure and a portion of a first sidewall of each of the second and third gate structures, the second insulation layer pattern covers a second sidewall of each of the second and third gate structures and has a top surface higher than that of the first insulation layer pattern, and the third insulation layer pattern covers a sidewall of the fourth gate structure and has a top surface higher than that of the first insulation layer pattern. A conductive layer is reacted with portions of the gate structures that are not covered by the insulation layer patterns. A fourth insulation layer pattern is formed on the substrate to form an air gap between the first through third gate structures.

According to example embodiments, a reaction prevention layer is formed on a portion of a sidewall of each of a plurality of gate structures spaced apart from each other, and a conductive layer is formed on portions of the gate structure that are not covered by the reaction prevention layer. The conductive layer may be reacted with the gate structures, e.g., by a heat treatment, to form a control gate having a low resistance. An insulation layer having an air gap between the gate structures may be formed by a process for forming a layer having low step coverage, so that the parasitic capacitance may be reduced. The air gap may be uniformly formed and may have a top surface higher than those of the gate structures.

Particularly, in a method of manufacturing a semiconductor device having different gate structure density at different regions, a mask may be formed on a sacrificial layer before removing the sacrificial layer and the insulation layer, and thus the sacrificial layer and the insulation layer may be prevented from being over-etched in a region having a low density of the gate structure by a loading effect. Thus, a control gate and a floating gate or a control gate and a source/drain region may be prevented from being electrically connected via a metal silicide layer, and the semiconductor device may have stable electrical characteristics.

### BRIEF DESCRIPTION OF THE DRAWINGS

Example embodiments will be more clearly understood from the following detailed description taken in conjunction with the accompanying drawings. FIGS. 1 to 66 represent non-limiting, example embodiments as described herein.

FIGS. 1 to 10 are cross-sectional views illustrating a method of manufacturing a semiconductor device in accordance with example embodiments, and

FIGS. 11 to 20 are top views illustrating the method of manufacturing the semiconductor device;

FIGS. 21 to 24 are cross-sectional views illustrating some semiconductor devices manufactured by the above processes;

FIGS. 25 to 36 are cross-sectional views illustrating a method of manufacturing a semiconductor device in accordance with other example embodiments, and

FIGS. 37 to 48 are top views illustrating the method of manufacturing the semiconductor device;

FIGS. 49 to 54 are cross-sectional views illustrating a method of manufacturing a semiconductor device in accordance with still other example embodiments;

FIGS. 55 to 59 are cross-sectional views illustrating a method of manufacturing a semiconductor device in accordance with still other example embodiments;

FIGS. 60 to 64 are cross-sectional views illustrating a method of manufacturing a semiconductor device in accordance with still other example embodiments;

FIG. 65 is a cross-sectional view illustrating a method of manufacturing a semiconductor device in accordance with still other example embodiments; and

FIG. 66 is a cross-sectional view illustrating a method of manufacturing a semiconductor device in accordance with still other example embodiments.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout the description. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Hereinafter, example embodiments will be explained in detail with reference to the accompanying drawings.

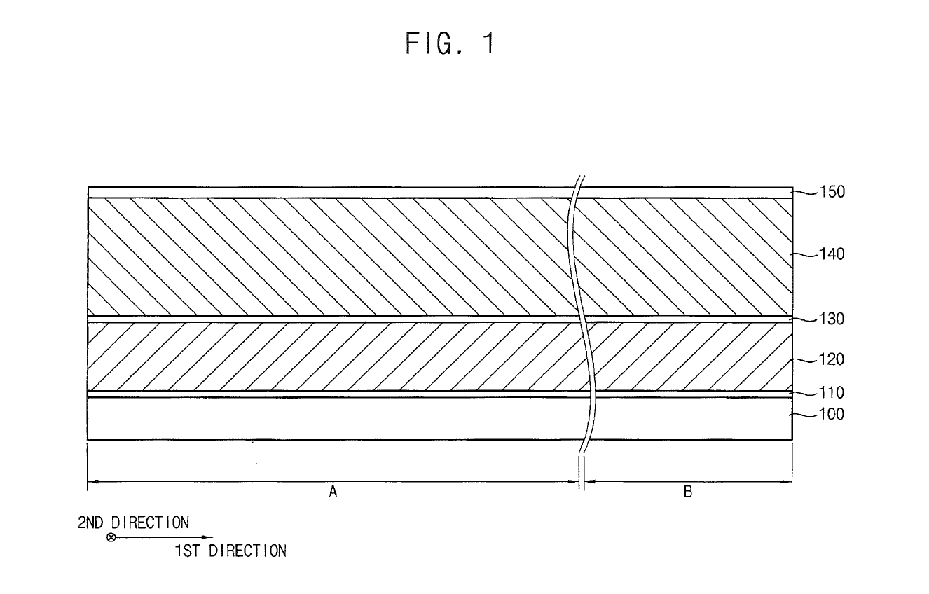

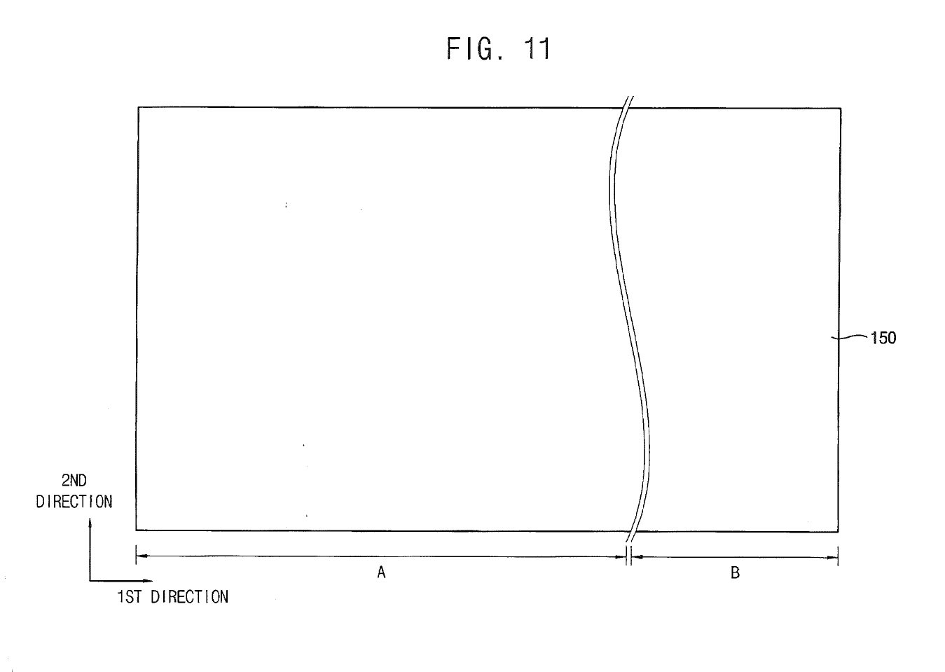

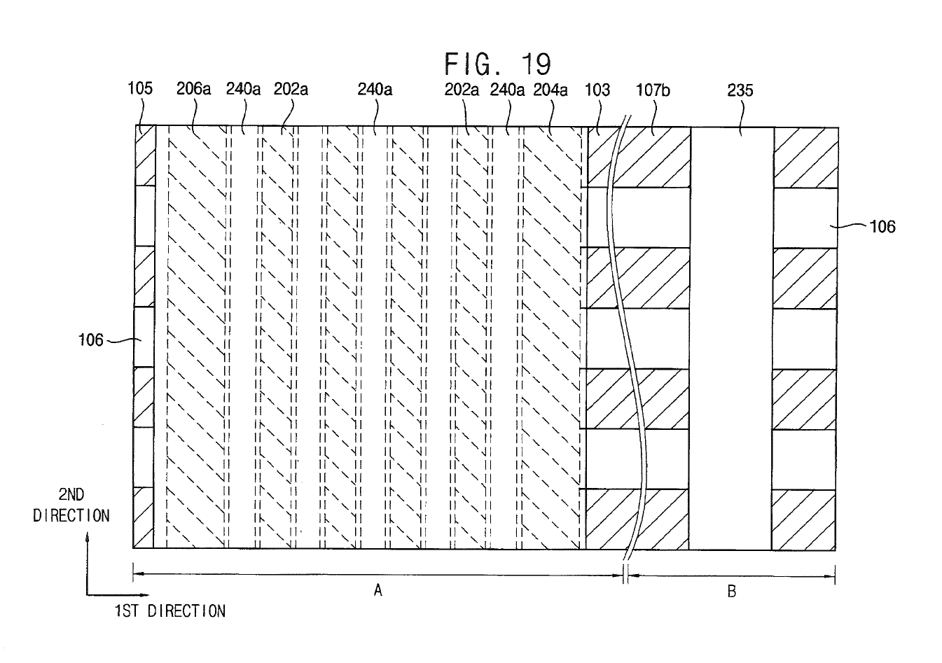

FIGS. 1 to 10 are cross-sectional views illustrating a method of manufacturing a semiconductor device in accordance with example embodiments, and FIGS. 11 to 20 are top views illustrating the method of manufacturing the semiconductor device.

Referring to FIGS. 1 and 11, a tunnel insulation layer 110, a floating gate layer 120, a dielectric layer 130, a control gate layer 140 and a gate mask layer 150 may be sequentially formed on a substrate 100.

The substrate 100 may be a semiconductor substrate, e.g., a silicon substrate, a germanium substrate or a silicon-germanium substrate, a silicon-on-insulator (SOI) substrate, a germanium-on-insulator (GOI) substrate, etc. The substrate 100 may further include a well region (not shown) doped with p-type or n-type impurities.

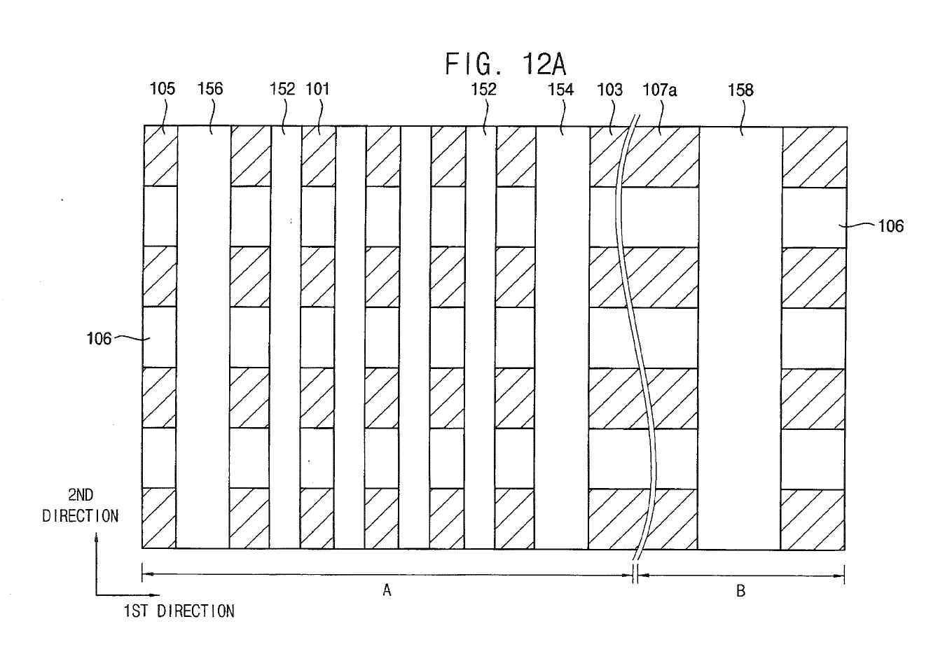

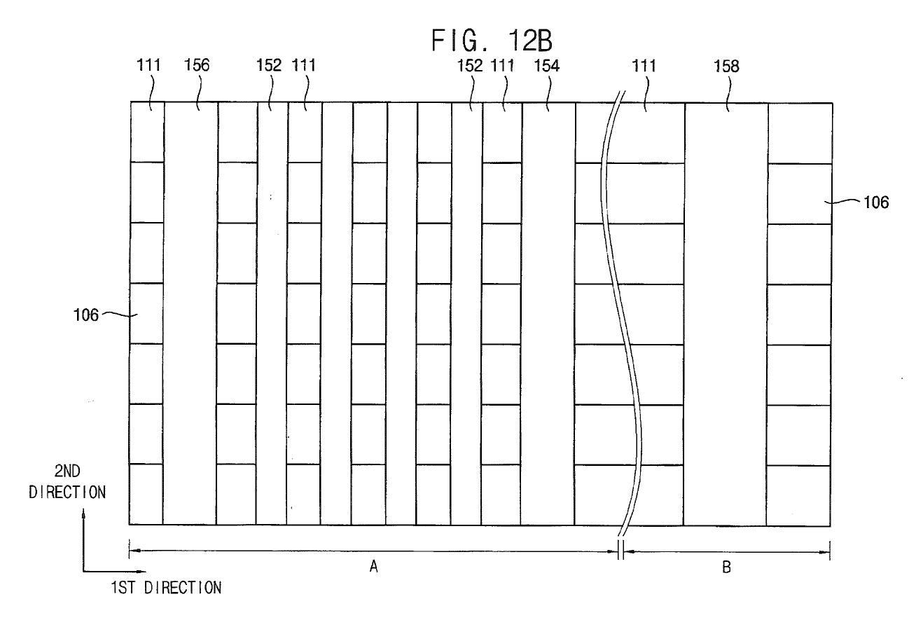

The substrate 100 may be divided into an active region and a field region by a plurality of isolation layers 106 (refer to FIGS. 12A and 12B), each of which extends in a first direction, and arranged in a second direction substantially perpendicular to the first direction. That is, a region in which the isolation layers 106 are formed may be referred to as the field region and a region in which the isolation layers 106 are not formed may be referred to as the active region. FIGS. 1 to 10 are cross-sectional views of the semiconductor devices in the active region.

The substrate 100 may be divided into a first region A and a second region B. In example embodiments, the first region A may serve as a cell region for forming memory cells, and the second region may serve as a peripheral region or core region for forming peripheral circuits.

The tunnel insulation layer 110 may be formed using an oxide, such as silicon oxide, a nitride, such as silicon nitride, silicon oxide doped with impurities, or a low-k dielectric material.

The floating gate layer 120 may be formed using doped polysilicon, a metal having a high work function, e.g., tungsten, titanium, cobalt, nickel, etc.

The dielectric layer 130 may be formed using an oxide or a nitride, and, for example, may have a multi-layered structure of oxide/nitride/oxide (ONO). Alternatively, the dielectric layer 130 may be formed using a metal oxide having a high dielectric constant, so that the semiconductor device may have a high capacitance and improved leakage current characteristics. The high-k metal oxide may include hafnium oxide, titanium oxide, tantalum oxide, zirconium oxide, aluminum oxide, etc.

The control gate layer 140 may be formed using doped polysilicon, a metal, a metal nitride, a metal silicide, etc. In example embodiments, the control gate layer 140 may be formed to include doped polysilicon at an upper portion thereof.

The gate mask layer 150 may be formed using silicon oxide, silicon nitride or silicon oxynitride.

Alternatively, a charge trapping layer 120, a blocking layer 130 and a gate electrode layer 140 may be sequentially formed on the tunnel insulation layer 110 instead of the floating gate layer 120, the dielectric layer 130 and the control gate layer 140, respectively.

The charge trapping layer 120 may be formed using a nitride, such as silicon nitride, or a metal oxide, such as hafnium oxide. The blocking layer 130 may be formed using silicon oxide, or a high-k metal oxide, such as hafnium oxide, titanium oxide, tantalum oxide, zirconium oxide, aluminum oxide, etc. The gate electrode layer 140 may be formed using doped polysilicon, a metal, a metal nitride, a metal silicide, etc. In example embodiments, the gate electrode layer 140 may be formed to include doped polysilicon at an upper portion thereof.

Hereinafter, only the structure including the floating gate layer 120, the dielectric layer 130 and the control gate layer 140 sequentially stacked on the tunnel insulation layer 110 is illustrated.

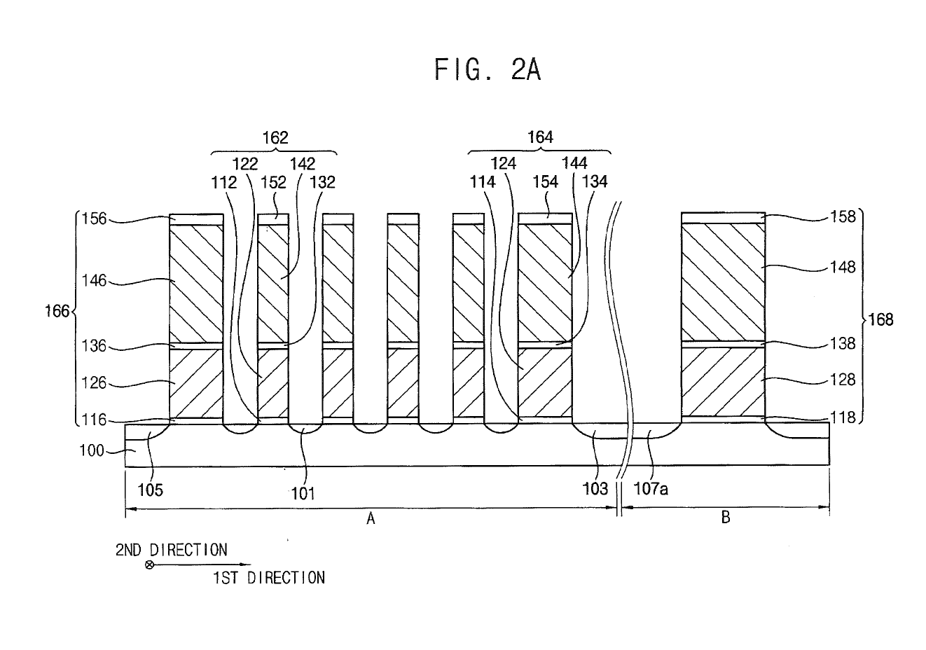

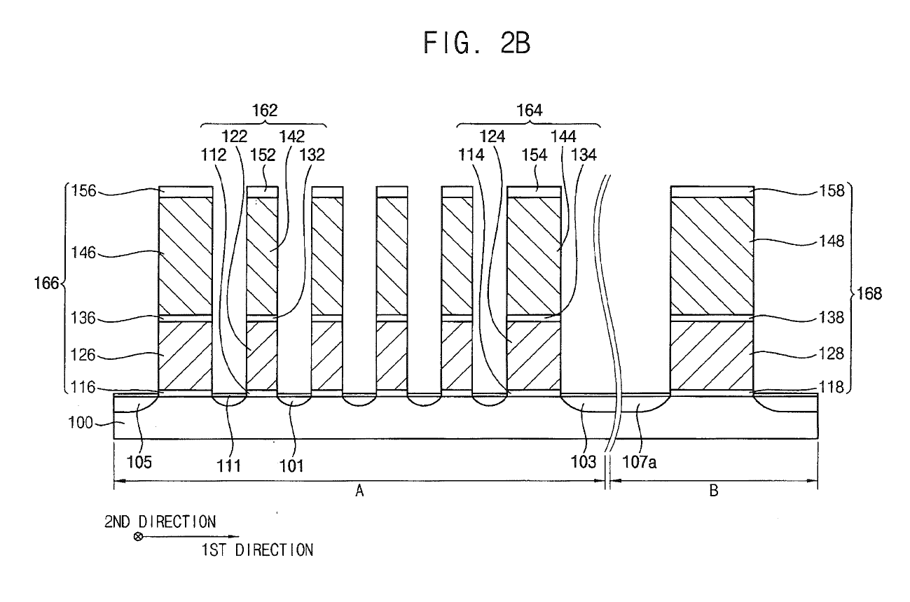

Referring to FIGS. 2A and 12A, the gate mask layer 150, the control gate layer 140, the dielectric layer 130, the floating gate layer 120 and the tunnel insulation layer 110 may be sequentially etched by a photolithography process to form first, second, third and fourth preliminary gate structures 162, 164, 166 and 168 on the substrate 100.

The first, second and third preliminary gate structures 162, 164 and 166 may be formed in the first region A. A plurality of first preliminary gate structures 162 may be formed between the first and second preliminary gate structures 164 and 166, and in example embodiments, 16 or 32 first preliminary gate structures 162 may be formed. The fourth preliminary gate structure 168 may be formed in the second region B.

The first through fourth preliminary gate structures 162, 164, 166 and 168 may include first through fourth tunnel insulation layer patterns 112, 114, 116 and 118, first through fourth floating gates 122, 124, 126 and 128, first through fourth dielectric layer patterns 132, 134, 136 and 138, first through fourth preliminary control gates 142, 144, 146 and 148, and first through fourth gate masks 152, 154, 156 and 158 sequentially stacked on the substrate 100, respectively.

In example embodiments, the tunnel insulation layer patterns 112, 114, 116 and 118 may be formed to have an island shape from each other on the substrate 100 in the active region. The floating gates 122, 124, 126 and 128 may be also formed to have an island shape from each other on the tunnel insulation layer patterns 112, 114, 116 and 118, respectively, in the active region. In example embodiments, each of the dielectric layer patterns 132, 134, 136 and 138, and each of the preliminary control gates 142, 144, 146 and 148 may be formed to extend in the second direction and sequentially formed on the floating gates 122, 124, 126 and 128 and the isolation layer 106.

Alternatively, referring to FIGS. 2B and 12B, the tunnel insulation layer patterns 112, 114, 116 and 118 may not have the island shape but extend in the first direction. In this case, portions of the tunnel insulation layer patterns 112, 114, 116 and 118 that are not covered by the floating gates 122, 124, 126 and 128, respectively, may have a relatively small thickness. The portions of the tunnel insulation layer patterns 112, 114, 116 and 118 that are not covered by the floating gates 122, 124, 126 and 128 may be referred to as a fifth tunnel insulation layer pattern 111. Particularly, the fifth tunnel insulation layer pattern 111 may be formed by patterning the tunnel insulation layer 110 to form a plurality of lines or bars extending in the first direction in the active region and removing upper portions of the lines or bars not covered by the floating gates 122, 124, 126 and 128. The tunnel insulation layer 110 may not be completely removed from the substrate 100, and, thus, damage to the substrate 100 during the patterning process may be reduced or prevented.

Referring to FIGS. 2A and 12A again, first impurities may be implanted into the substrate 100 using the preliminary gate structures 162, 164, 166 and 168 as an ion implantation mask. Thus, first, second, third and fourth impurity regions 101, 103, 105 and 107a may be formed at upper portions of the substrate 100 adjacent to the preliminary gate structures 162, 164, 166 and 168, respectively. Particularly, the first impurity region 101 may be formed at upper portions of the substrate 100 adjacent to the first preliminary gate structures 162, the second impurity region 103 may be formed at an upper portion of the substrate 100 outside the second preliminary gate structure 164, the third impurity region 105 may be formed at an upper portion of the substrate 100 outside the third preliminary gate structure 166, and the fourth impurity region 107a may be formed at an upper portion of the substrate 100 adjacent to the fourth preliminary gate structure 168.

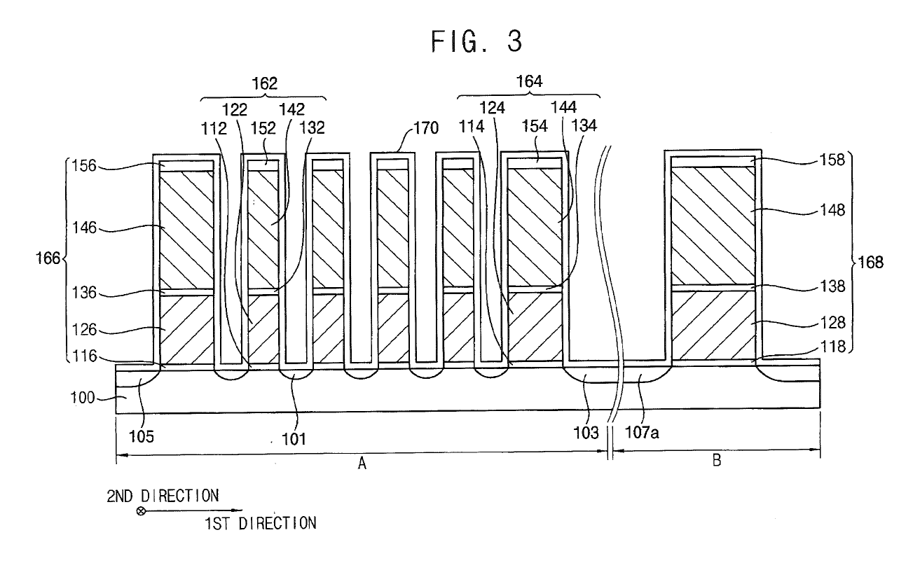

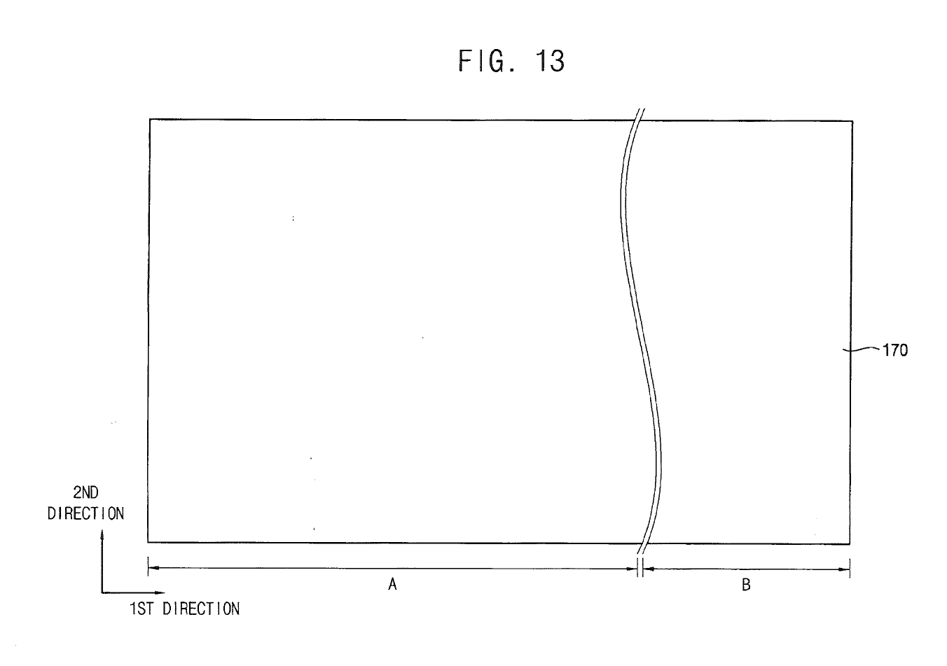

Referring to FIGS. 3 and 13, a first insulation layer 170 may be formed on the substrate 100 to cover the preliminary gate structures 162, 164, 166 and 168.

The first insulation layer 170 may be formed using silicon oxide, silicon nitride or silicon oxynitride by a chemical vapor deposition (CVD) process, an atomic layer deposition (ALD) process, a physical vapor deposition (PVD) process, etc. In example embodiments, the first insulation layer 170 may be formed using high temperature oxide (HTO) or middle temperature oxide (MTO) to have a thickness of about 50 Å.

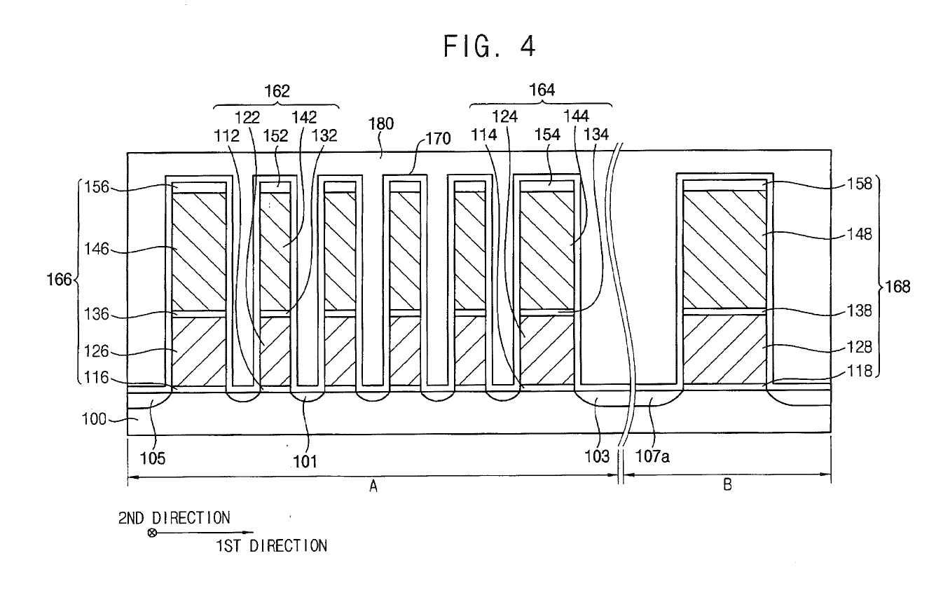

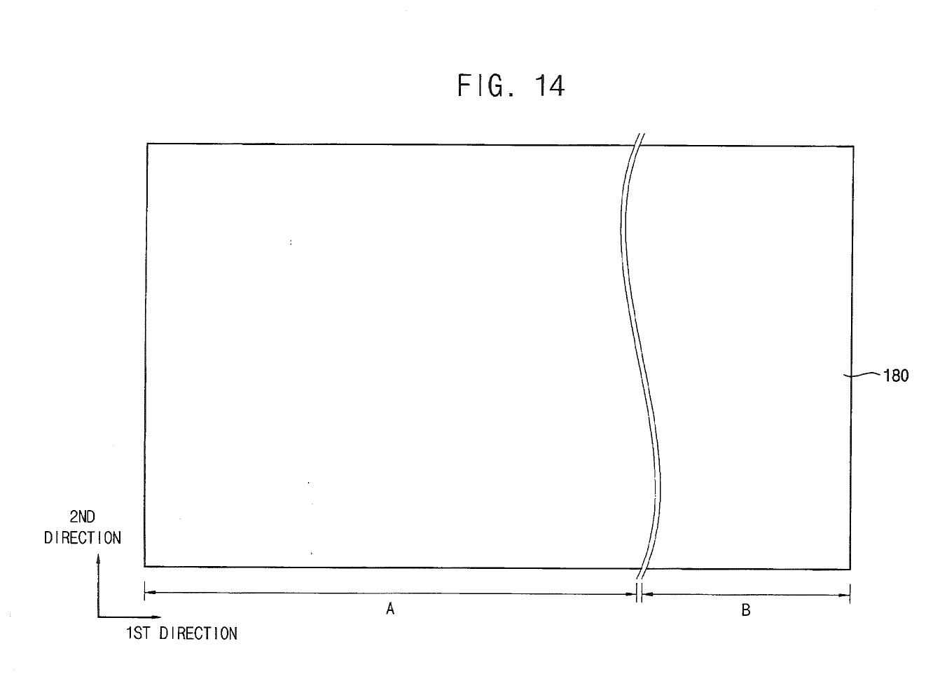

Referring to FIGS. 4 and 14, a sacrificial layer 180 may be formed on the first insulation layer 170 to fill spaces between preliminary gate structures 162, 164, 166 and 168.

The sacrificial layer 180 may be formed by a CVD process, an ALD process, a PVD process, etc. In example embodiments, the sacrificial layer 180 may be formed using carbon-based spin-on-hardmask (C-SOH) or silicon-based spin-on-hardmask (Si-SOH).

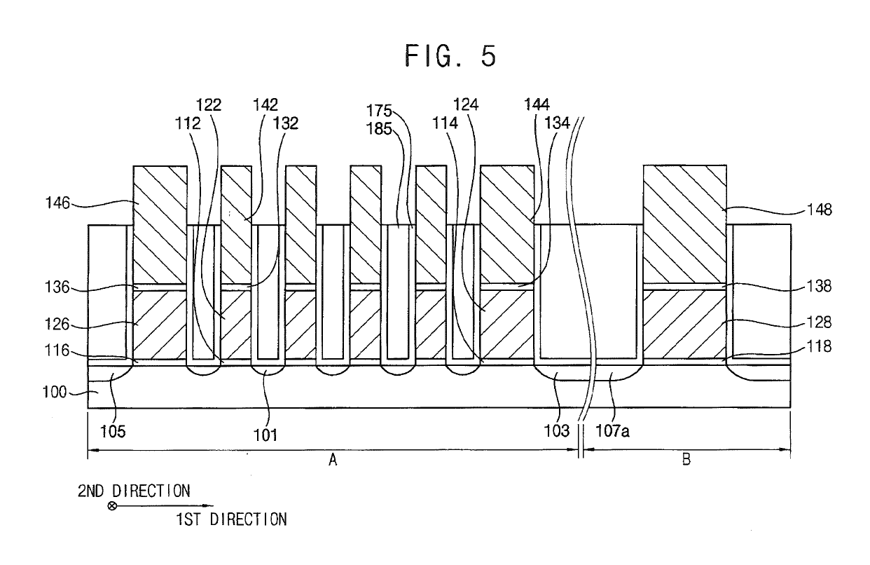

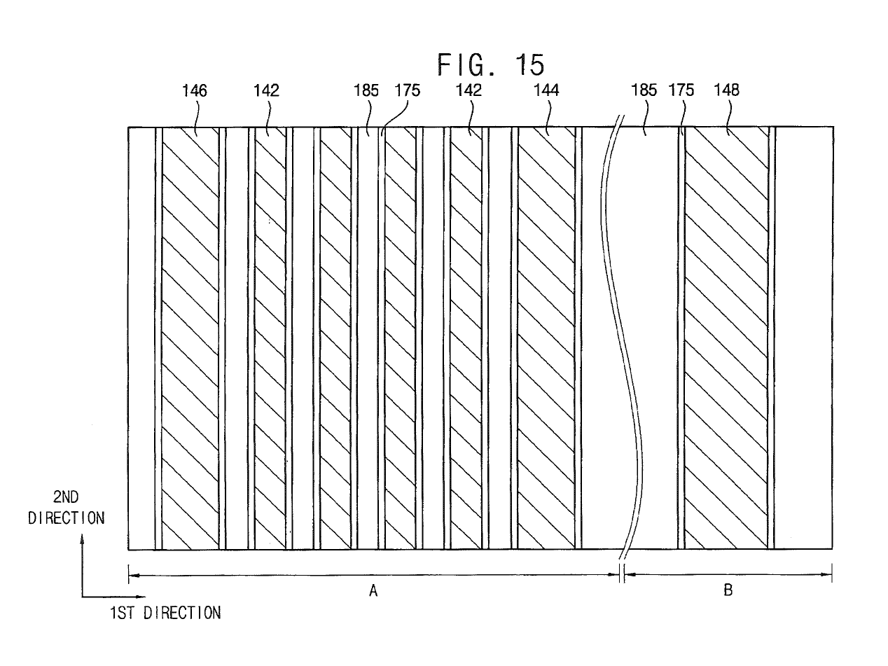

Referring to FIGS. 5 and 15, upper portions of the sacrificial layer 180 and the first insulation layer 170 may be removed to form a sacrificial layer pattern 185 and a first insulation layer pattern 175, respectively, and the preliminary control gates 142, 144, 146 and 148 may be partially exposed. That is, the first insulation layer pattern 175 may be formed on sidewalls of the tunnel insulation layer patterns 112, 114, 116 and 118, the floating gates 122, 124, 126 and 128 and the dielectric layer patterns 132, 134, 136 and 138, on a portion of sidewalls of the preliminary control gates 142, 144, 146 and 148, and on a top surface of the substrate 100 between the preliminary gate structures 162, 164, 166 and 168. Thus, the first insulation layer pattern 175 may have a top surface higher than those of the dielectric layer patterns 132, 134, 136 and 138.

The gate masks 152, 154, 156 and 158 may be also removed, so that not only sidewalls but also top surfaces of the preliminary control gates 142, 144, 146 and 148 may be exposed.

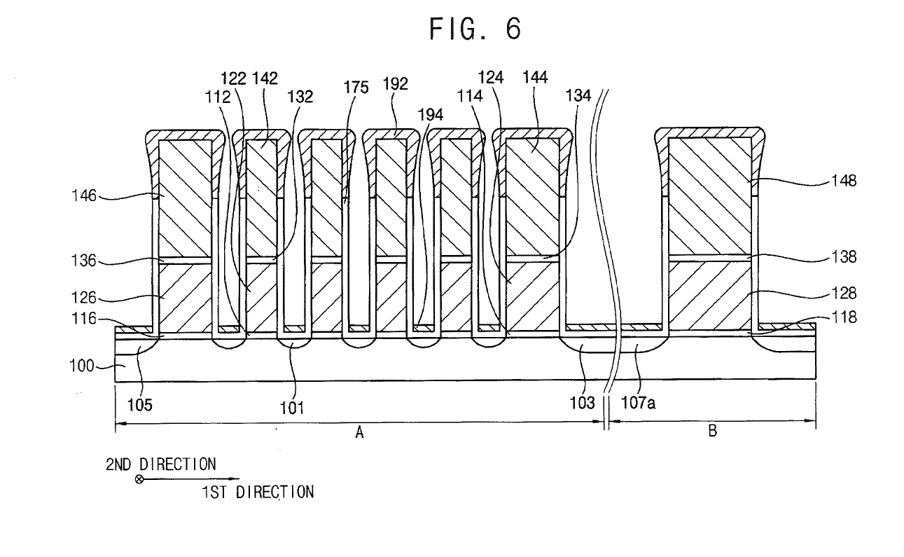

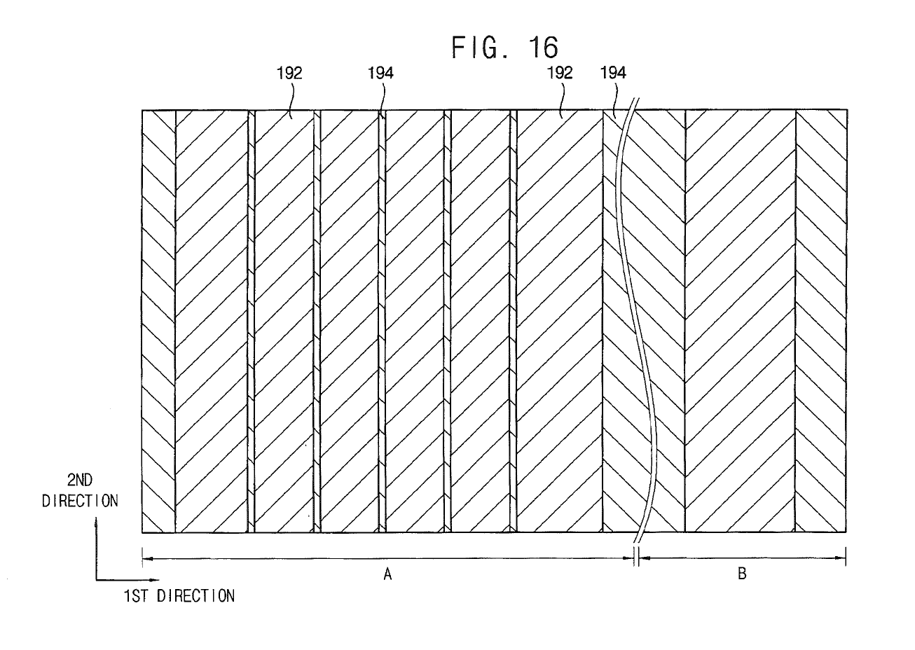

The first insulation layer pattern 175 may restrict a region for forming a first conductive layer 192 (refer to FIGS. 6 and 16), and also restrict a region in which the first conductive layer 192 may be reacted with the preliminary gate structures 162, 164, 166 and 168. That is, the first insulation layer pattern 175 may serve as a reaction prevention layer.

In example embodiments, the upper portion of the sacrificial layer 180 may be removed by a dry etching process, and the upper portion of the first insulation layer 170 may be removed by an etch back process.

The sacrificial layer pattern 185 may be removed. In example embodiments, the sacrificial layer pattern 185 may be removed by an ashing process.

Referring to FIGS. 6 and 16, the first conductive layer 192 may be formed on the exposed portions of the preliminary control gates 142, 144, 146 and 148.

In example embodiments, the first conductive layer 192 may be formed using a metal, such as cobalt, nickel, etc. by a PVD process. The first conductive layer 192 may be formed on the exposed portions of the preliminary control gates 142, 144, 146 and 148, and a second conductive layer 194 may be further formed on a portion of the first insulation layer pattern 175 on the substrate 100.

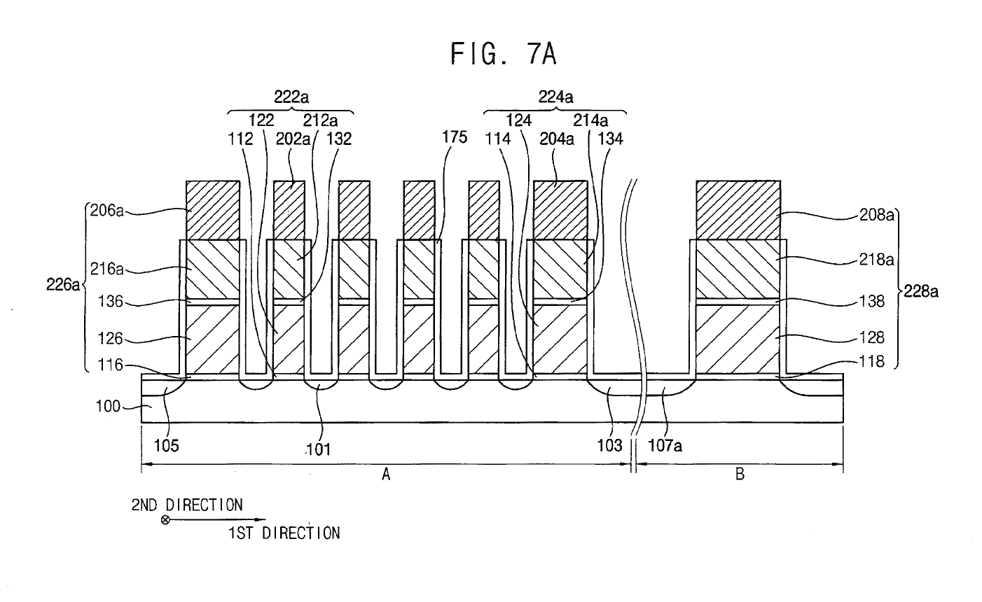

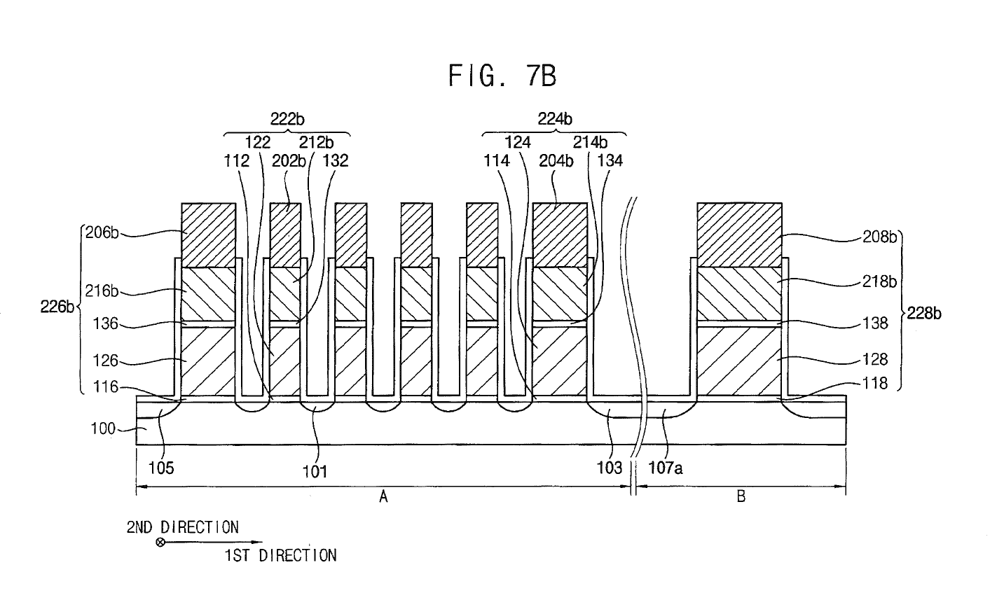

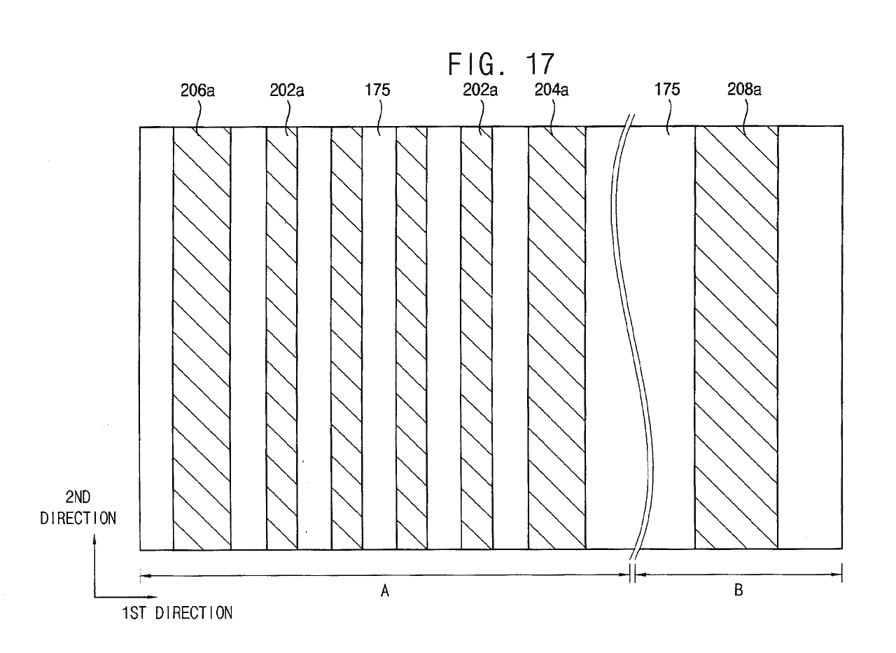

Referring to FIGS. 7A and 17, the exposed portions of the preliminary control gates 142, 144, 146 and 148 may be reacted with the first conductive layer 192 to form first, second, third and fourth upper conductive patterns 202a, 204a, 206a and 208a, respectively. Portions of the preliminary control gates 142, 144, 146 and 148 that are not reacted with the first conductive layer 192 may be defined as first, second, third and fourth lower conductive patterns 212a, 214a, 216a and 218a, respectively. The first through fourth upper conductive patterns 202a, 204a, 206a and 208a together with the first through fourth lower conductive patterns 212a, 214a, 216a and 218a may define first through fourth control gates, respectively.

In example embodiments, portions of the preliminary control gates 142, 144, 146 and 148 including doped polysilicon may be reacted with the first conductive layer 192 to form a metal silicide layer. The silicidation process may be performed by a heat treatment. When the first conductive layer 192 includes cobalt, a cobalt silicide layer may be formed to have a bottom surface substantially coplanar with the top surface of the first insulation layer pattern 175. That is, the portions of the preliminary control gates 142, 144, 146 and 148 not covered by the first insulation layer pattern 175 may be reacted with the first conductive layer 192 to form the upper conductive patterns 202a, 204a, 206a and 208a, respectively.

Alternatively, when the first conductive layer 192 includes nickel, referring to FIG. 7B, a nickel silicide layer may be formed to have a bottom surface lower than the top surface of the first insulation layer pattern 175, because nickel of the first conductive layer 192 may move to even portions of the preliminary control gates 142, 144, 146 and 148 covered by the first insulation layer pattern 175 during the silicidation process. Thus, fifth, sixth, seventh and eighth upper conductive patterns 202b, 204b, 206b and 208b may be formed. In this case, portions of the first through fourth preliminary control gates 142, 144, 146 and 148 that are not reacted with the first conductive layer 192 may be referred to as fifth, sixth, seventh and eighth lower conductive patterns 212b, 214b, 216b and 218b, respectively. The fifth through eighth upper conductive patterns 202b, 204b, 206b and 208b together with the fifth through eighth lower conductive patterns 212b, 214b, 216b and 218b may define fifth through eighth control gates, respectively.

In the present embodiment, metal of the first conductive layer 192 may be reacted with silicon of the preliminary control gates 142, 144, 146 and 148 to form a metal silicide layer, however, other types of reaction may also occur. That is, if the characteristics, e.g., low resistance characteristics, of the preliminary control gates 142, 144, 146 and 148 may be improved by reaction with the first conductive layer 192 on the exposed portions of the preliminary control gates 142, 144, 146 and 148, any type of reaction may be within the scope of the present inventive concept. Further, not only a conductive layer but also an insulating layer may be formed on the preliminary control gates 142, 144, 146 and 148, if the insulating layer may be reacted with the preliminary control gates 142, 144, 146 and 148. In this respect, the first conductive layer 192 and the first insulation layer pattern 175 may serve as a reaction layer and a reaction prevention layer, respectively.

Referring to FIGS. 7A and 17 again, portions of the first conductive layer 192 that are not reacted with the preliminary control gates 142, 144, 146 and 148 and the second conductive layer 194 may be removed, e.g., by a stripping process.

Thus, first, second, third and fourth gate structures 222a, 224a, 226a and 228a may be formed on the substrate 100. The first through fourth gate structures 222a, 224a, 226a and 228a may include the first through fourth tunnel insulation layer patterns 112, 114, 116 and 118, the first through fourth floating gates 122, 124, 126 and 128, the first through fourth dielectric layer patterns 132, 134, 136 and 138, the first through fourth lower conductive patterns 212a, 214a, 216a and 218a, and the first through fourth upper conductive patterns 202a, 204a, 206a and 208a, respectively.

The first, second and third control gates included in the first, second and third gate structures 222a, 224a and 226a, respectively, may be formed in the first region A and serve as a word line, a ground selection line (GSL) and a string selection line (SSL), respectively.

Alternatively, referring to FIG. 7B, fifth, sixth, seventh and eighth gate structures 222b, 224b, 226b and 228b may be formed on the substrate 100. The fifth through eighth gate structures 222b, 224b, 226b and 228b may include the first through fourth tunnel insulation layer patterns 112, 114, 116 and 118, the first through fourth floating gates 122, 124, 126 and 128, the first through fourth dielectric layer patterns 132, 134, 136 and 138, the fifth through eighth lower conductive patterns 212b, 214b, 216b and 218b, and the fifth through eighth upper conductive patterns 202b, 204b, 206b and 208b, respectively. The fifth, sixth and seventh control gates included in the fifth, sixth and seventh gate structures 222b, 224b and 226b, respectively, may be formed in the first region A and serve as a word line, a GSL and a SSL, respectively.

Hereinafter, only the case in which the first through fourth gate structures 222a, 224a, 226a and 228a are formed on the substrate 100 is illustrated.

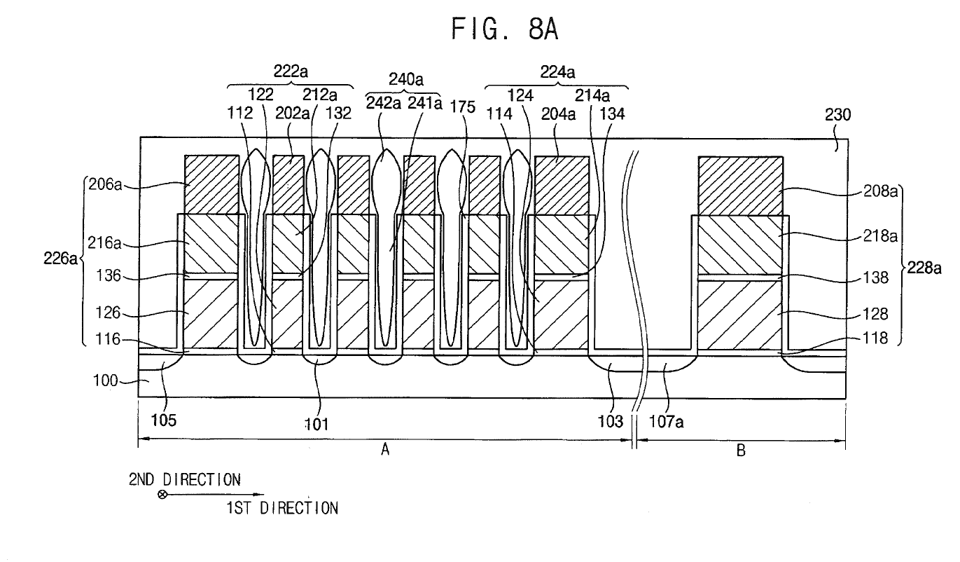

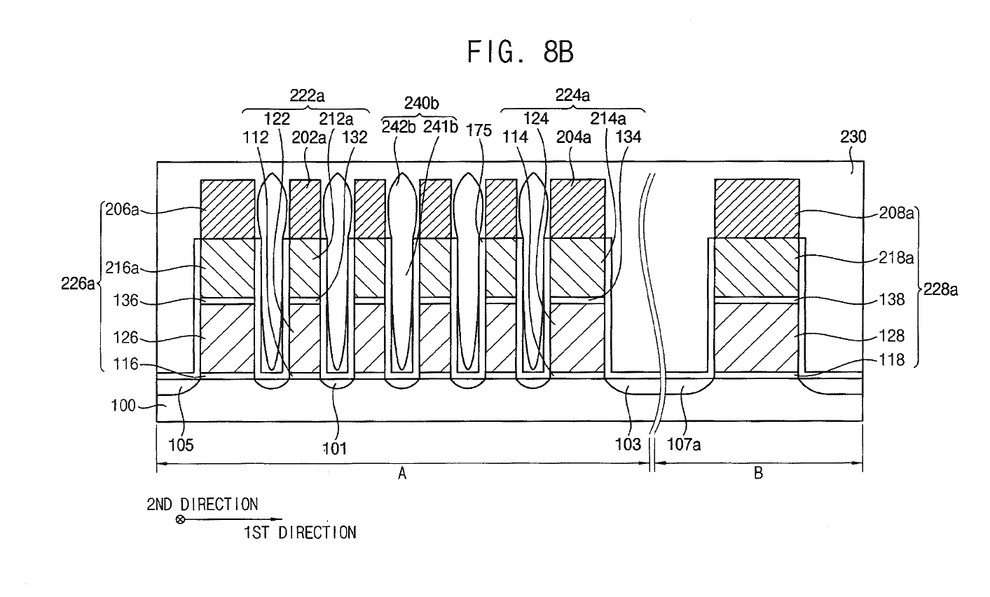

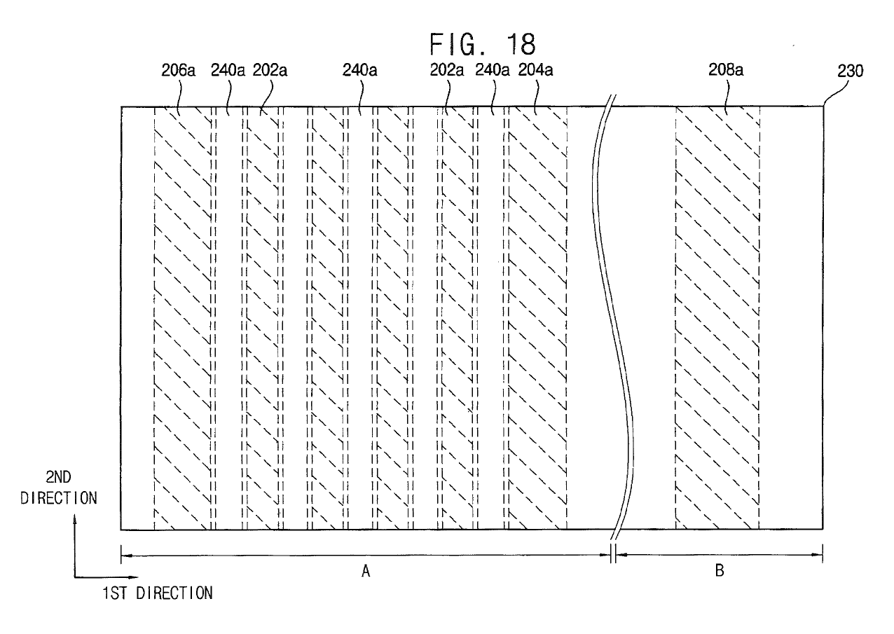

Referring to FIGS. 8A and 18, a second insulation layer 230 may be formed on the substrate 100 to cover the gate structures 222a, 224a, 226a and 228a and the first insulation layer pattern 175. The second insulation layer 230 may not completely fill spaces between the gate structures 222a, 224a, 226a and 228a. Thus, a first air gap 240a may be formed between the first, second and third gate structures 222a, 224a and 226a. In example embodiments, the first air gap 240a may be formed to extend in the second direction, and thus the air gap 240a may be also referred to as a first air tunnel.

The second insulation layer 230 may be formed using an oxide such as plasma enhanced oxide (PEOX), MTO, etc. by a CVD process, a plasma enhanced chemical vapor deposition (PECVD) process, a low pressure chemical vapor deposition (LPCVD) process, etc. The second insulation layer 230 may be formed using a material having poor step coverage so that the first air gap 240a may be formed therein.

In example embodiments, the first air gap 240a may be formed to have a top surface higher than those of the first, second and third gate structures 222a, 224a and 226a.

In example embodiments, the first air gap 240a may be formed to include a lower portion 241a having a first width and an upper portion 242a having a second width larger than the first width. In an example embodiment, the lower portion 241a of the first air gap 240a may have a linear shape or a bar shape extending in a direction perpendicular to a top surface of the substrate 100, and the upper portion 242a of the first air gap 240a may have an oval shape of which a top surface is sharp. That is, when the second insulation layer 230 is formed, the lower portion 241a having a linear shape or a bar shape having a relatively narrow width may be formed in an area narrowed by the first insulation layer pattern 175 on the sidewall of the first through third gates 222a, 224a and 226a, while the upper portion 242a having an oval shape having a relatively wide width may be formed in an area in which the first insulation layer pattern 175 is not formed. In this case, as the first insulation layer pattern 175 has a thicker thickness, the width difference between the upper portion 242a and the lower portion 241a may be larger.

The first air gap 240a may be defined only by the second insulation layer 230. That is, the second insulation layer 230 may be formed to cover not only the gate structures 222a, 224a, 226a and 228a but also the first insulation layer pattern 175, so that the boundary of the first air gap 240a may be defined only by the second insulation layer 230.

Alternatively, referring to FIG. 8B, a second air gap 240b defined by the second insulation layer 230 and the first insulation layer pattern 175 may be formed. That is, the second insulation layer 230 may be formed to cover the gate structures 222a, 224a, 226a and 228a and a portion of the first insulation layer pattern 175, so that the boundary of the second air gap 240b may be defined by both of the second insulation layer 230 and the first insulation layer pattern 175. In example embodiments, the second air gap 240b may be formed to extend in the second direction, and thus may be also referred to as a second air tunnel. The second air gap 240b may also include a lower portion 241b and an upper portion 242b.

Referring to FIG. 8C, a third air gap 245a having a different size or shape from that of the first air gap 240a may be formed between the first gate structure 222a and the second gate structure 224a or between the first gate structure 222a and the third gate structure 226a. In this case, the first air gap 240a may be formed only between the first gate structures 222a.

Particularly, when the second insulation layer 230 is deposited between an outermost of the first gate structure 222a and the second gate structure 224a or the third gate structure 226a, which are relatively more distant from the first gate structure 222a, the second insulation layer 230 may be formed at a wider space than when the second insulation layer 230 is deposited between the first gate structures 222a themselves, which are relatively less distant from each other. Thus, the second insulation layer 230 may be formed to have a relatively thick thickness between the outermost of the first gate structure 222a and the second gate structure 224a or the third gate structure 226a, and the third air gap 245a may have a width smaller than or equal to that of the first air gap 240a.

When the second insulation layer 230 is formed using MTO, the size difference between the first air gap 240a and the third air gap 245a may be relatively large.

Hereinafter, the semiconductor device including the second insulation layer 230 having only the first air gap 240a therein is illustrated.

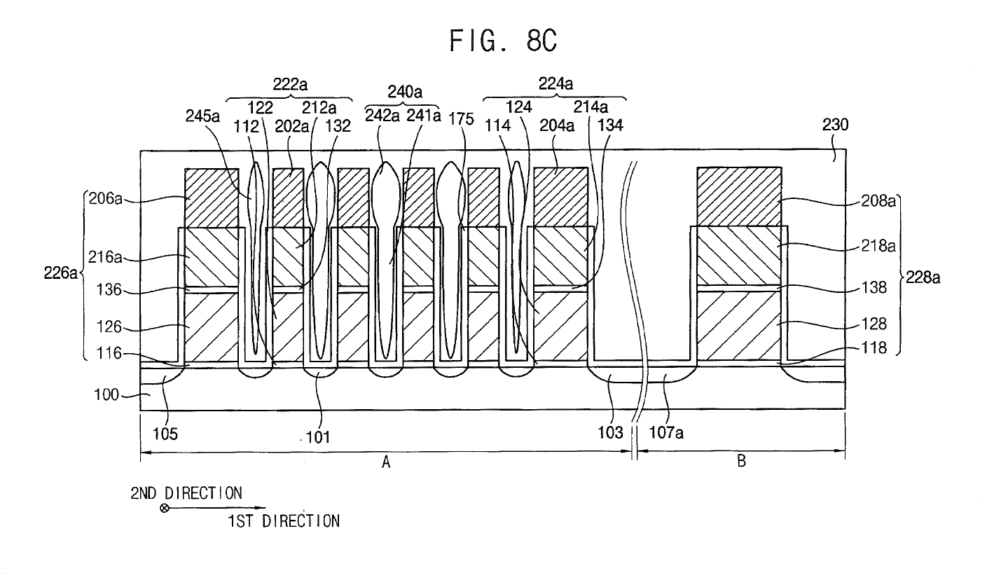

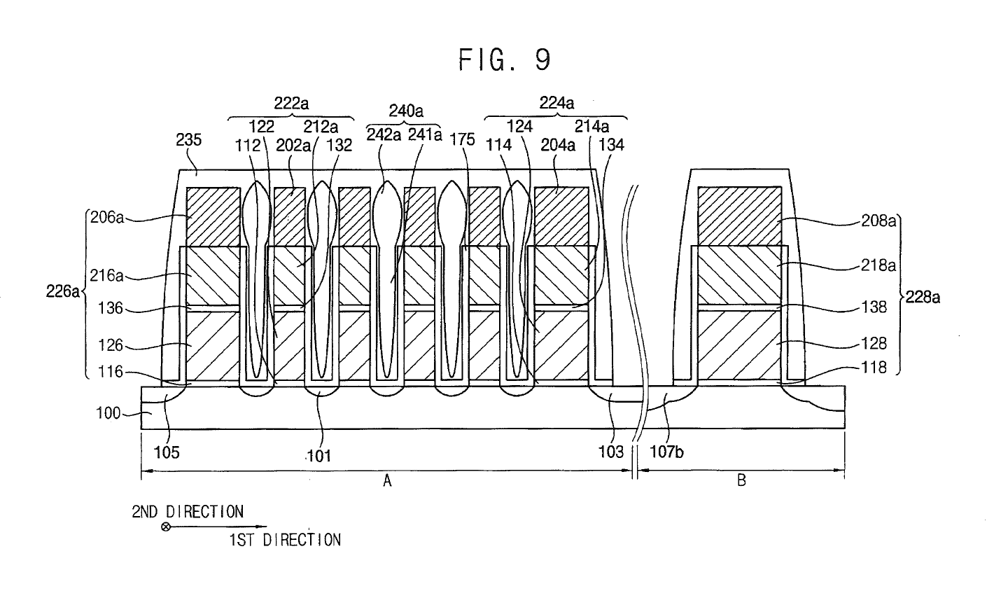

Referring to FIGS. 9 and 16, the second insulation layer 230 and the first insulation layer pattern 175 may be partially removed by a photolithography process to expose the second, third and fourth impurity regions 103, 105 and 107a. Thus, a second insulation layer pattern 235 covering the first through fourth gate structures 222a, 224a, 226a and 228a and the first insulation layer pattern 175 may be formed.

Second impurities may be implanted into the substrate 100 using the gate structures 222a, 224a, 226a and 228a and the second insulation layer pattern 235 as an ion implantation mask. Thus, a fifth impurity region 107b having a lightly doped drain (LDD) structure may be formed at an upper portion of the substrate 100 adjacent to the fourth gate structure 228a. The second impurities may be also implanted into the second and third impurity regions 103 and 105.

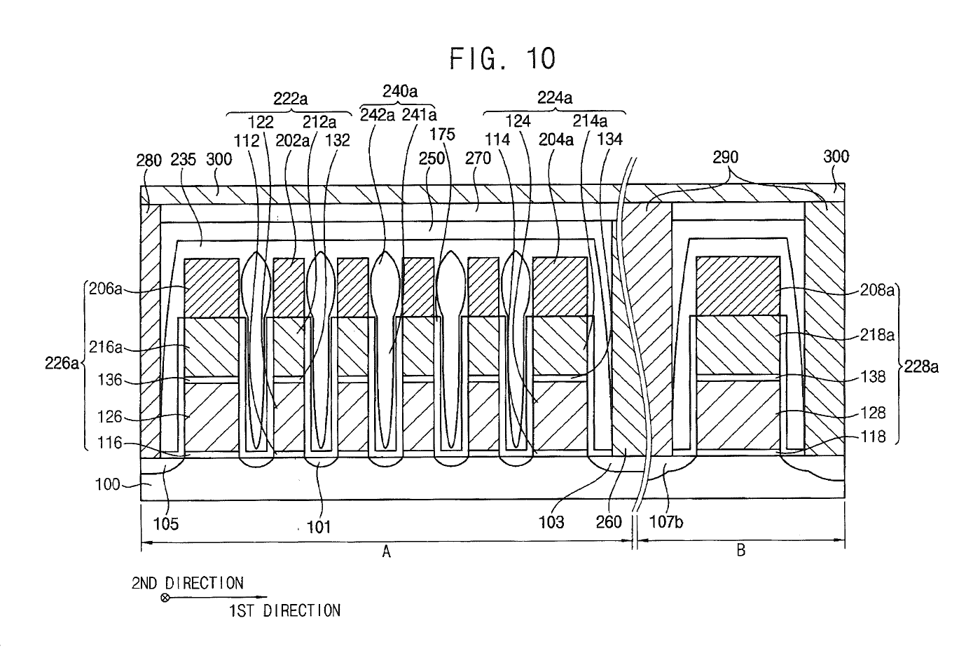

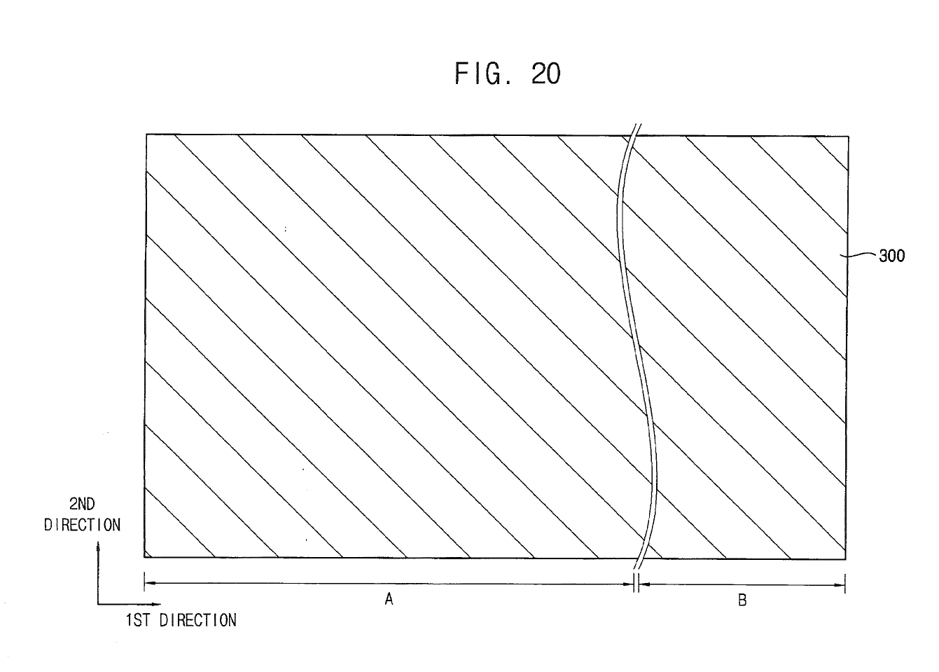

Referring to FIGS. 10 and 20, a first insulating interlayer 250 may be formed on the substrate 100 to cover the second insulation layer pattern 235. The first insulating interlayer 250 may be formed using an oxide such as borophospho silicate glass (BPSG), undoped silicate glass (USG), spin on glass (SOG), etc.

A common source line (CSL) 260 may be formed on the second impurity region 103 through the first insulating interlayer 250. The CSL 260 may be formed using doped polysilicon, a metal or a metal silicide.

A second insulating interlayer 270 may be formed on the first insulating interlayer 250 and the CSL 260. The second insulating interlayer 270 may be formed using an oxide, such as BPSG, USG, SOG, etc.

A bit line contact 280 may be formed on the third impurity region 105 through the first and second insulating interlayers 250 and 270. The bit line contact 280 may be formed using a metal, doped polysilicon, etc. A plug 290 may be formed on the fifth impurity region 107b through the first and second insulating interlayers 250 and 270.

A bit line 300 may be formed on the second insulating interlayer 270 to be electrically connected to the bit line contact 280. The bit line 300 may be formed to extend in the first direction. The bit line 300 may be formed using a metal, doped polysilicon, etc. The bit line 300 may be also formed in the second region B to be electrically connected to the plug 290.

By the above processes, the semiconductor device in accordance with example embodiments may be manufactured. In FIGS. 1 to 20, a NAND flash memory device is illustrated, however, the scope of the present inventive concept may be also applied to other types of semiconductor devices, such as a NOR flash memory device, a DRAM device, etc.

The semiconductor device may include the first through fourth gate structures 222a, 224a, 226a and 228a, each of which extends in the second direction, spaced apart from each other in the first direction. The first insulation layer pattern 175 may be formed on the sidewalls of the first through fourth gate structures 222a, 224a, 226a and 228a and the top surface of the substrate 100 therebetween. Additionally, the semiconductor device may include the second insulation layer pattern 235 covering the first through fourth gate structures 222a, 224a, 226a and 228a and the first insulation layer pattern 175 and having the first air gap 240a that extends in the second direction between the first through third gate structures 222a, 224a and 226a.

In example embodiments, the first air gap 240a may have a top surface higher than those of the first through third gate structures 222a, 224a and 226a. In example embodiments, the first air gap 240a may be formed to include the lower portion 241a having the first width and the upper portion 242a having the second width larger than the first width. The lower portion 241 a of the first air gap 240a may be adjacent to the first insulation layer pattern 175, and the upper portion of the first air gap 240a may be adjacent to the sidewalls of the first through the third gate structures 222a, 224a and 226a not covered by the first insulation layer pattern 175. In an example embodiment, the lower portion 241a may have a linear or bar shape, and the upper portion 242a may have an oval shape of which the top surface is sharp.

Due to the first air gap 240a between the first through third gate structures 222a, 224a and 226a, the parasitic capacitance therebetween may be reduced to enhance the characteristics of the semiconductor device. In example embodiments, the distance between a bottom surface of the first air gap 240a and a top surface of the substrate 100, i.e., the thickness of portions of the first and second insulation layer patterns 175 and 235 under the first air gap 240a may be equal to or less than about 10 nm. Thus, the first air gap 240a may be formed closer to the top surface of the substrate 100 than that of the conventional semiconductor device, and, thus, parasitic capacitance may be reduced.

The first through fourth gate structures 222a, 224a, 226a and 228a may include first through fourth tunnel insulation layer patterns 112, 114, 116 and 118, the first through fourth floating gates 122, 124, 126 and 128, the first through fourth dielectric layer patterns 132, 134, 136 and 138, and the first through fourth control gates, respectively. The first through fourth control gates may include the first through fourth lower conductive patterns 212a, 214a, 216a and 218a and the first through fourth upper conductive patterns 202a, 204a, 206a and 208a, respectively.

The first insulation layer pattern 175 may cover the sidewalls of the tunnel insulation layer patterns 112, 114, 116 and 118, the sidewalls of the floating gates 122, 124, 126 and 128, and the sidewalls of the dielectric layer patterns 132, 134, 136 and 138. The first insulation layer pattern 175 may have a top surface coplanar with bottom surfaces of the upper conductive patterns 202a, 204a, 206a and 208a including cobalt silicide.

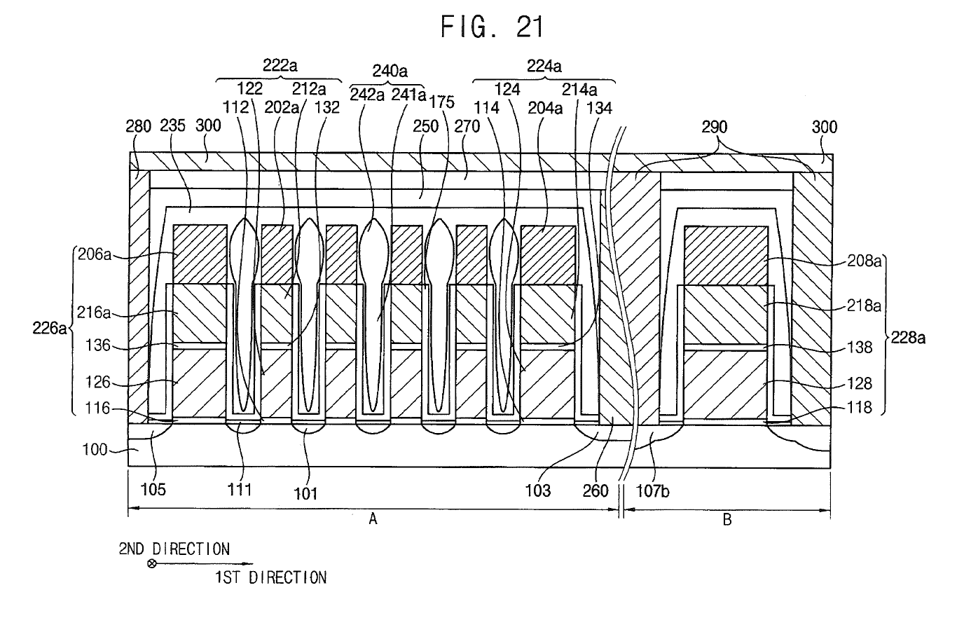

FIGS. 21 to 24 are cross-sectional views illustrating some semiconductor devices manufactured by the above processes. The semiconductor devices in FIGS. 21 to 24 are substantially the same as that of FIG. 20 except for some elements, and thus only the difference therebetween is explained.

The semiconductor device of FIG. 21 further includes the fifth tunnel insulation layer pattern 111 on the portion of the substrate 100 between the first through third gate structures 222a, 224a and 226a. Thus, the first insulation layer pattern 175 may be formed on the sidewalls of the first through fourth gate structures 222a, 224a, 226a and 228a and on the fifth tunnel insulation layer pattern 111. The fifth tunnel insulation layer pattern 111 may have a thickness smaller than those of the first through fourth tunnel insulation layer patterns 112, 114, 116 and 118.

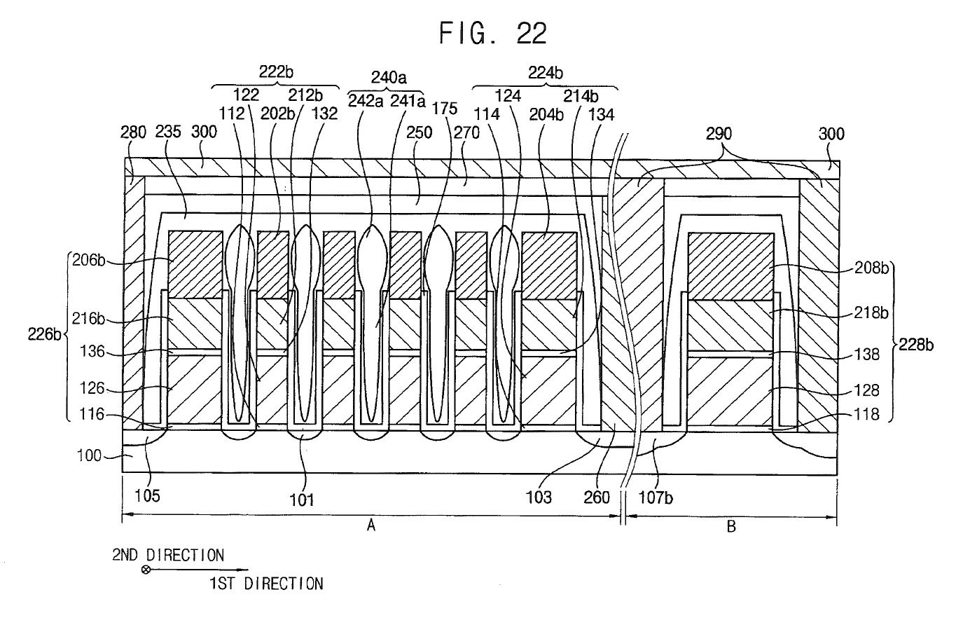

The semiconductor device of FIG. 22 may include the fifth through eighth control gates. The fifth through eighth control gates may include the fifth through eighth lower conductive patterns 212b, 214b, 216b and 218b, and the fifth through eighth upper conductive patterns 202b, 204b, 206b and 208b. The upper conductive patterns 202b, 204b, 206b and 208b including nickel silicide may have bottom surfaces lower than a top surface of the first insulation layer pattern 175.

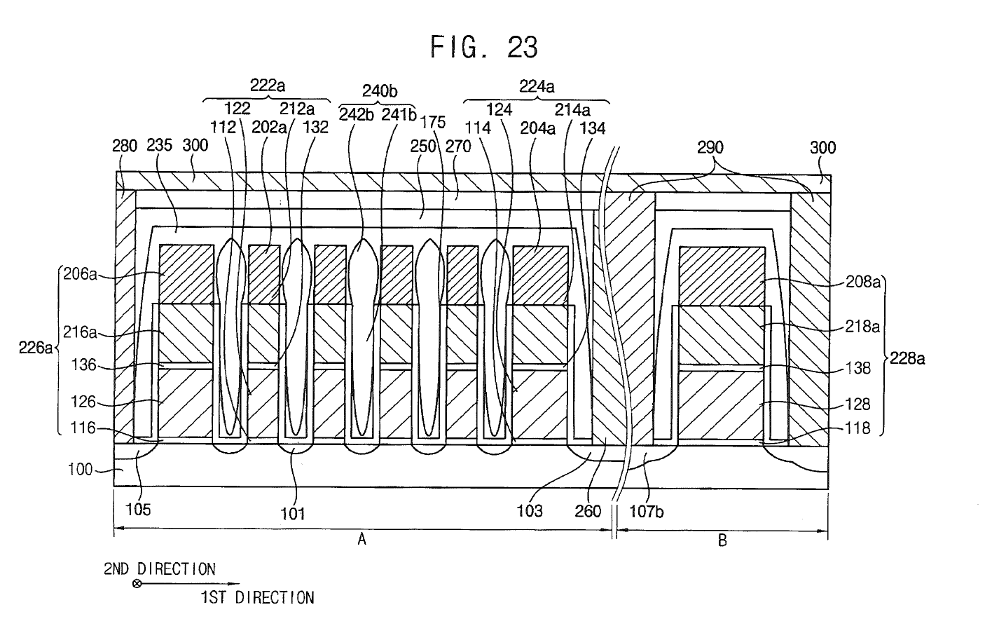

The semiconductor device of FIG. 23 may include the second insulation layer pattern 235 that covers the first through fourth gate structures 222a, 224a, 226a and 228a and a portion of the first insulation layer pattern 175, and has the second air gap 240b defined by the first through third gate structures 222a, 224a and 226a and the first insulation layer pattern 175. The boundary of the second air gap 240b may be defined by the first through third gate structures 222a, 224a and 226a and the first insulation layer pattern 175.

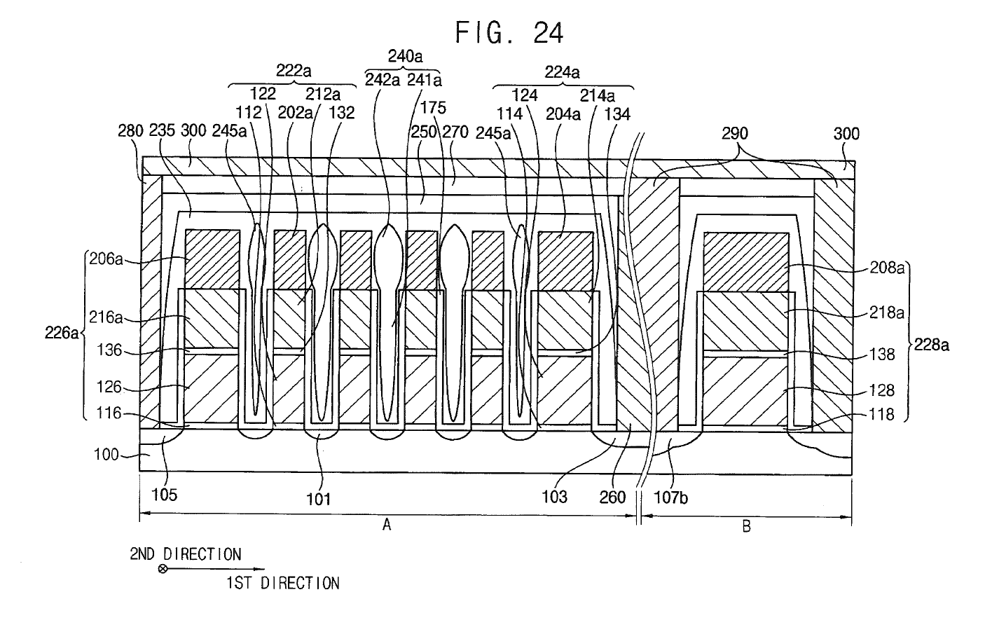

The semiconductor device of FIG. 24 may include the second insulation layer pattern 235 that covers the first through fourth gate structures 222a, 224a, 226a and 228a and a portion of the first insulation layer pattern 175, and has the first air gap 240a between the first gate structures 222a and the third air gap 245a between the first gate structure 222a and the second gate structure 224a or the third gate structure 226a. The third air gap 245a may have a width smaller than or equal to that of the first air gap 240a.

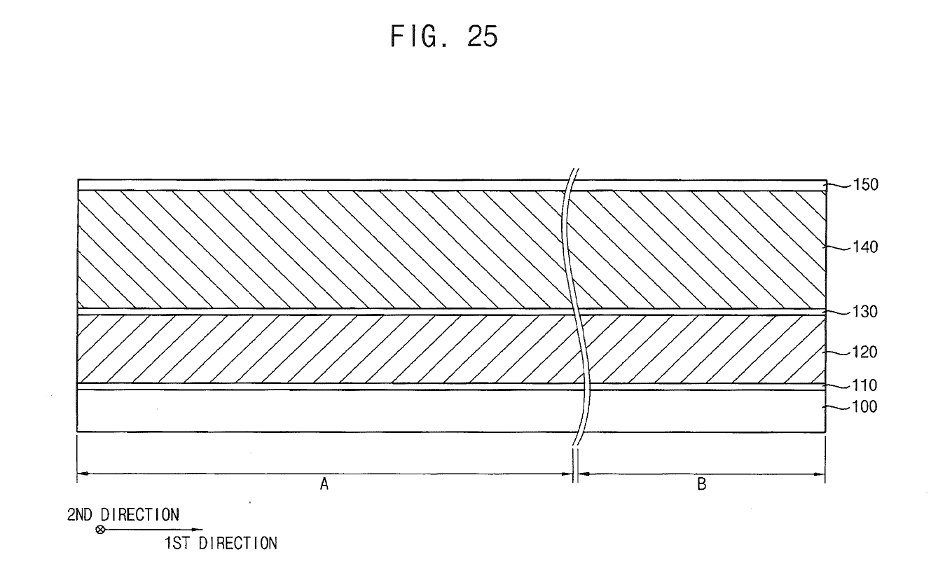

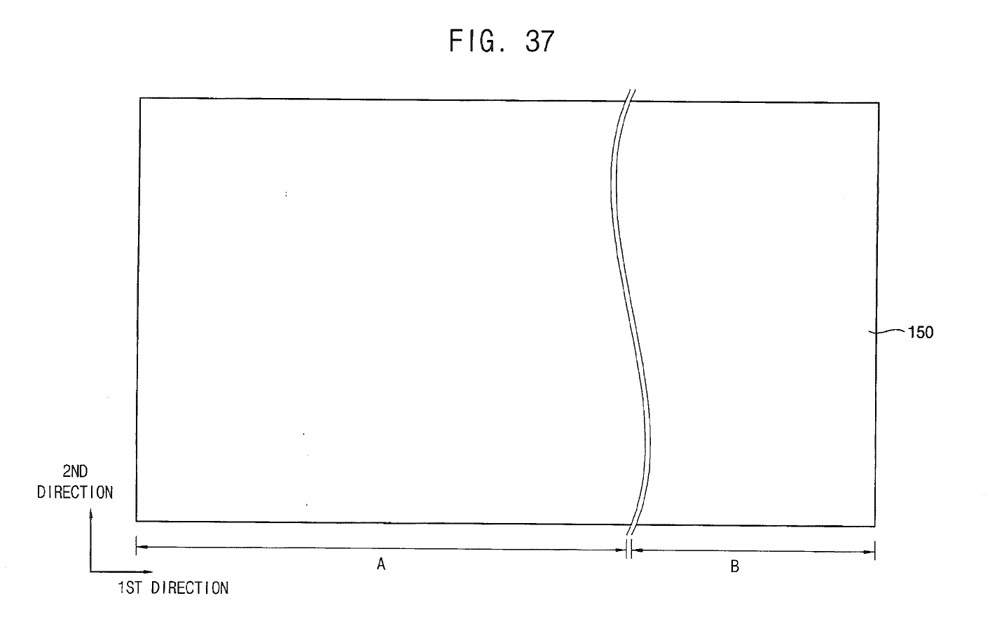

FIGS. 25 to 36 are cross-sectional views illustrating a method of manufacturing a semiconductor device in accordance with other example embodiments, and FIGS. 37 to 48 are top views illustrating the method of manufacturing the semiconductor device.

Referring to FIGS. 25 and 37, a tunnel insulation layer 110, a floating gate layer 120, a dielectric layer 130, a control gate layer 140 and a gate mask layer 150 may be sequentially formed on a substrate 100.

The substrate 100 may be divided into an active region and a field region by a plurality of isolation layers 106 (refer to FIGS. 38A and 38B), each of which extends in a first direction, arranged in a second direction substantially perpendicular to the first direction. That is, a region in which the isolation layers 106 are formed may be referred to as the field region, and a region in which the isolation layers 106 are not formed may be referred to as the active region. FIGS. 25 to 36 are cross-sectional views of the semiconductor devices in the active region.

The substrate 100 may be divided into a first region A and a second region B. In example embodiments, the first region A may serve as a cell region for forming memory cells and the second region B may serve as a peripheral circuit region or a core region for forming peripheral circuits. Alternatively, both of the first and second regions A and B may be in the cell region or the peripheral circuit region, wherein the first region A may be a region in which a plurality of gate structures is formed at a relatively high density and the second region B may be a region in which a plurality of gate structures is formed at a relatively low density. Hereinafter, only the case in which the first and second regions A and B serve as the cell region and the peripheral circuit region, respectively, is illustrated.

Instead of the floating gate layer 120, the dielectric layer 130 and the control gate layer 140, respectively, a charge trapping layer 120, a blocking layer 130 and a gate electrode layer 140 may be sequentially formed on the tunnel insulation layer 110.

Hereinafter, only the structure including the floating gate layer 120, the dielectric layer 130 and the control gate layer 140 sequentially stacked on the tunnel insulation layer 110 is illustrated.

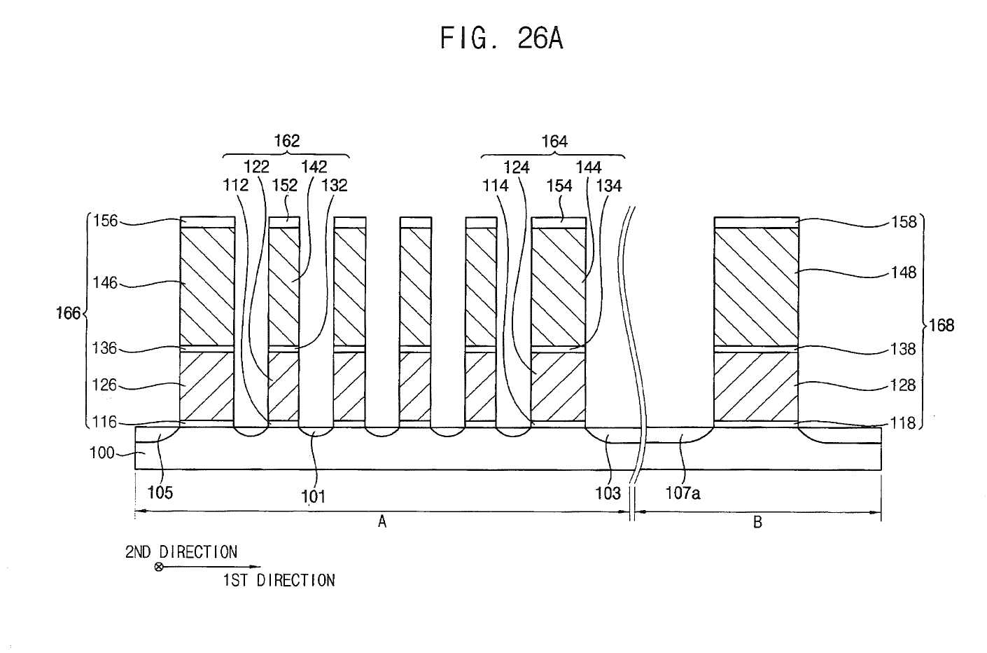

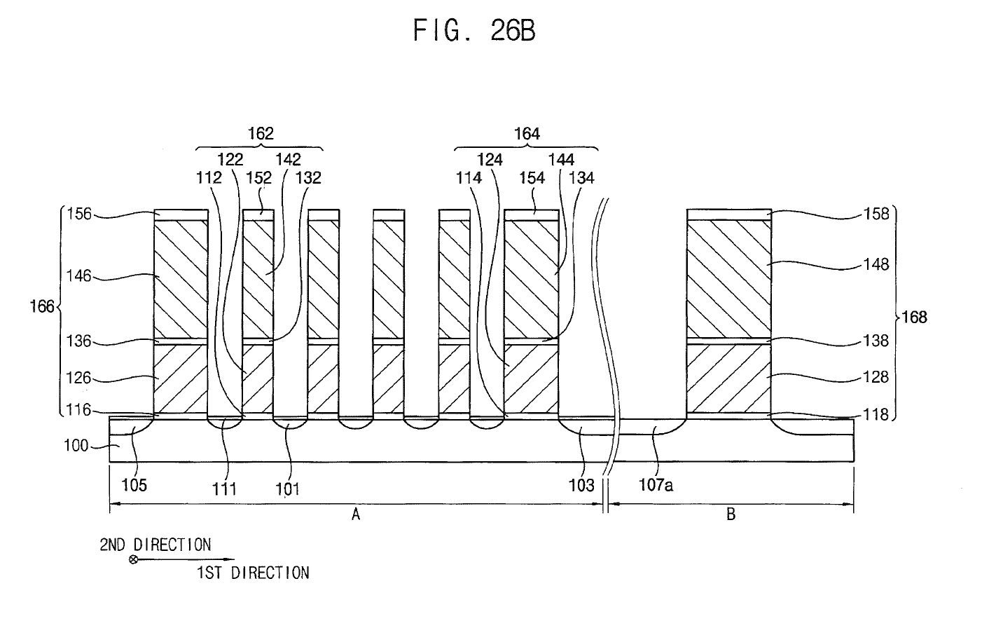

Referring to FIGS. 26A and 38A, the gate mask layer 150, the control gate layer 140, the dielectric layer 130, the floating gate layer 120 and the tunnel insulation layer 110 may be sequentially etched by a photolithography process to form first, second, third and fourth preliminary gate structures 162, 164, 166 and 168 on the substrate 100.

The first, second and third preliminary gate structures 162, 164 and 166 may be formed in the first region A. A plurality of first preliminary gate structure 162 may be formed between the first and second preliminary gate structures 164 and 166, and in example embodiments, 16 or 32 first preliminary gate structures 162 may be formed.

The fourth preliminary gate structure 168 may be formed in the second region B. In example embodiments, a plurality of fourth preliminary gate structures 168 may be formed in the second region B, wherein the density of the fourth preliminary gate structures 168 may be lower than those of the first through third preliminary gate structures 162, 164 and 166 in the first region A. That is, the distance between the plurality of fourth preliminary gate structures 168 may be larger than those between the first through third preliminary gate structures 162, 164 and 166.

The first through fourth preliminary gate structures 162, 164, 166 and 168 may include first through fourth tunnel insulation layer patterns 112, 114, 116 and 118, first through fourth floating gates 122, 124, 126 and 128, first through fourth dielectric layer patterns 132, 134, 136 and 138, first through fourth preliminary control gates 142, 144, 146 and 148, and first through fourth gate masks 152, 154, 156 and 158 sequentially stacked on the substrate 100, respectively.

In example embodiments, the tunnel insulation layer patterns 112, 114, 116 and 118 may be formed to have an island shape from each other on the substrate 100 in the active region. The floating gates 122, 124, 126 and 128 may be also formed to have an island shape from each other on the tunnel insulation layer patterns 112, 114, 116 and 118, respectively, in the active region. Each of the dielectric layer patterns 132, 134, 136 and 138, and each of the preliminary control gates 142, 144, 146 and 148 may be formed to extend in the second direction and sequentially formed on the floating gates 122, 124, 126 and 128 and the isolation layer 106.

Alternatively, referring to FIGS. 26B and 38B, the tunnel insulation layer patterns 112, 114, 116 and 118 may not have the island shape but extend in the first direction. In this case, portions of the tunnel insulation layers 112, 114, 116 and 118 that are not covered by the floating gates 122, 124, 126 and 128, respectively, may have a relatively small thickness. The portions of the tunnel insulation layer patterns 112, 114, 116 and 118 that are not covered by the floating gates 122, 124, 126 and 128 may be referred to as a fifth tunnel insulation layer 111.

Referring to FIGS. 26A and 38A again, first impurities may be implanted into the substrate 100 using the preliminary gate structures 162, 164, 166 and 168 as an ion implantation mask. Thus, first, second, third and fourth impurity regions 101, 103, 105 and 107a may be formed at upper portions of the substrate 100 adjacent to the preliminary gate structures 162, 164, 166 and 168, respectively. Particularly, the first impurity region 101 may be formed at upper portions of the substrate 100 adjacent to the first preliminary gate structures 162, the second impurity region 103 may be formed at an upper portion of the substrate 100 outside the second preliminary gate structure 164, the third impurity region 105 may be formed at an upper portion of the substrate 100 outside the third preliminary gate structure 166, and the fourth impurity region 107a may be formed at an upper portion of the substrate 100 adjacent to the fourth preliminary gate structure 168.

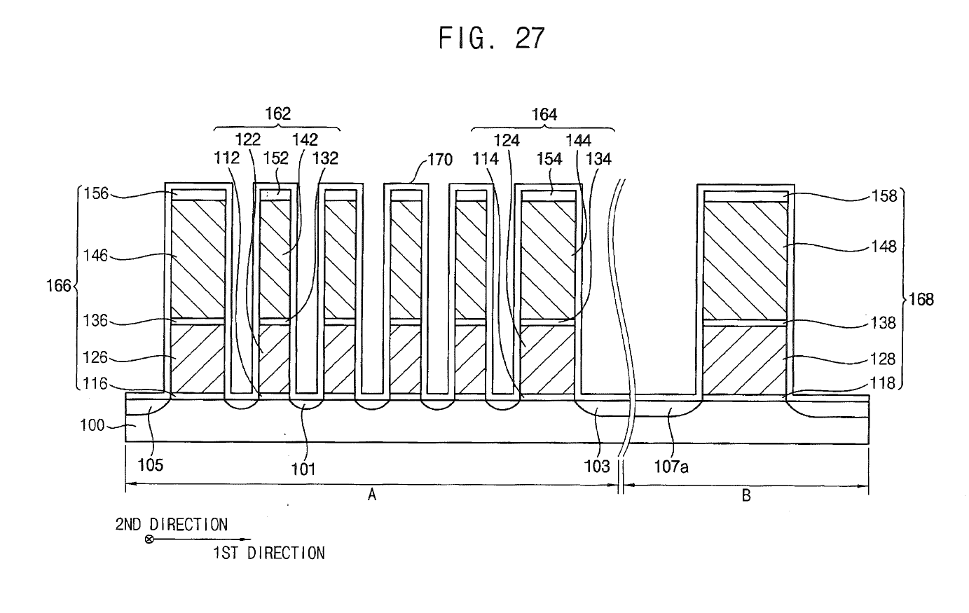

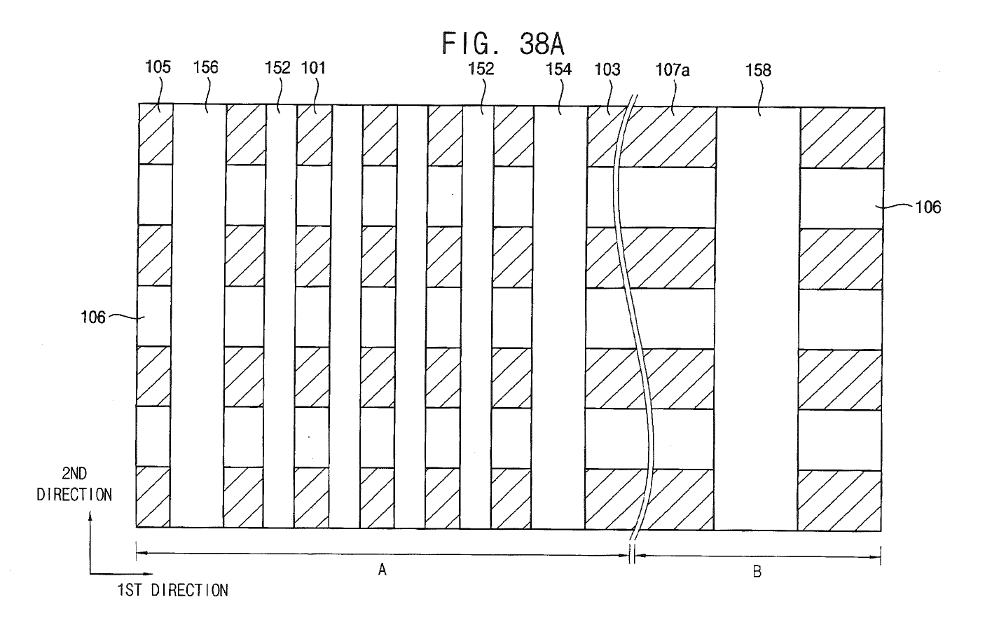

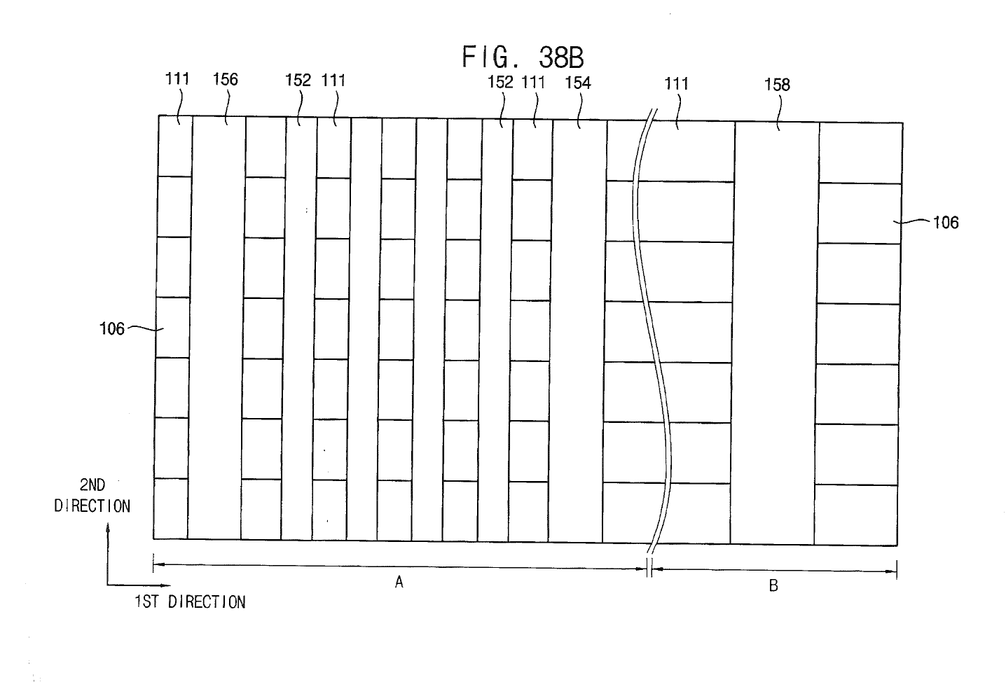

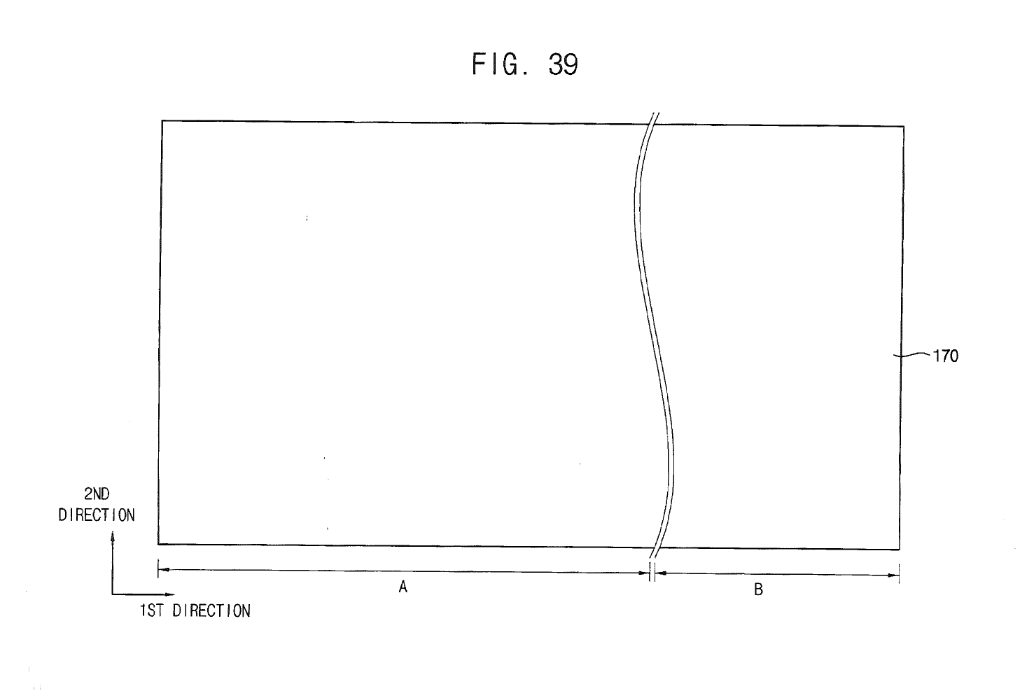

Referring to FIGS. 27 and 39, a first insulation layer 170 may be formed on the substrate 100 to cover the preliminary gate structures 162, 164, 166 and 168.

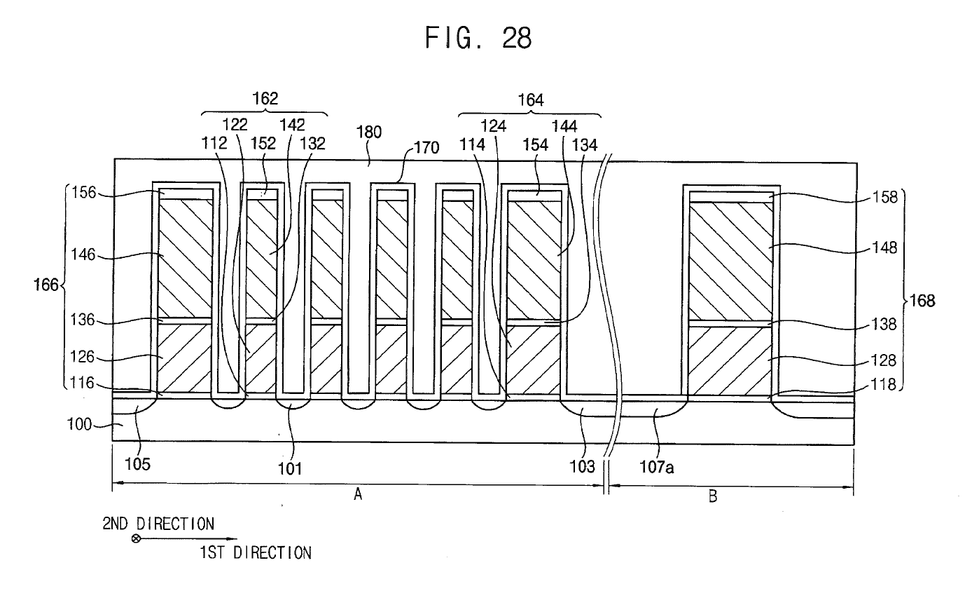

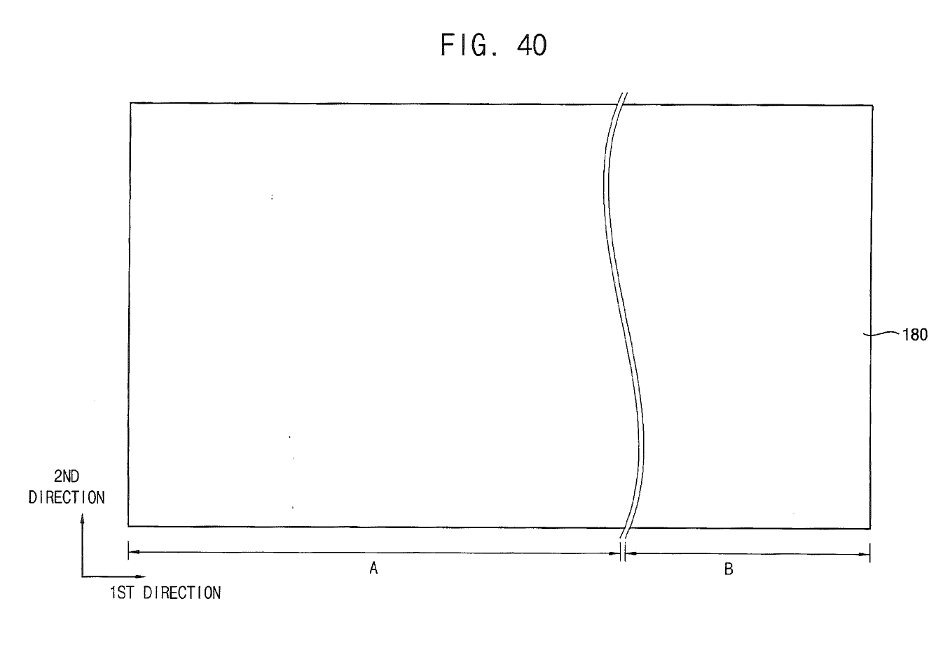

Referring to FIGS. 28 and 40, a sacrificial layer 180 may be formed on the first insulation layer 170 to fill spaces between preliminary gate structures 162, 164, 166 and 168.

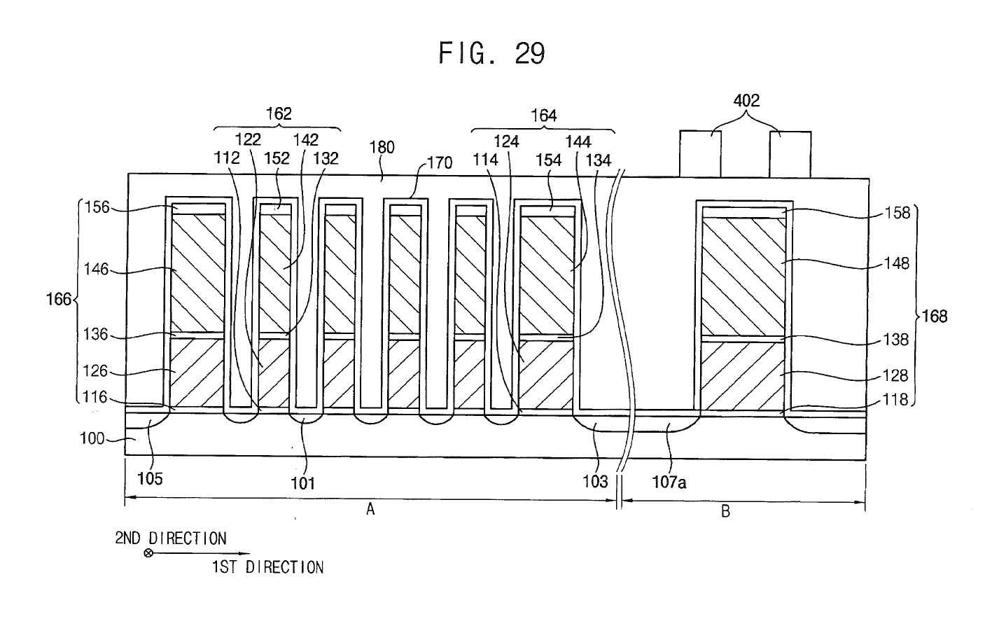

Referring to FIGS. 29 and 41, a first mask 402 partially overlapping the fourth preliminary gate structure 168 may be formed on the sacrificial layer 180. In example embodiments, the first mask 402 may overlap a lateral portion of the fourth preliminary gate structure 168 and a lateral portion of the first insulation layer 170 thereon, and may include two mask patterns each of which extends in the second direction. In example embodiments, the first mask 402 may include a photoresist pattern.

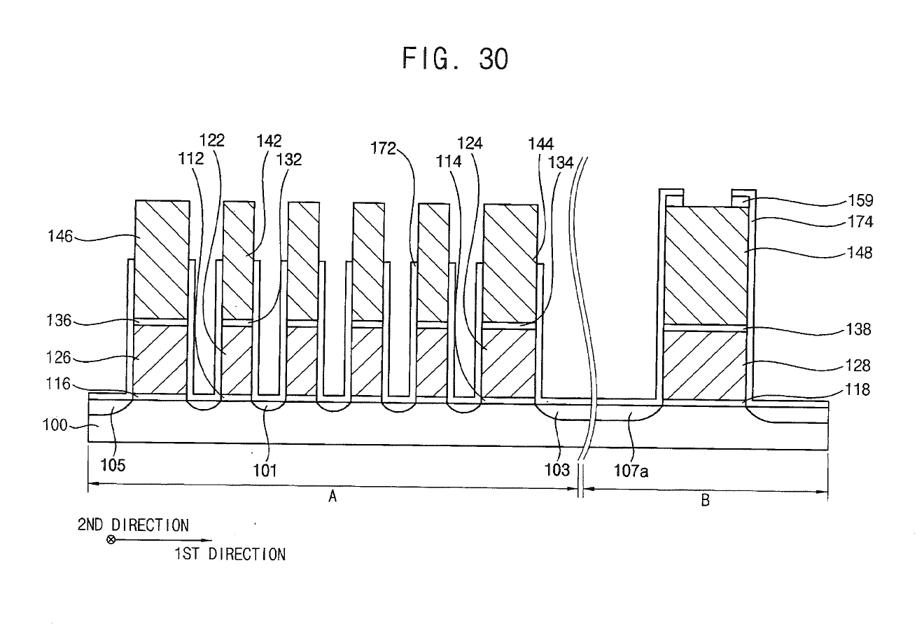

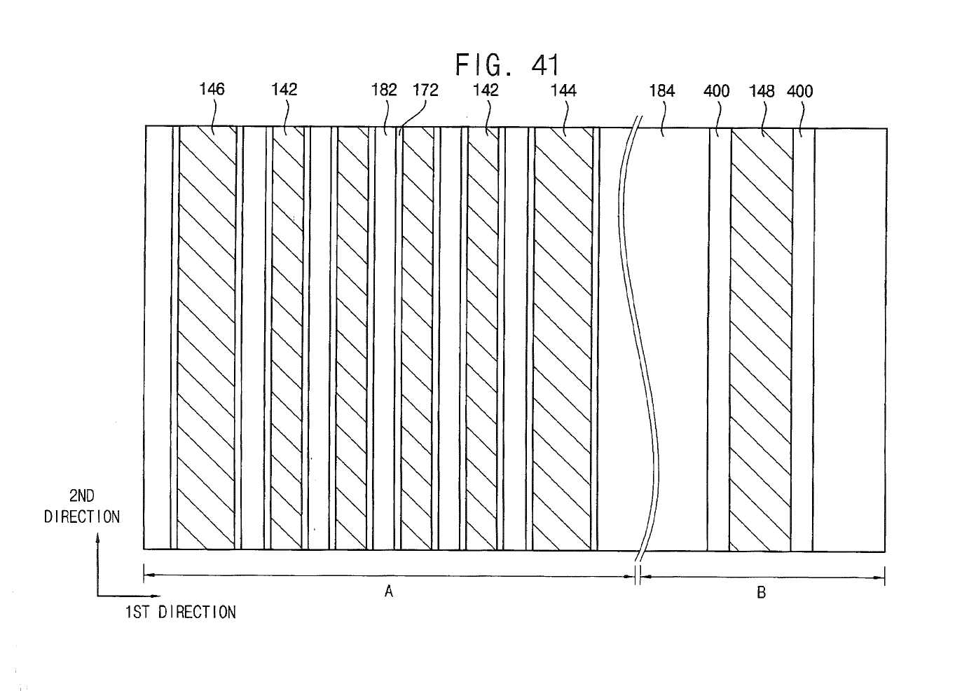

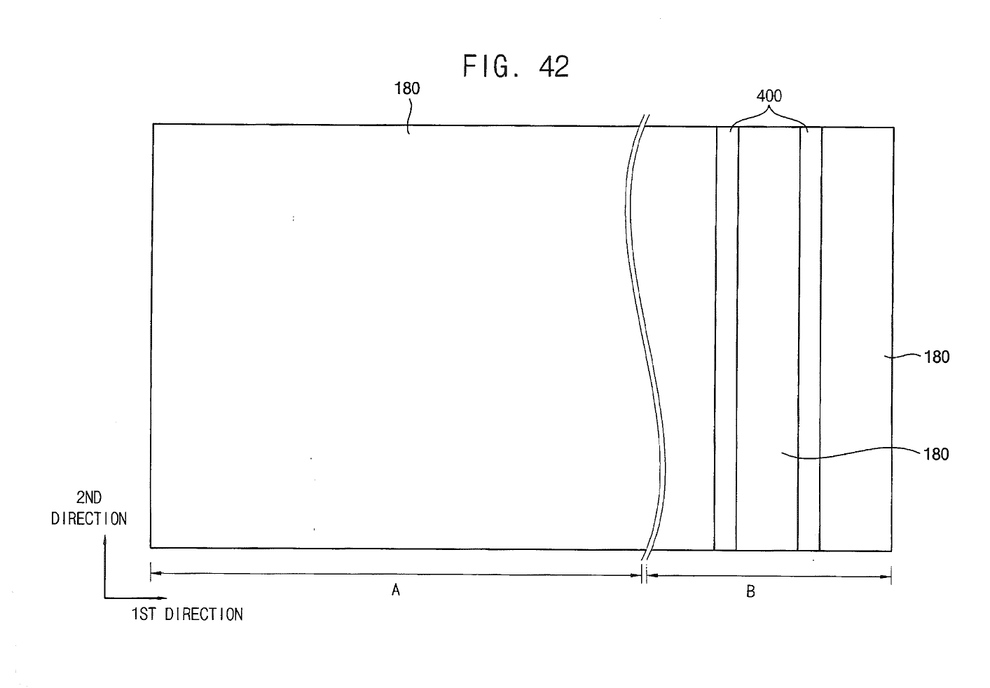

Referring to FIGS. 30 and 42, upper portions of the sacrificial layer 180 and the first insulation layer 170 may be removed using the first mask 402 as an etching mask. In example embodiments, the etching process may include an etch back process.

Due to the etching process, a first sacrificial layer pattern 182 and a first insulation layer pattern 172 may be formed, and the first through third gate masks 152, 154 and 156 may be removed. Thus, the first through third preliminary control gates 142, 144 and 146 may be partially exposed. In example embodiments, portions of the first through third preliminary control gates 142, 144 and 146 including doped polysilicon may be exposed. The first insulation layer pattern 172 may be formed on sidewalls of the first through third tunnel insulation layer patterns 112, 114 and 116, the first through third floating gates 122, 124 and 126 and the first through third dielectric layer patterns 132, 134 and 136, on a portion of sidewalls of the first through third preliminary control gates 142, 144 and 146, and on a top surface of the substrate 100 adjacent to the first through third preliminary gate structures 162, 164 and 166. Thus, the first insulation layer pattern 172 may have a top surface higher than those of the first through third dielectric layer patterns 132, 134 and 136.

In the etching process, upper portions of the sacrificial layer 180 and the first insulation layer 170 in the second region B may be removed to form a second sacrificial layer pattern 184 and a second insulation layer pattern 174, respectively, and the fourth gate mask 158 may be partially removed to form a fourth gate mask pattern 159. Thus, a top surface of the fourth preliminary control gate 148 may be exposed.

Particularly, the first mask 402 may overlap the lateral portions of the fourth preliminary gate structure 168 and the first insulation layer 170, and thus the fourth gate mask pattern 159 may be formed on an edge top surface of the fourth preliminary control gate 148, and the second insulation layer pattern 174 may be formed on sidewalls of the fourth tunnel insulation layer pattern 118, the fourth floating gate 128, the fourth dielectric layer pattern 138 and the fourth preliminary control gate 148, on a top surface and a sidewall of the fourth gate mask pattern 159, and on a top surface of the substrate 100 adjacent to the fourth preliminary gate structure 168.

The distance between the fourth preliminary gate structures 168 in the second region B may be larger than those between the first through third preliminary gate structures 162, 164 and 166 in the first region A, and thus a portion of the sacrificial layer 180 in the second region B may be removed more than that of the sacrificial layer 180 in the first region A in the etching process due to a loading effect. However, the first mask 402 may cover a portion of the sacrificial layer 180 on the sidewall of the fourth preliminary gate structure 168, and thus the second insulation layer pattern 174 may have a top surface higher than that of the first insulation layer pattern 172.

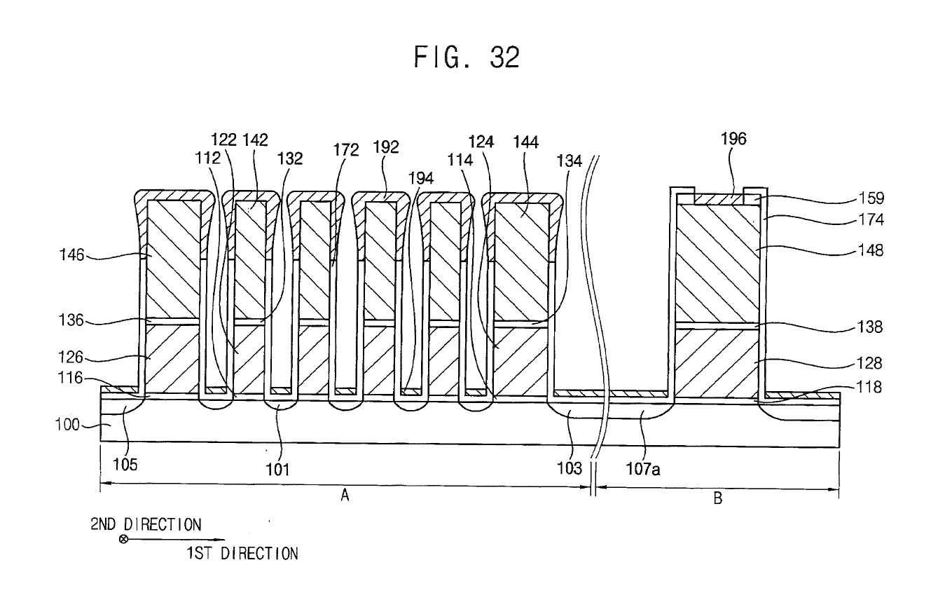

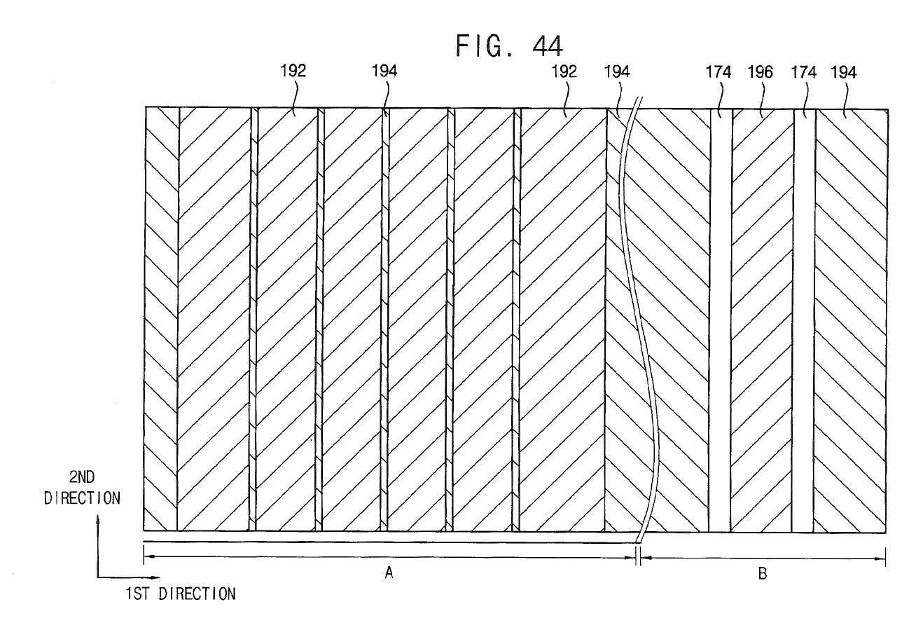

The first and second insulation layer patterns 172 and 174 may restrict regions for forming first and second conductive layers 192 and 196, respectively, (refer to FIGS. 32 and 44), and also restrict regions in which the first and second conductive layers 192 and 196 may be reacted with the preliminary gate structures 162, 164, 166 and 168. That is, the first and second insulation layer patterns 172 and 174 may serve as a reaction prevention layer.

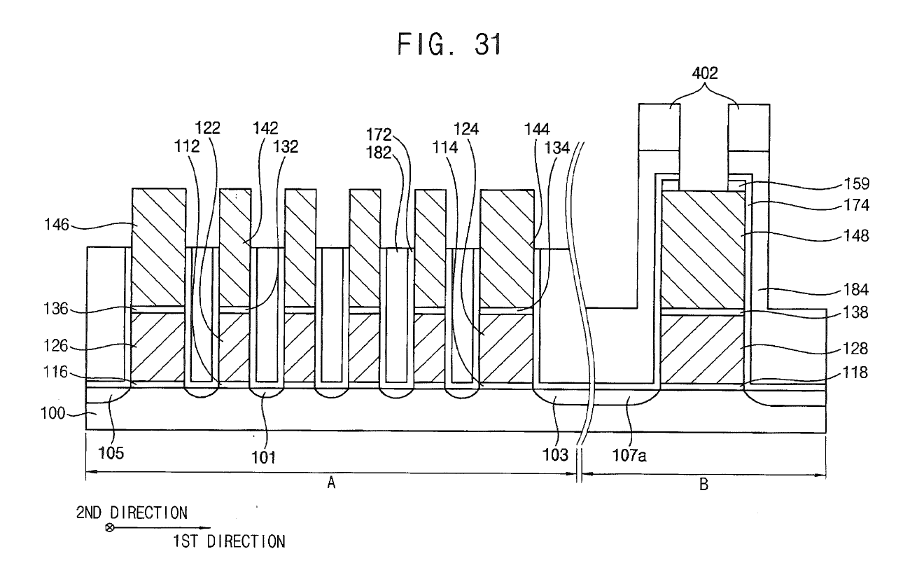

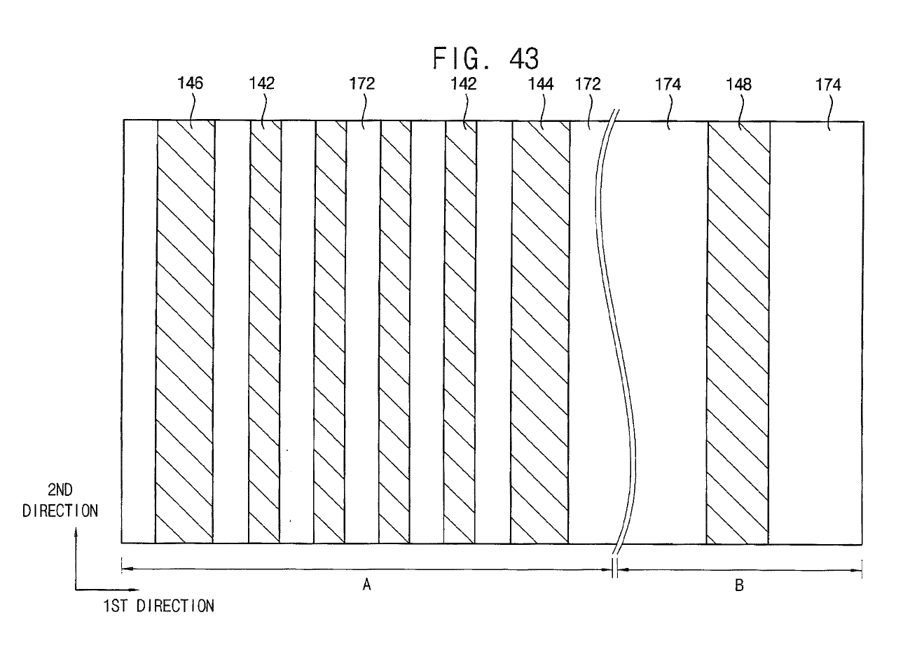

Referring to FIGS. 31 and 43, the first mask 402 and the first and second sacrificial layer patterns 182 and 184 may be removed. In example embodiments, the first mask 402 and the first and second sacrificial layer patterns 182 and 184 may be removed by an ashing process and/or a stripping process.

Referring to FIGS. 32 and 44, the first conductive layer 192 may be formed on exposed portions of the first through third preliminary control gates 142, 144 and 146, and the second conductive layer 196 may be formed on an exposed portion of the fourth preliminary control gate 148.

In example embodiments, the first and second conductive layers 192 and 196 may be formed using a metal, such as cobalt, nickel, etc. by a PVD process. The first and second conductive layers 192 and 196 may be formed on the exposed portions of the preliminary control gates 142, 144, 146 and 148, and a third conductive layer 194 may be further formed on portions of the first and second insulation layer patterns 172 and 174 on the substrate 100. Particularly, the first conductive layer 192 may be formed on top surfaces and portions of the sidewalls of the first through third preliminary control gates 142, 144 and 146, and the second conductive layer 196 may be formed on a portion of the top surface of the fourth preliminary control gate 148.

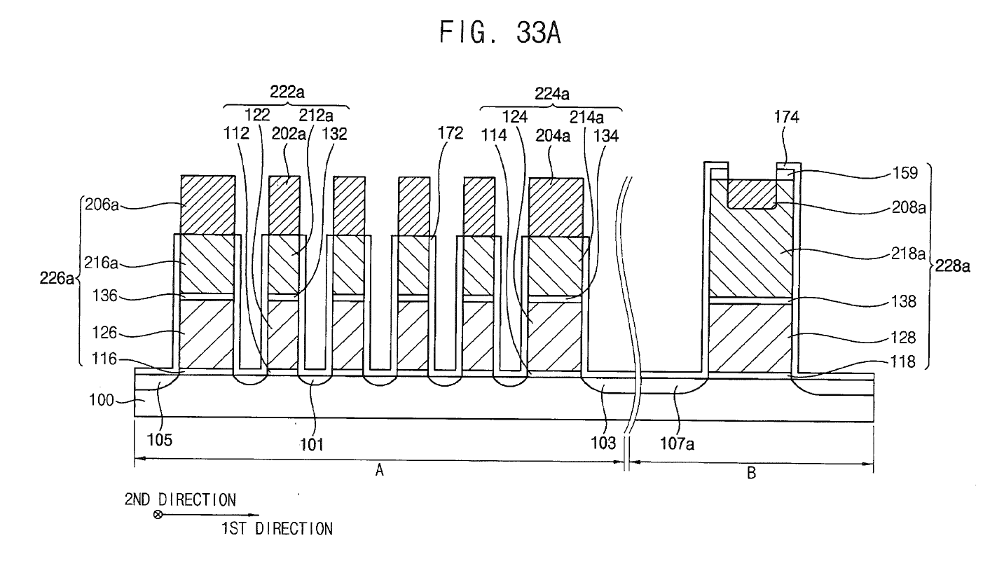

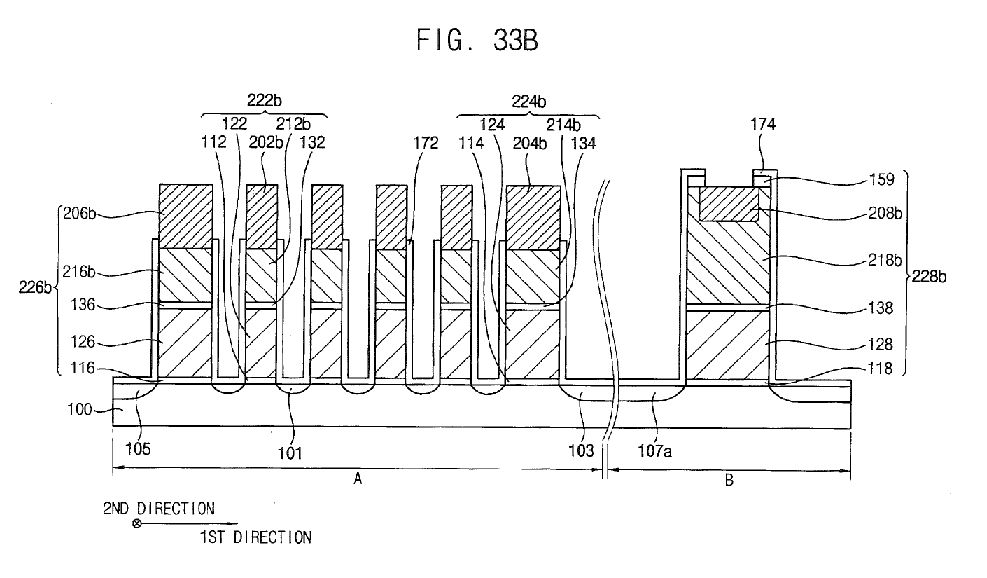

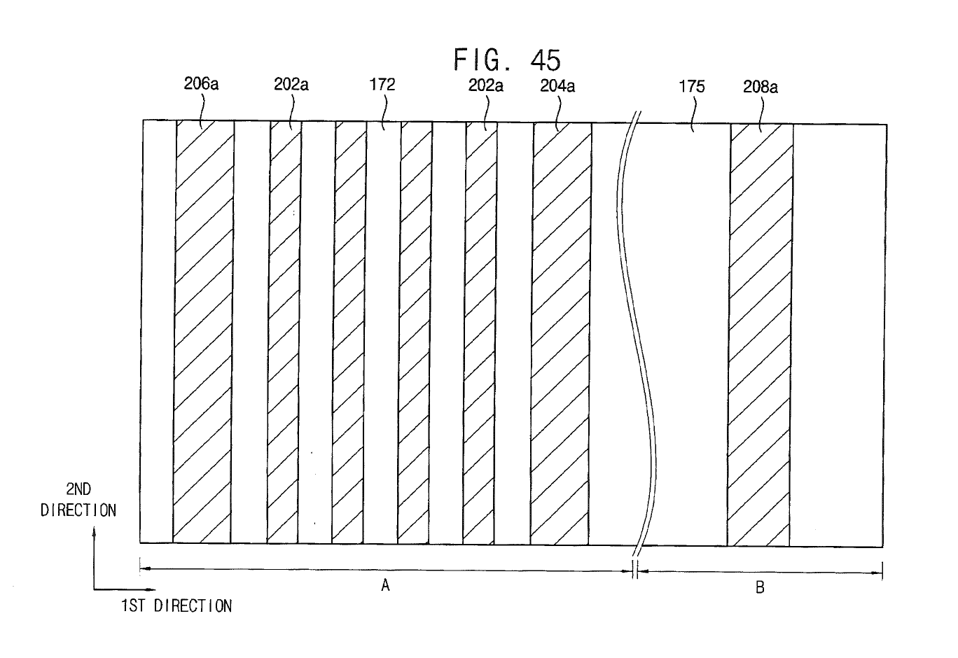

Referring to FIGS. 33A and 45, the exposed portions of the preliminary control gates 142, 144, 146 and 148 may be reacted with the first and second conductive layers 192 and 196 to form first, second, third and fourth upper conductive patterns, 202a, 204a, 206a and 208a, respectively. Portions of the preliminary control gates 142, 144, 146 and 148 that are not reacted with the first and second conductive layers 192 and 196 may be defined as first, second, third and fourth lower conductive patterns 212a, 214a, 216a and 218a, respectively. The first through fourth upper conductive patterns 202a, 204a, 206a and 208a together with the first through fourth lower conductive patterns 212a, 214a, 216a and 218a may define first through fourth control gates, respectively.

In example embodiments, portions of the preliminary control gates 142, 144, 146 and 148 including doped polysilicon may be reacted with the first and second conductive layers 192 and 196 to form a metal silicide layer. The silicidation process may be performed by a heat treatment.

When the first conductive layer 192 includes cobalt, a cobalt silicide layer may be formed to have a bottom surface substantially coplanar with a top surface of the first insulation layer pattern 175. When the second conductive layer 196 also includes cobalt, a cobalt silicide layer may be formed to have a width substantially the same as that of the exposed portion of the fourth preliminary control gate 148. That is, portions of the preliminary control gates 142, 144, 146 and 148 may be reacted with the first and second conductive layers 192 and 196 to form the upper conductive patterns 202a, 204a, 206a and 208a.

Alternatively, when the first conductive layer 192 includes nickel, referring to FIG. 33B, a nickel silicide layer may be formed to have a bottom surface lower than the top surface of the first insulation layer pattern 175. When the second conductive layer 196 also includes nickel, a nickel silicide layer may be formed to have a width larger than that of the exposed portion of the fourth preliminary control gate 148. Thus, fifth, sixth, seventh and eighth upper conductive patterns 202b, 204b, 206b and 208b may be formed. In this case, portions of the first through fourth preliminary control gates 142, 144, 146 and 148 that are not reacted with the first and second conductive layers 192 and 196 may be referred to as fifth, sixth, seventh and eighth lower conductive patterns 212b, 214b, 216b and 218b, respectively. The fifth through eighth upper conductive patterns 202b, 204b, 206b and 208b together with the fifth through eighth lower conductive patterns 212b, 214b, 216b and 218b may define fifth through eighth control gates, respectively.

In the present embodiment, metal of the first and second conductive layers 192 and 196 may be reacted with silicon of the preliminary control gates 142, 144, 146 and 148 to form a metal silicide layer, however, other types of reaction may occur.

Referring to FIGS. 33A and 45 again, the portions of the first and second conductive layers 192 and 196 that are not reacted with the preliminary control gates 142, 144, 146 and 148 and the third conductive layer 194 may be removed, e.g., by a stripping process.

Thus, first, second, third and fourth gate structures 222a, 224a, 226a and 228a may be formed on the substrate 100. The first through third gate structures 222a, 224a and 226a may include the first through third tunnel insulation layer patterns 112, 114 and 116, the first through third floating gates 122, 124 and 126, the first through third dielectric layer patterns 132, 134 and 136, the first through third lower conductive patterns 212a, 214a and 216a, and the first through third upper conductive patterns 202a, 204a and 206a, respectively. The fourth gate structure 228a may include the fourth tunnel insulation layer pattern 118, the fourth floating gate 128, the fourth dielectric layer pattern 138, the fourth lower conductive pattern 218a, the fourth upper conductive pattern 208a and the fourth gate mask pattern 159.

The first, second and third control gates included in the first, second and third gate structures 222a, 224a and 226a, respectively, may be formed in the first region A and serve as a word line, a GSL and a SSL, respectively.

The first insulation layer pattern 172 may be formed on sidewalls of the first through third tunnel insulation layer patterns 112, 114 and 116, the first through third floating gates 122, 124 and 126, the first through third dielectric layer patterns 132, 134 and 136, and the first through third lower conductive patterns 212a, 214a and 216a, and the second insulation layer pattern 174 may be formed on sidewalls of the fourth tunnel insulation layer pattern 118, the fourth floating gate 128, the fourth dielectric layer pattern 138 and the fourth lower conductive pattern 218a, and on a top surface and a sidewall of the fourth gate mask pattern 159.

Alternatively, referring to FIG. 33B, fifth, sixth, seventh and eighth gate structures 222b, 224b, 226b and 228b may be formed on the substrate 100. The fifth through seventh gate structures 222b, 224b and 226b may include the first through third tunnel insulation layer patterns 112, 114 and 116, the first through third floating gates 122, 124 and 126, the first through third dielectric layer patterns 132, 134 and 136, the fifth through seventh lower conductive patterns 212b, 214b and 216b, and the fifth through seventh upper conductive patterns 202b, 24b and 206b, respectively. The eighth gate structure 228b may include the fourth tunnel insulation layer pattern 118, the fourth floating gate 128, the fourth dielectric layer pattern 138, the eighth lower conductive pattern 218b, the eighth upper conductive pattern 208b, and the fourth gate mask pattern 159. The fifth, sixth and seventh control gates included in the fifth, sixth and seventh gate structures 222b, 224b and 226b, respectively, may be formed in the first region A and serve as a word line, a GSL and a SSL, respectively.

The first insulation layer pattern 172 may be formed on the sidewalls of the first through third tunnel insulation layer patterns 112, 114 and 116, the first through third floating gates 122, 124 and 126, the first through third dielectric layer patterns 132, 134 and 136, and the fifth through seventh lower conductive patterns 212b, 214b and 216b, and on portions of the sidewalls of the fifth through seventh upper conductive patterns 202b, 204b and 206b. The second insulation layer pattern 174 may be formed on the sidewalls of the fourth tunnel insulation layer pattern 118, the fourth floating gate 128, the fourth dielectric layer pattern 138 and the fourth lower conductive pattern 218a, and on a top surface and a sidewall of the fourth gate mask pattern 159.

Hereinafter, only the case in which the first through fourth gate structures 222a, 224a, 226a and 228a are formed on the substrate 100 is illustrated.

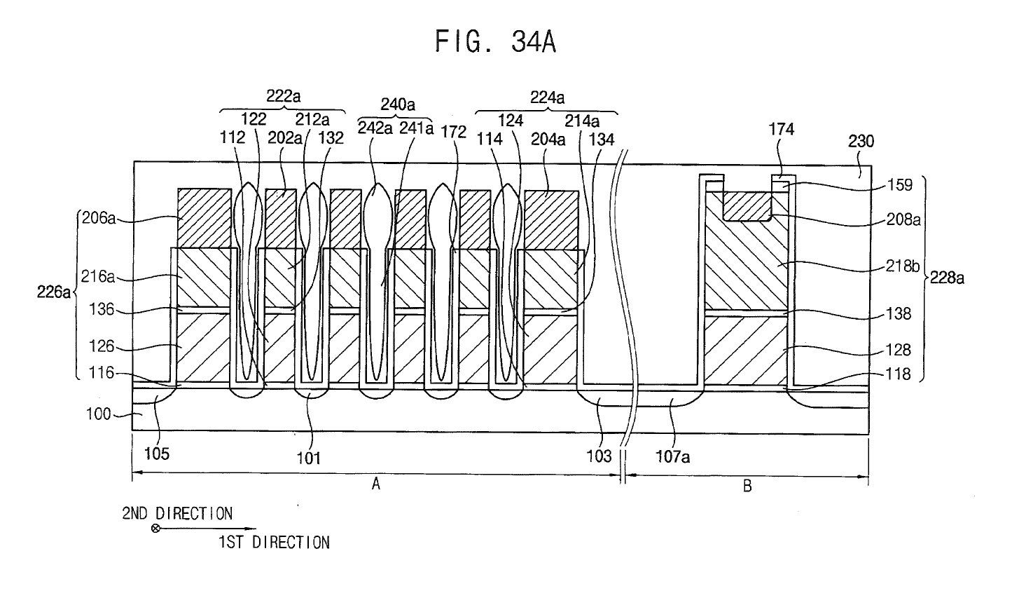

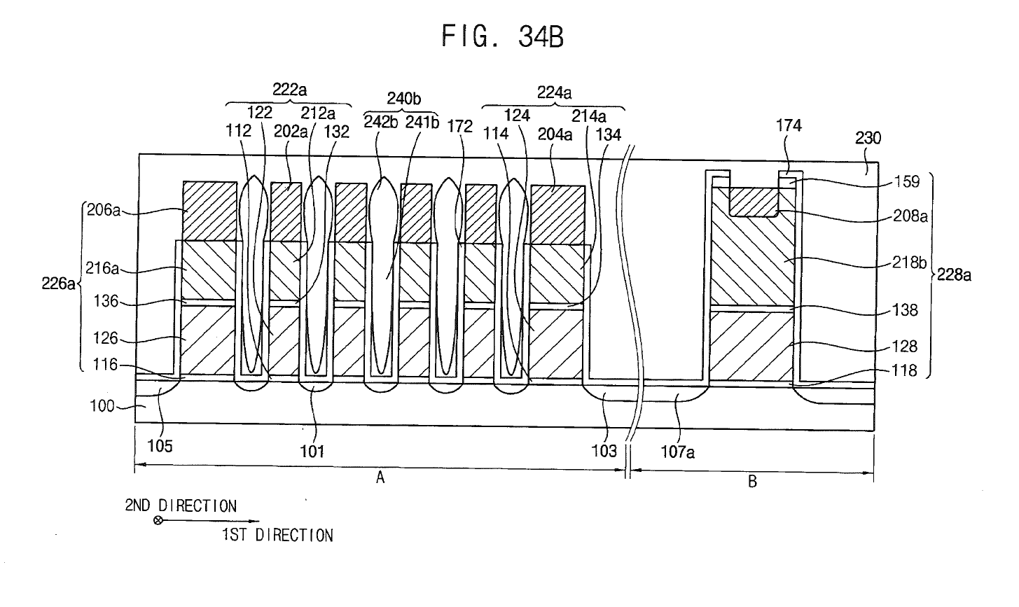

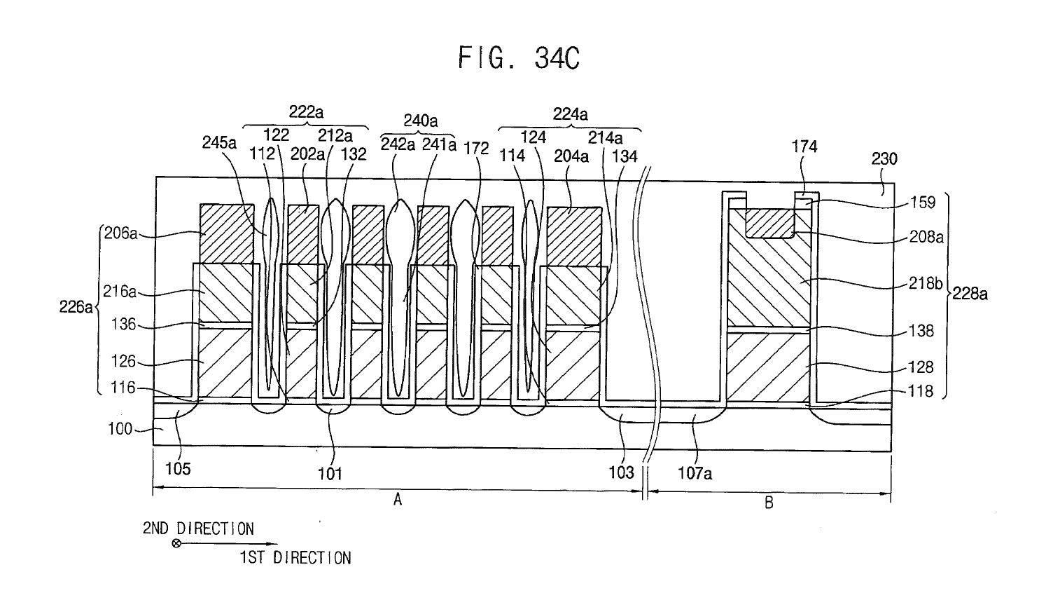

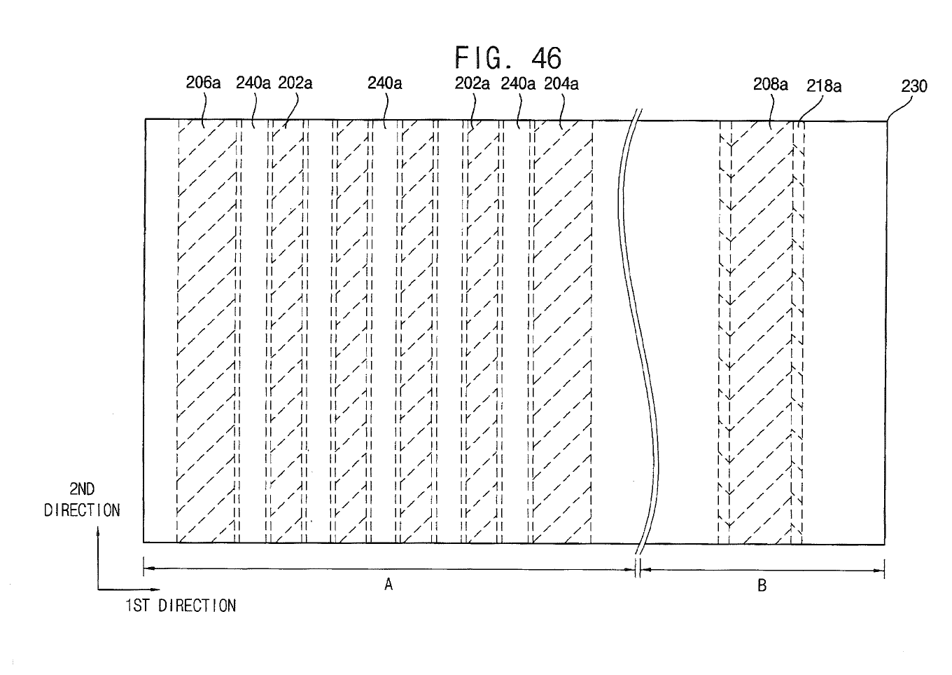

Referring to FIGS. 34A and 46, a third insulation layer 230 may be formed on the substrate 100 to cover the gate structures 222a, 224a, 226a and 228a and the first and second insulation layer patterns 172 and 174. The third insulation layer 230 may not completely fill spaces between the gate structures 222a, 224a, 226a and 228a. Thus, a first air gap 240a may be formed between the first, second and third gate structures 222a, 224a and 226a. In example embodiments, the first air gap 240a may be formed to extend in the second direction, and thus the air gap 240a may be referred to as a first air tunnel.

In example embodiments, the first air gap 240a may be formed to have a top surface higher than those of the first, second and third gate structures 222a, 224a and 226a.

In example embodiments, the first air gap 240a may be formed to include a lower portion 241a having a first width and an upper portion 242a having a second width larger than the first width. In an example embodiment, the lower portion 241a of the first air gap 240a may have a linear shape or a bar shape extending in a direction perpendicular to a top surface of the substrate 100, and the upper portion 242a of the first air gap 240a may have an oval shape of which a top surface is sharp. That is, when the third insulation layer 230 is formed, the lower portion 214a having a linear shape or a bar shape having a relatively narrow width may be formed in an area narrowed by the first insulation layer pattern 172 on the sidewall of the first through third gates 222a, 224a and 226a, while the upper portion 242a having an oval shape having a relatively wide width may be formed in an area in which the first insulation layer pattern 172 is not formed. In this case, as the first insulation layer pattern 172 has a thicker thickness, the width difference between the upper portion 242a and the lower portion 241 a may be larger.

The first air gap 240a may be defined only by the third insulation layer 230. That is, the third insulation layer 230 may be formed to cover not only the gate structures 222a, 224a, 226a and 228a but also the first insulation layer pattern 172, so that the boundary of the first air gap 240a may be defined only by the third insulation layer 230.

Alternatively, referring to FIG. 34B, a second air gap 240b defined by the third insulation layer 230 and the first insulation layer pattern 172 may be formed. That is, the third insulation layer 230 may be formed to cover the gate structures 222a, 224a, 226a and 228a and a portion of the first insulation layer pattern 172, so that the boundary of the second air gap 240b may be defined by both of the third insulation layer 230 and the first insulation layer pattern 172. In example embodiments, the second air gap 240b may be formed to extend in the second direction, and thus may be also referred to as a second air tunnel. The second air gap 240b may also include a lower portion 241b and an upper portion 242b.

Referring to FIG. 34C, a third air gap 245a having a different size or shape from that of the first air gap 240a may be formed between the first gate structure 222a and the second gate structure 224a or between the first gate structure 222a and the third gate structure 226a. In this case, the first air gap 240a may be formed only between the first gate structures 222a.

Particularly, when the third insulation layer 230 is deposited between an outermost of the first gate structure 222a and the second gate structure 224a or the third gate structure 226a, which are relatively more distant from the first gate structure 222a, the third insulation layer 230 may be formed at a wider space than when the third insulation layer 230 is deposited between the first gate structures 222a, which are relatively less distant from each other. Thus, the third insulation layer 230 may be formed to have a relatively thick thickness between the outermost of the first gate structure 222a and the second gate structure 224a or the third gate structure 226a, and the third air gap 245a may have a width smaller than or equal to that of the first air gap 240a.

When the third insulation layer 230 is formed using MTO, the size difference between the first air gap 240a and the third air gap 245a may be relatively large.

Hereinafter, the semiconductor device including the third insulation layer 230 only having the first air gap 240a therein is illustrated.

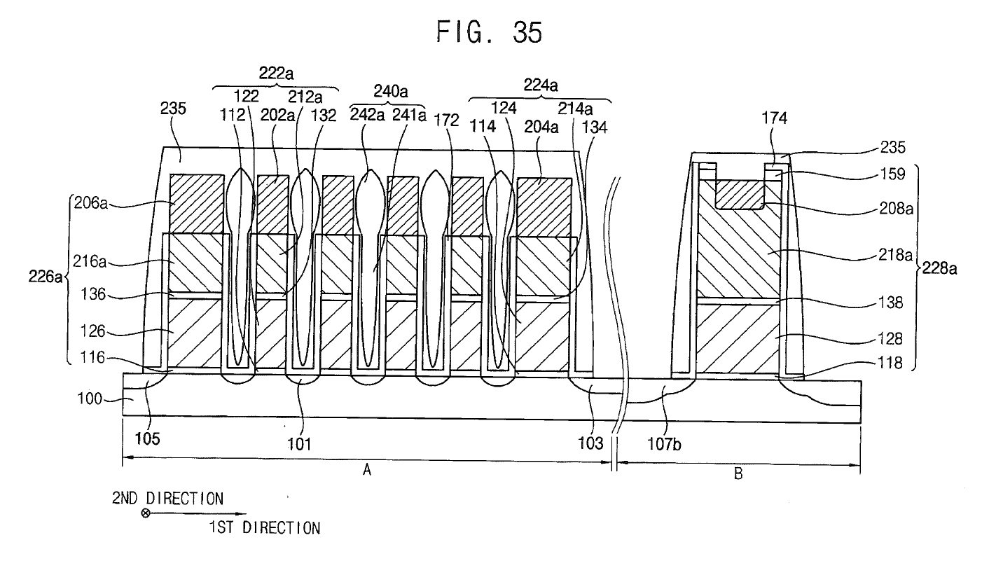

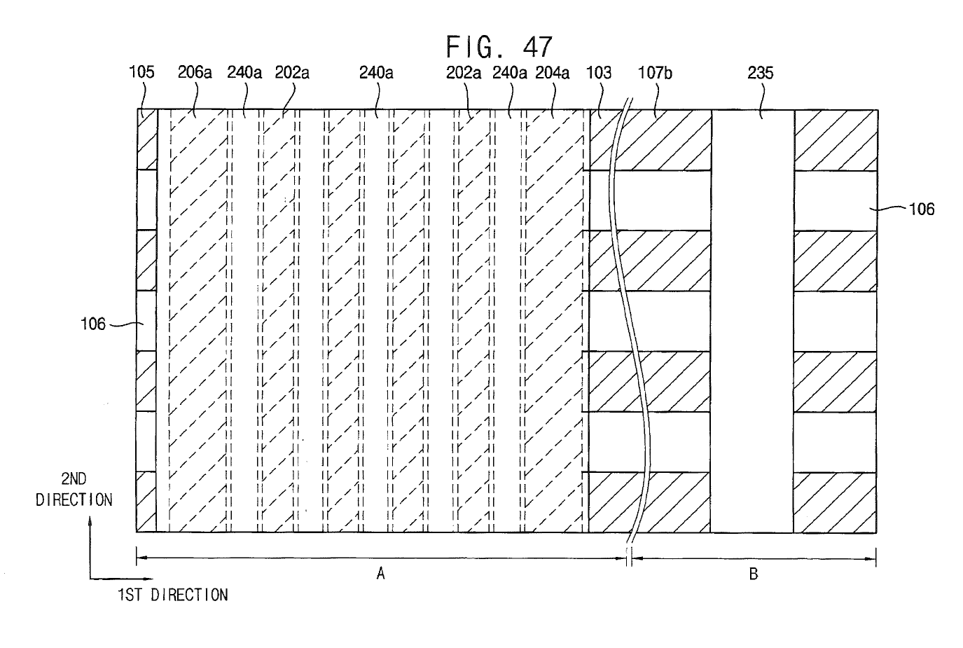

Referring to FIGS. 35 and 47, the third insulation layer 230 and the first and second insulation layer patterns 172 and 174 may be partially removed by a photolithography process to expose the second, third and fourth impurity regions 103, 105 and 107a. Thus, a third insulation layer pattern 235 covering the first through fourth gate structures 222a, 224a, 226a and 228a and the first and second insulation layer patterns 172 and 174 may be formed.

Second impurities may be implanted into the substrate 100 using the gate structures 222a, 224a, 226a and 228a and the third insulation layer pattern 235 as an ion implantation mask. Thus, a fifth impurity region 107b having an LDD structure may be formed at an upper portion of the substrate 100 adjacent to the fourth gate structure 228a. The second impurities may be also implanted into the second and third impurity regions 103 and 105.

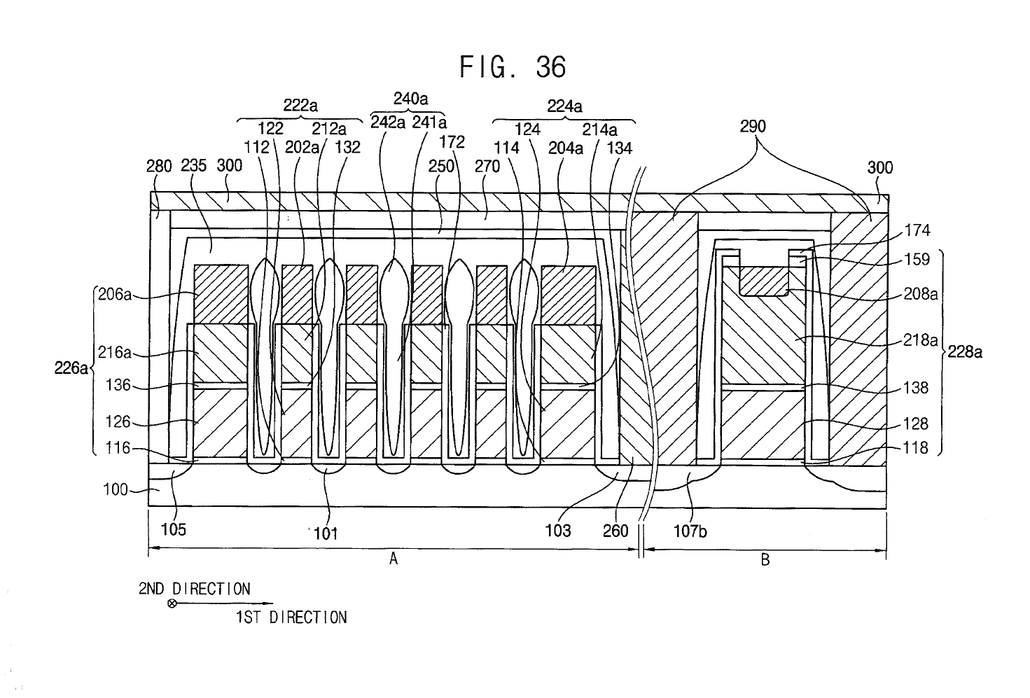

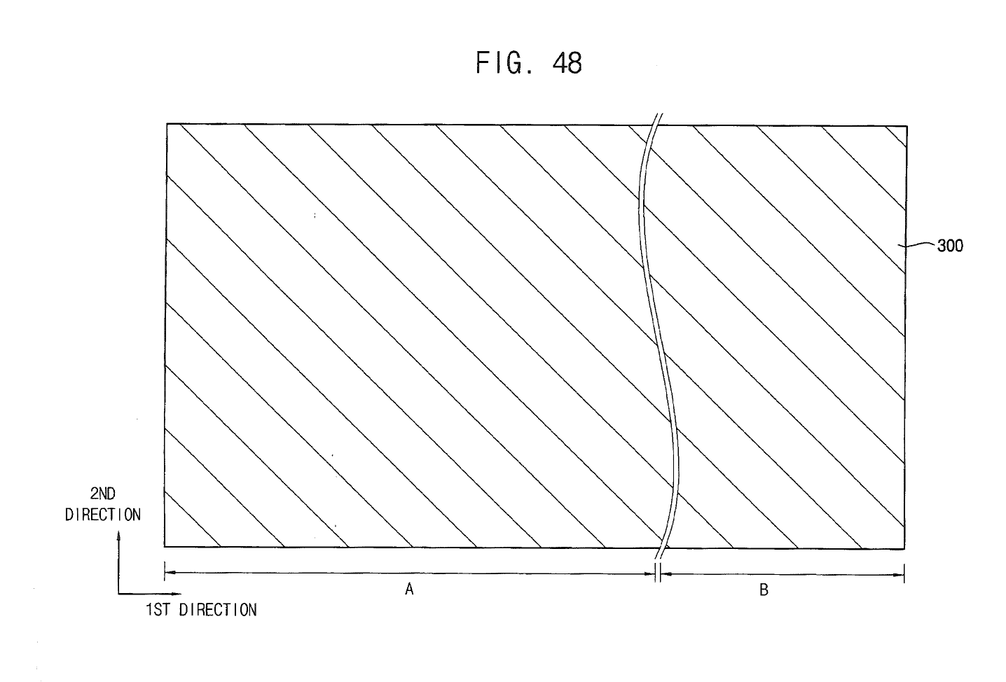

Referring to FIGS. 36 and 48, a first insulating interlayer 250 may be formed on the substrate 100 to cover the third insulation layer pattern 235. The first insulating interlayer 250 may be formed using an oxide such as BPSG, USG, SOG, etc.

A CSL 260 may be formed on the second impurity region 103 through the first insulating interlayer 250. The CSL 260 may be formed using doped polysilicon, a metal or a metal silicide.

A second insulating interlayer 270 may be formed on the first insulating interlayer 250 and the CSL 260. The second insulating interlayer 270 may be formed using an oxide such as BPSG, USG, SOG, etc.

A bit line contact 280 may be formed on the third impurity region 105 through the first and second insulating interlayers 250 and 270. The bit line contact 280 may be formed using a metal, doped polysilicon, etc. A plug 290 may be formed on the fifth impurity region 107b through the first and second insulating interlayers 250 and 270.

A bit line 300 may be formed on the second insulating interlayer 270 to be electrically connected to the bit line contact 280. The bit line 300 may be formed to extend in the first direction. The bit line 300 may be formed using a metal, doped polysilicon, etc. The bit line 300 may be also formed in the second region B to be electrically connected to the plug 290.

By the above processes, the semiconductor device may be manufactured. In FIGS. 25 to 48, a NAND flash memory device is illustrated, however, the scope of the present inventive concept may be also applied to other types of semiconductor device such as a NOR flash memory device, a DRAM device, etc.

In the method of manufacturing the semiconductor device, the fourth preliminary gate structures 168 in the second region B may have a density smaller than that of the first through third preliminary gate structures 162, 164 and 166 in the first region A. Thus, if the sacrificial layer 180 and the first insulation layer 170 are etched without the first mask 402, portions of the sacrificial layer 180 and the first insulation layer 170 in the second region B may be removed more than those of the sacrificial 180 and the first insulation layer 170 in the first region A due to the loading effect. Thus, the second insulation layer pattern 174 may not sufficiently cover the sidewall of the fourth dielectric layer pattern 138, and further may not cover the sidewalls of the fourth floating gate 128 and the fourth tunnel insulation layer pattern 118 and the top surface of the substrate 100 adjacent to the fourth preliminary gate structure 168. In that case, when a conductive layer is formed on portions of the fourth preliminary gate structure 168 and the substrate 100 that are not covered by the second insulation layer pattern 174, and a silicidation process is performed thereon, the fourth control gate, the fourth floating gate 128 and the fourth impurity region 107a of the substrate 100 may be electrically connected to each other, i.e., may become short. However, according to example embodiments, the first mask 402 may be formed on the sacrificial layer 180 and protect the sidewall of the fourth preliminary gate structure 168 and the portion of the first insulation layer 170 on the portion of the substrate 100 adjacent to the fourth preliminary gate structure 168. Thus, the above short problem may not occur.

The semiconductor device may include the first through fourth gate structures 222a, 224a, 226a and 228a, each of which extends in the second direction, spaced apart from each other in the first direction. The first insulation layer pattern 172 may be formed on the sidewalls of the first through third gate structures 222a, 224a and 226a in the first region A, and on the top surface of the substrate 100 adjacent thereto. The second insulation layer pattern 174 may be formed on the sidewall and a portion of the top surface of the fourth gate structure 228a and on a top surface of the substrate 100 adjacent thereto. Additionally, the semiconductor device may include the third insulation layer pattern 235 that may cover the first through fourth gate structures 222a, 224a, 226a and 228a and the first and second insulation layer patterns 172 and 174 and have the first air gap 240a extending in the second direction between the first through third gate structures 222a, 224a and 226a.

The first through third gate structures 222a, 224a and 226a may include the first through third tunnel insulation layer patterns 112, 114 and 116, the first through third floating gates 122, 124 and 126, the first through third dielectric layer patterns 132, 134 and 136, and the first through third control gates, respectively, sequentially stacked on the substrate 100. The fourth gate structure 228a may include the fourth tunnel insulation layer pattern 118, the fourth floating gate 128, the fourth dielectric layer pattern 138, the fourth control gate, and the fourth gate mask pattern 159 sequentially stacked on the substrate 100. The first through fourth control gates may include first through fourth lower conductive patterns 212a, 214a, 216a and 218a, and the first through fourth upper conductive patterns 202a, 204a, 206a and 208a, respectively.

The first insulation layer pattern 172 may cover at least the sidewalls of the first through third tunnel insulation layer patterns 112, 114 and 116, the first through third floating gates 122, 124 and 126, and the first through third dielectric layer patterns 132, 134 and 136. The second insulation layer pattern 174 may cover the sidewalls of the fourth tunnel insulation layer pattern 118, the fourth floating gate 128, the fourth dielectric layer pattern 138 and the fourth control gate, and the sidewall and the top surface of the fourth gate mask 159.

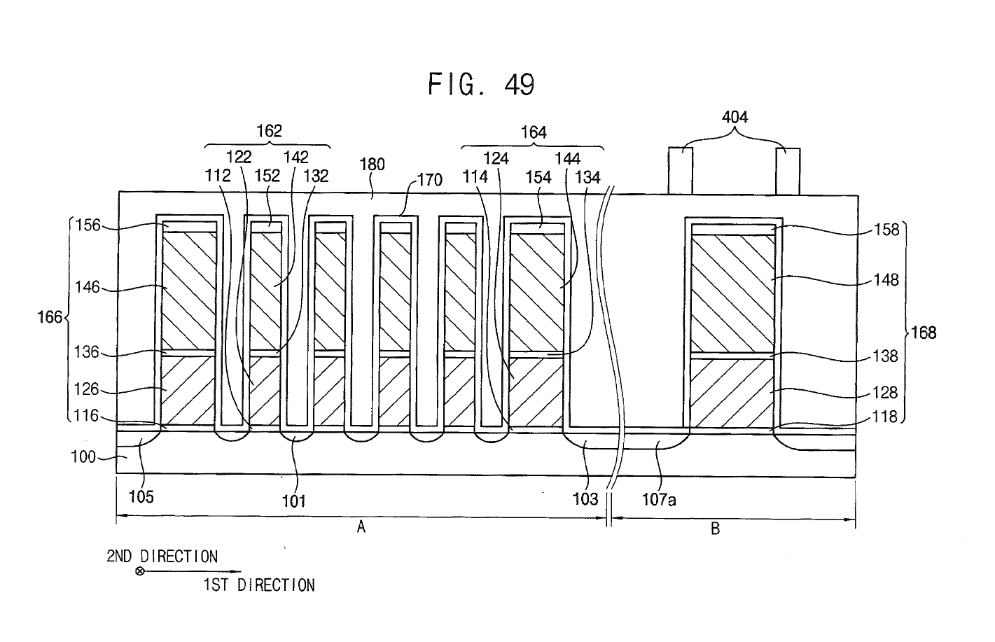

FIGS. 49 to 54 are cross-sectional views illustrating a method of manufacturing a semiconductor device in accordance with still other example embodiments. The method of manufacturing the semiconductor device may be substantially the same as or similar to that illustrated with reference to FIGS. 25 to 48 except for a mask and an insulation layer pattern. Thus, like reference numerals refer to like elements, and only the difference is illustrated hereinafter.

First, the processes illustrated with reference to FIGS. 25 to 28 may be performed.

Referring to FIG. 49, a second mask 404 that may not overlap the fourth preliminary gate structure 168 may be formed on the sacrificial layer 180. In example embodiments, the second mask 404 may include two mask patterns each of which may not overlap the fourth preliminary gate structure 168 but overlap a portion of the first insulation layer 170 on the sidewall of the fourth preliminary gate structure 168, and extends in the second direction.

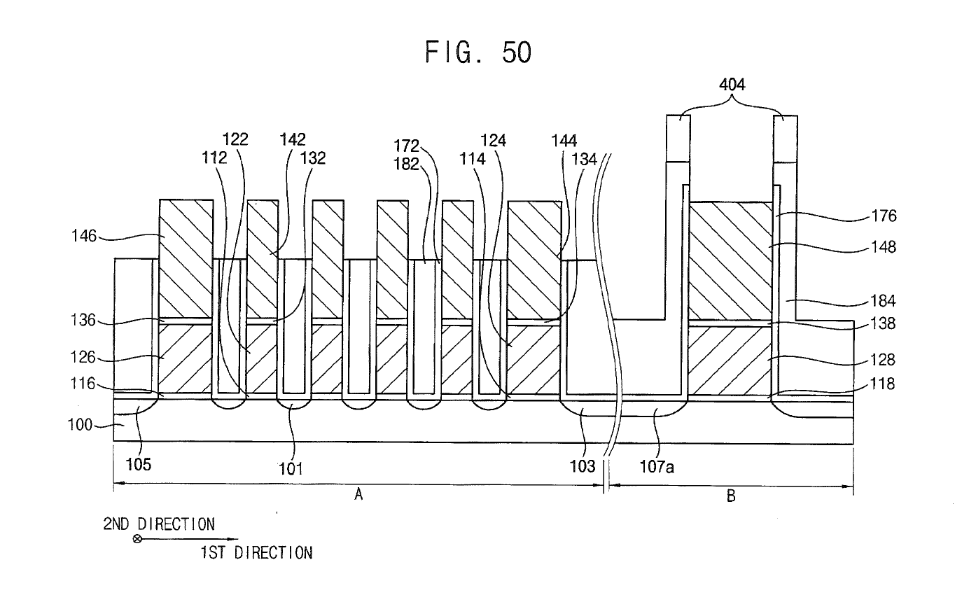

Referring to FIG. 50, upper portions of the sacrificial layer 180 and the first insulation layer 170 in the first region A may be removed using the second mask 404 as an etching mask to form a first sacrificial layer pattern 182 and a first insulation layer pattern 172, respectively. In the etching process, the first through third gate masks 152, 154 and 156 may be removed. Thus, upper portions of the first through third preliminary control gates 142, 144 and 146 may be exposed.

In the etching process, upper portions of the sacrificial layer 180 and the first insulation layer 170 in the second region B may be also removed to form a second sacrificial layer pattern 184 and a fourth insulation layer pattern 176, respectively. Thus, a top surface of the fourth preliminary control gate 148 may be exposed. The fourth insulation layer pattern 176 may cover sidewalls of the fourth tunnel insulation layer pattern 118, the fourth floating gate 128, the fourth dielectric layer pattern 138 and the fourth preliminary control gate 148, and a top surface of the substrate 100 adjacent to the fourth preliminary gate structure 168. In an example embodiment, the fourth insulation layer pattern 176 may be formed to have a top surface higher than that of the fourth preliminary control gate 148.

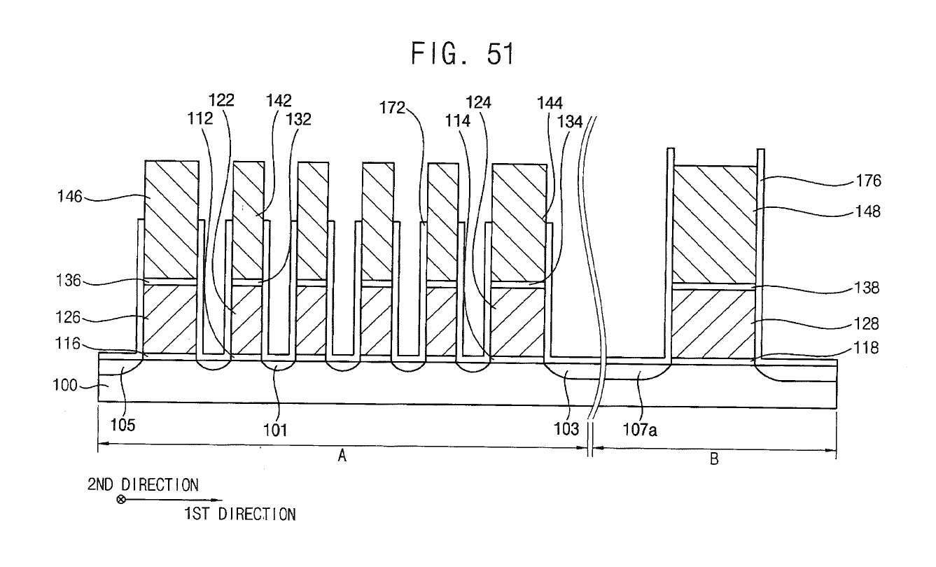

Referring to FIG. 51, the second mask 404 and the first and second sacrificial layer patterns 182 and 184 may be removed. In example embodiments, the second mask 404 and the first and second sacrificial layer patterns 182 and 184 may be removed by an ashing process and/or a stripping process.

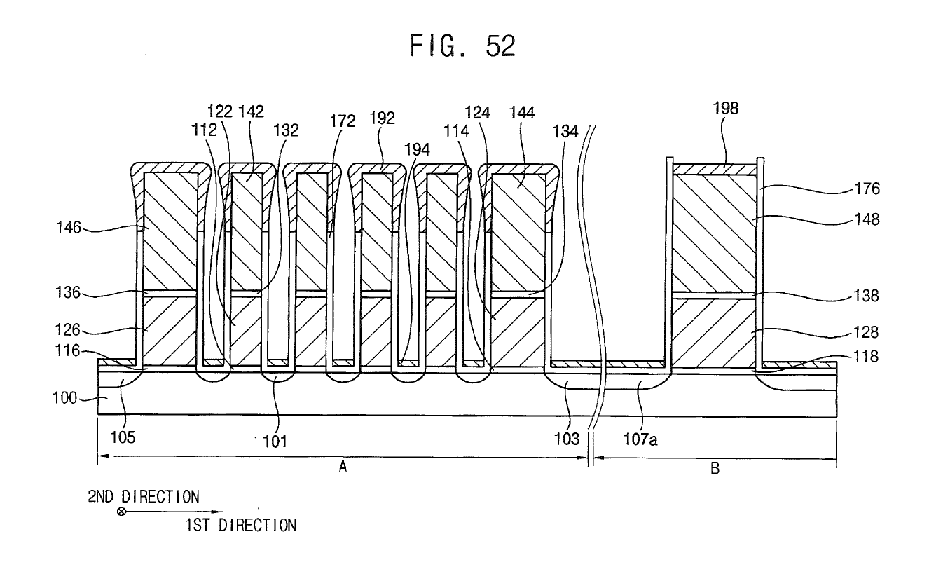

Referring to FIG. 52, the first conductive layer 192 may be formed on the exposed portions of the first through third preliminary control gates 142, 144 and 146, and a fourth conductive layer 198 may be formed on the exposed portion of the fourth preliminary control gate 148.

In example embodiments, the first and fourth conductive layers 192 and 198 may be formed using a metal, such as cobalt, nickel, etc. by a PVD process. The first and fourth conductive layers 192 and 198 may be formed on the exposed portions of the preliminary control gates 142, 144, 146 and 148, and a third conductive layer 194 may be further formed on portions of the first and fourth insulation layer patterns 172 and 176 on the substrate 100. Particularly, the first conductive layer 192 may be formed on top surfaces and portions of the sidewalls of the first through third preliminary control gates 142, 144 and 146, and the fourth conductive layer 198 may be formed on a top surface of the fourth preliminary control gate 148.

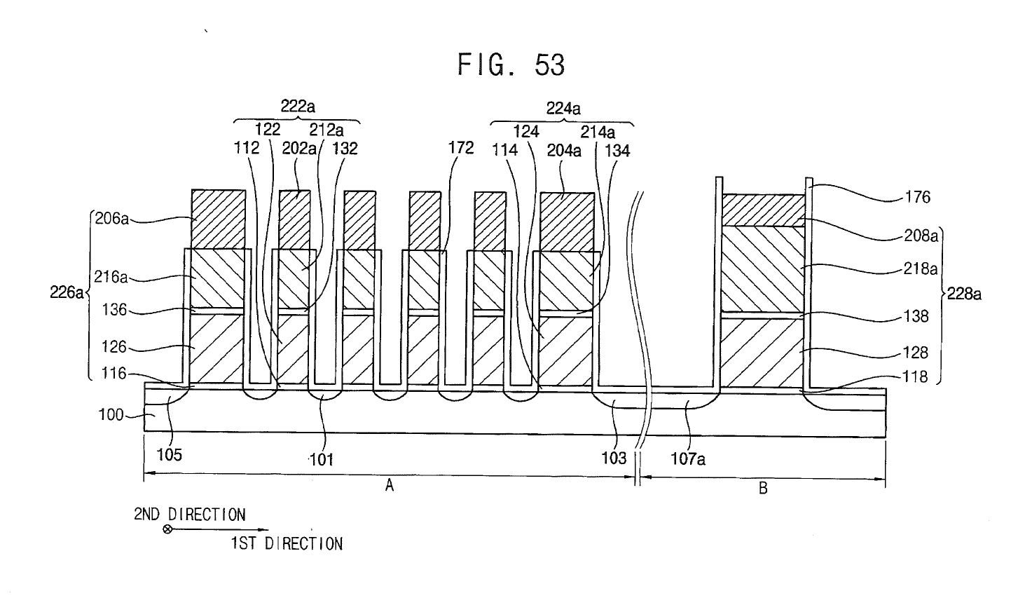

Referring to FIG. 53, the exposed portions of the preliminary control gates 142, 144, 146 and 148 may be reacted with the first and fourth conductive layers 192 and 198 to form first, second, third and fourth upper conductive patterns 202a, 204a, 206a and 208a, respectively. The fourth conductive layer 198 may be formed only on the top surface of the fourth preliminary control gate 148, and thus the fourth upper conductive pattern 208a may have a relatively small thickness when compared to those of the first through third upper conductive patterns 202a, 204a and 206a.

Portions of the first and fourth conductive layers 192 and 198 that are not reacted with the preliminary control gates 142, 144, 146 and 148 and the third conductive layer 194 may be removed.

Thus, first, second, third and fourth gate structures 222a, 224a, 226a and 228a may be formed on the substrate 100. The first through fourth gate structures 222a, 224a, 226a and 228a may include the first through fourth tunnel insulation layer patterns 112, 114, 116 and 118, the first through fourth floating gates 122, 124, 126 and 128, the first through fourth dielectric layer patterns 132, 134, 136 and 138, the first through fourth lower conductive patterns 212a, 214a, 216a and 218a, and the first through fourth upper conductive patterns 202a, 204a, 206a and 208a, respectively.

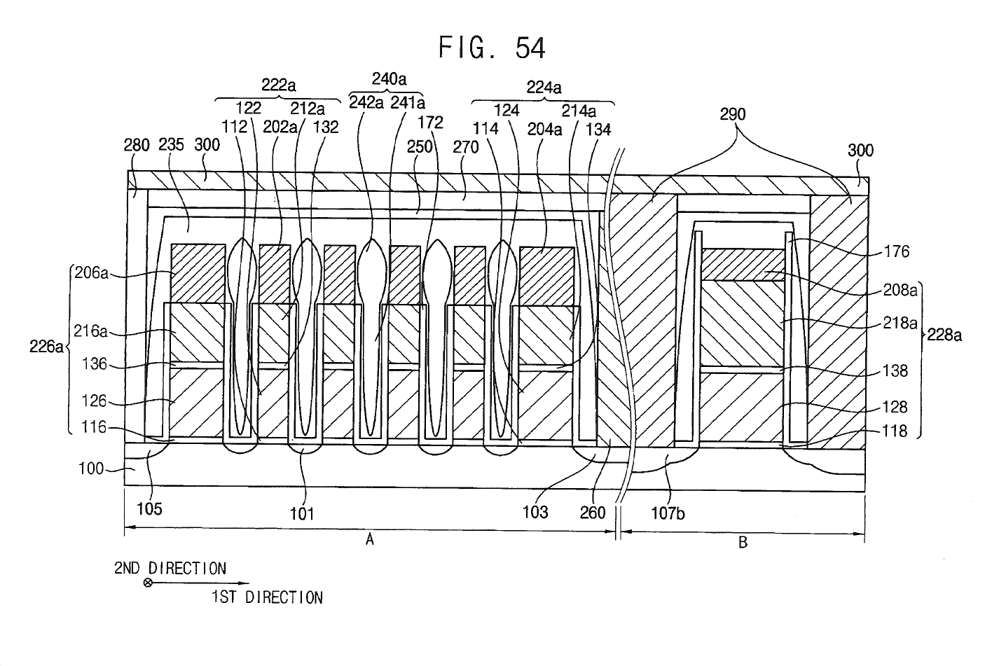

Referring to FIG. 54, the process illustrated with reference to FIGS. 34 to 36 may be performed to manufacture the semiconductor device.

In the method of manufacturing the semiconductor device, unlike the method illustrated with reference to FIGS. 25 to 48, the second mask 404 not overlapping the fourth preliminary gate structure 168 may be formed, the fourth gate mask 158 may be completely removed, and the fourth insulation layer pattern 176 may not be formed on the top surface of the fourth gate structure 228a. Thus, the fourth upper conductive pattern 208a may be formed to have a relatively large volume, so that the fourth gate structure 228a may have a relatively small resistance.

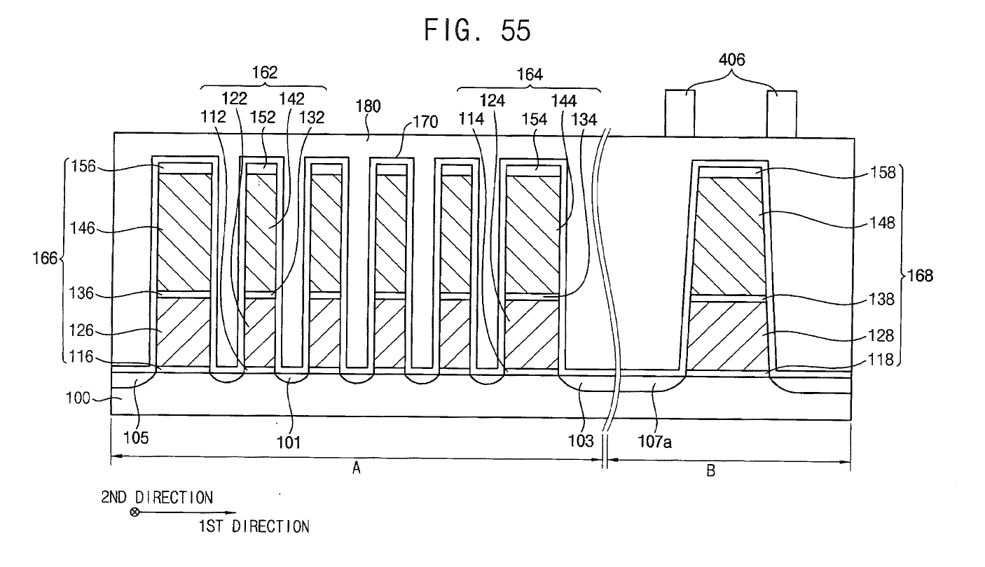

FIGS. 55 to 59 are cross-sectional views illustrating a method of manufacturing a semiconductor device in accordance with still other example embodiments. The method of manufacturing the semiconductor device may be substantially the same as or similar to that illustrated with reference to FIGS. 25 to 48 except for a mask and an insulation layer pattern. Thus, like reference numerals refer to like elements, and only the difference is illustrated hereinafter.

First, processes substantially the same as or similar to those illustrated with reference to FIGS. 25 to 28 may be performed. However, the fourth preliminary gate structure 168 may be formed to be not perpendicular but slanted with respect to a top surface of the substrate 100.

Referring to FIG. 55, a third mask 406 that may not overlap the fourth preliminary gate structure 168 may be formed on the sacrificial layer 180. In example embodiments, the third mask 404 may include two mask patterns each of which may not overlap the fourth preliminary gate structure 168 but partially overlap a portion of the first insulation layer 170 on the sidewall of the fourth preliminary gate structure 168, and extends in the second direction.

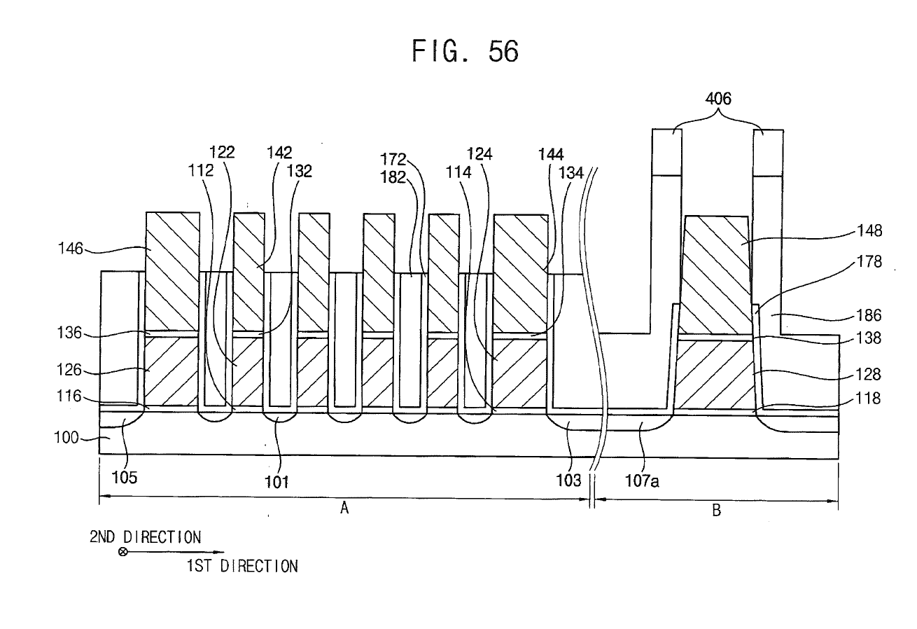

Referring to FIG. 56, upper portions of the sacrificial layer 180 and the first insulation layer 170 and the gate masks 152, 154, 156 and 158 may be removed using the third mask 406 as an etching mask. Thus, upper portions of the first through fourth preliminary control gates 142, 144, 146 and 148 may be exposed.

Particularly, in the second region B, an upper portion of the sacrificial layer 180 not covered by the third mask 406, and a portion of the first insulation layer 170 on a top surface and a sidewall of the fourth preliminary control gate 148 not covered by the third mask 406 may be removed to form a third sacrificial layer pattern 186 and a fifth insulation layer pattern 178, respectively, and the fourth gate mask 158 may be also removed. Thus, the fifth insulation layer pattern 178 may be formed to cover sidewalls of the fourth tunnel insulation layer pattern 118, the fourth floating gate 128 and the fourth dielectric layer pattern 138, and a portion of a sidewall of the fourth preliminary control gate 148. The fifth insulation layer pattern 178 may have a top surface different from that of the first insulation layer pattern 172 in the first region A. In an example embodiment, the fifth insulation layer pattern 178 may have a top surface lower than that of the first insulation layer pattern 172.

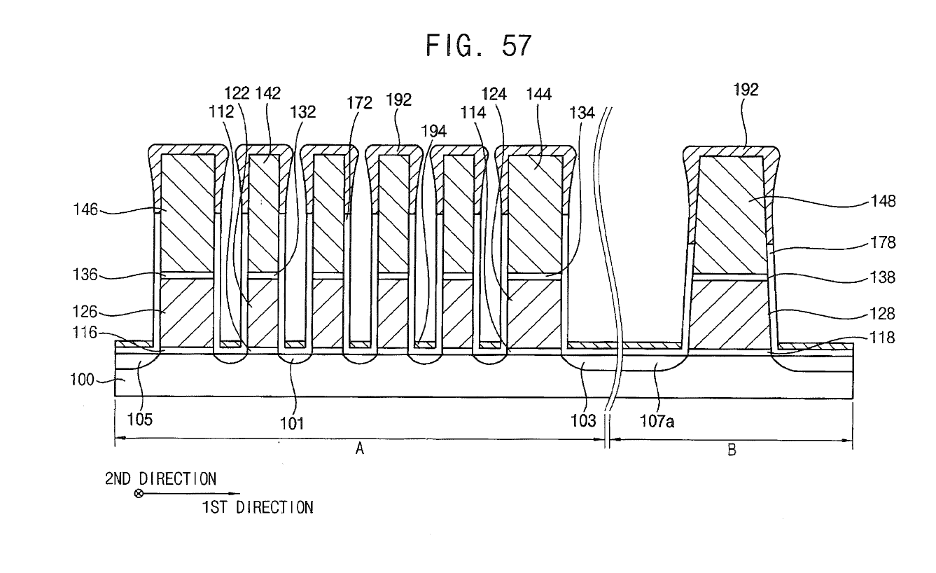

Referring to FIG. 57, the first and third sacrificial layer patterns 182 and 186 may be removed, and the first conductive layer 192 may be formed on the exposed portions of the first through fourth preliminary control gates 142, 144, 146 and 148.

The first conductive layer 192 may be formed on top surfaces and portions of sidewalls of the first through fourth preliminary control gates 142, 144, 146 and 148, and the third conductive layer 194 may be further formed on the first and fifth insulation layer patterns 172 and 178. In an example embodiment, the first conductive layer 192 may be formed to cover the sidewall of the fourth preliminary control gate 148 more than those of the first through third preliminary control gates 142, 144 and 146.

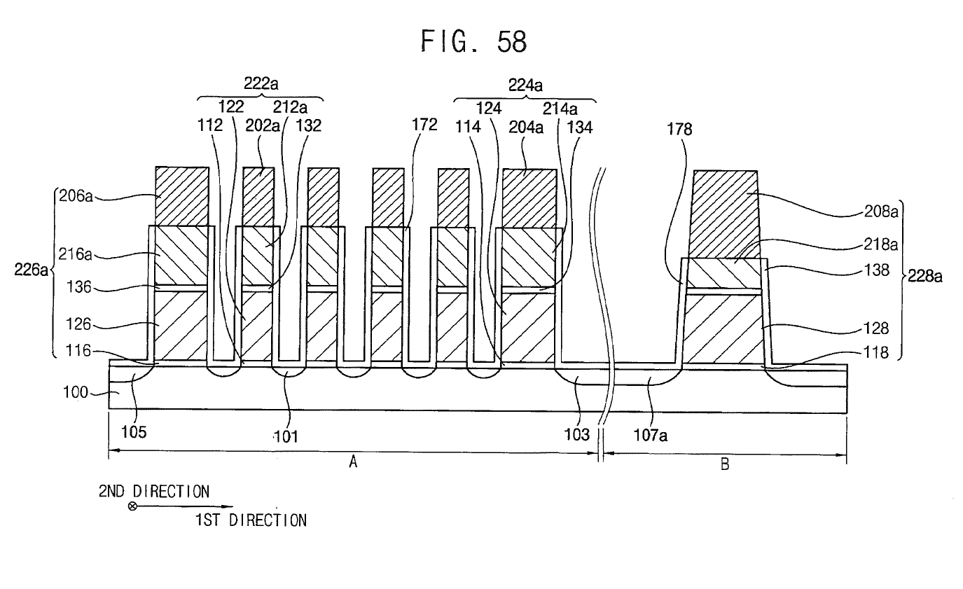

Referring to FIG. 58, the exposed portions of the preliminary control gates 142, 144, 146 and 148 may be reacted with the first conductive layer 192 to form first, second, third and fourth upper conductive patterns 202a, 204a, 206a and 208a, respectively. In an example embodiment, the fourth upper conductive pattern 208a may be formed to have a thickness larger than those of the first through third upper conductive patterns 202a, 204a and 206a.

A portion of the first conductive layer 192 that is not reacted with the preliminary control gates 142, 144, 146 and 148 and the third conductive layer 194 may be removed.

Thus, first, second, third and fourth gate structures 222a, 224a, 226a and 228a may be formed on the substrate 100. The first through fourth gate structures 222a, 224a, 226a and 228a may include the first through fourth tunnel insulation layer patterns 112, 114, 116 and 118, the first through fourth floating gates 122, 124, 126 and 128, the first through fourth dielectric layer patterns 132, 134, 136 and 138, the first through fourth lower conductive patterns 212a, 214a, 216a and 218a, and the first through fourth upper conductive patterns 202a, 204a, 206a and 208a, respectively.

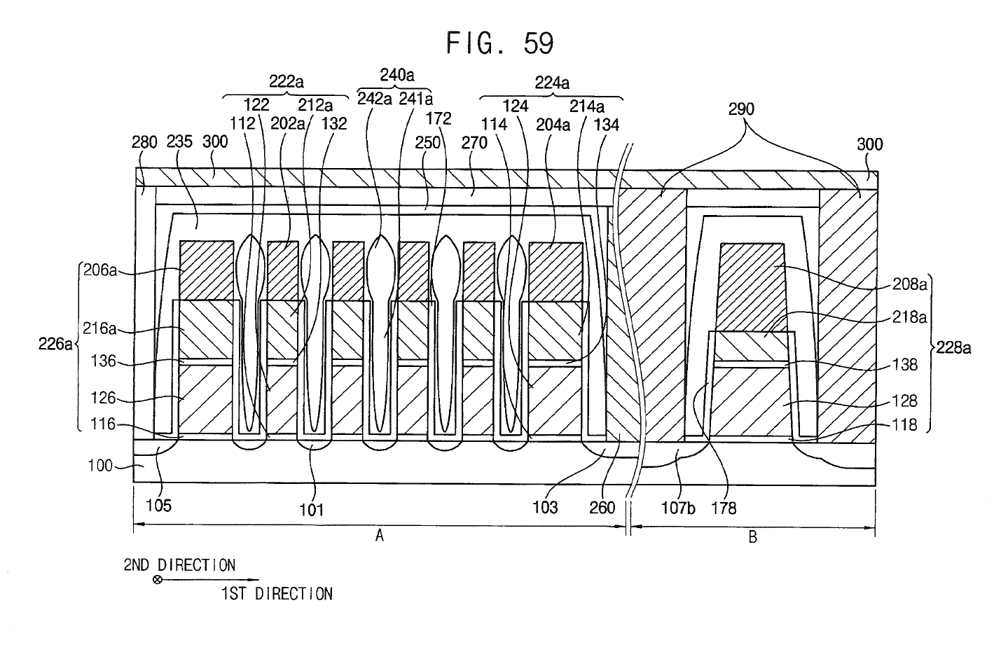

Referring to FIG. 59, the process illustrated with reference to FIGS. 34 to 36 may be performed to manufacture the semiconductor device.

In the method of manufacturing the semiconductor device, unlike the method illustrated with reference to FIGS. 25 to 48, the third mask 406 not overlapping the fourth preliminary gate structure 168 may be formed, the fourth gate mask 158 may be completely removed, and the fifth insulation layer pattern 178 may not be formed on the top surface of the fourth gate structure 228a. Additionally, unlike the method illustrated with reference to FIGS. 25 to 30, the fourth preliminary gate structure 168 may be slanted to the top surface of the substrate 100, and thus the third mask 406 may overlap only a portion of the first insulation layer 170 on the sidewall of the fourth preliminary gate structure 168. As a result, the fifth insulation layer pattern 178 may not cover the sidewall of the fourth preliminary control gate 148 completely, and thus the fourth upper conductive pattern 208a may have a larger thickness.

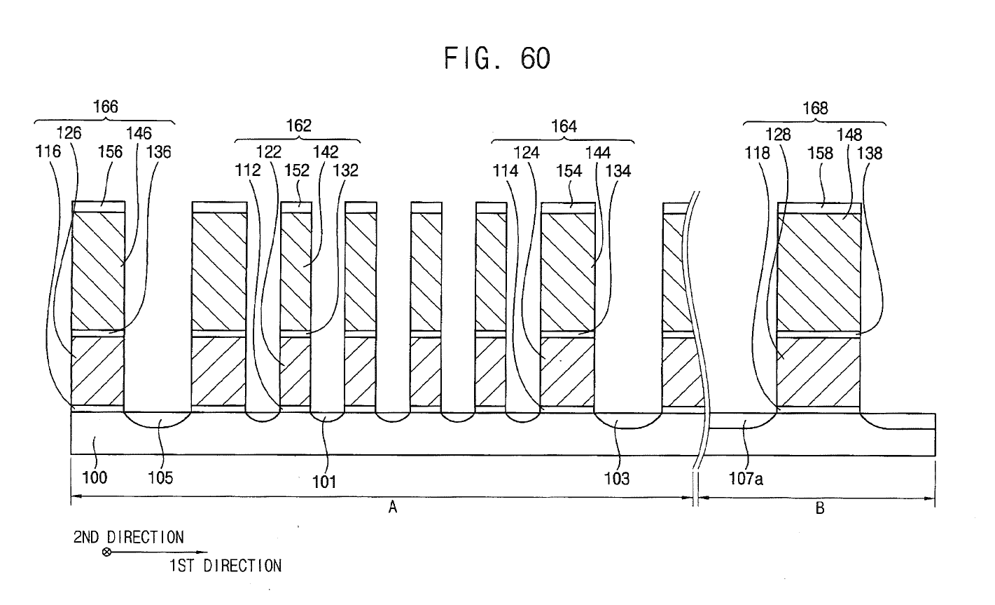

FIGS. 60 to 64 are cross-sectional views illustrating a method of manufacturing a semiconductor device in accordance with still other example embodiments. The method of manufacturing the semiconductor device may be substantially the same as or similar to that illustrated with reference to FIGS. 25 to 48 except that additional masks may be formed. Thus, like reference numerals refer to like elements, and only the difference is illustrated hereinafter.

Referring to FIG. 60, a plurality of strings each of which may include first through third preliminary gate structures 162, 164 and 166 may be formed in the first region A. In example embodiments, a plurality of first preliminary gate structures 162 may be formed between the second and third preliminary gate structures 164 and 166 in each string. The distance between the strings may be larger than those between the preliminary gate structures 162, 164 and 166 in each string.

A fourth preliminary gate structure 168 may be formed in the second region B. In example embodiments, a plurality of fourth preliminary gate structures 168 may be formed in the second region B. The distance between the fourth preliminary gate structures 168 may be larger than those between the first through third preliminary gate structures 162, 164 and 166.

Processes substantially the same as or similar to those illustrated with reference to FIGS. 27 to 28 may be performed.

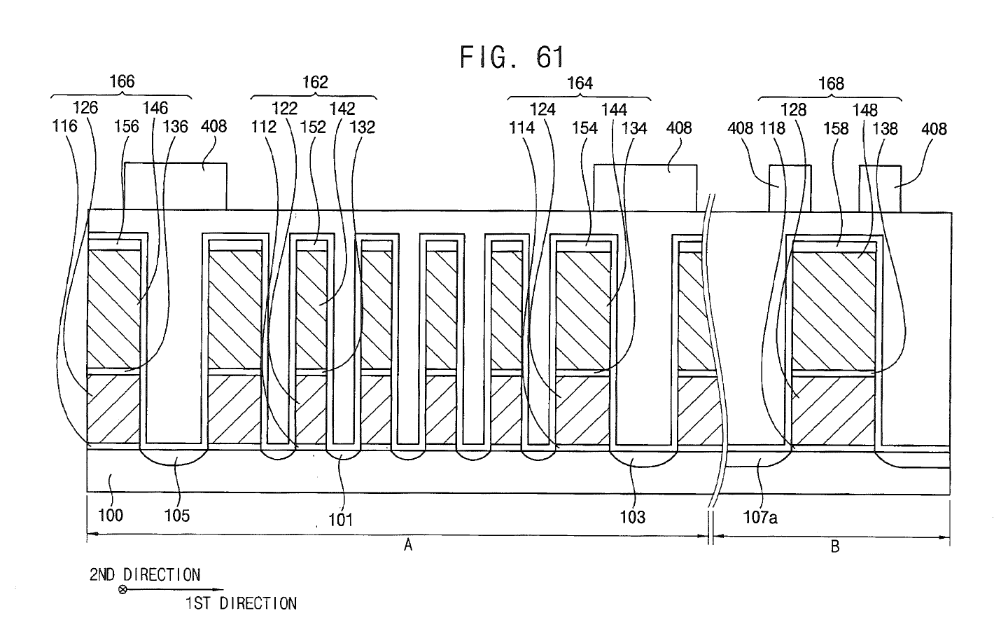

Referring to FIG. 61, a fourth mask 408 partially overlapping the second through fourth preliminary gate structures 164, 166 and 168 may be formed on the sacrificial layer 180. In example embodiments, the fourth mask 408 may include mask patterns each of which may overlap lateral portions of the second through fourth preliminary gate structures 164, 166 and 168 and portions of the first insulation layer 170 on sidewalls of the second through fourth preliminary gate structures 164, 166 and 168, and extend in the second direction. In an example embodiment, the fourth mask 408 may include a mask pattern overlapping both of the lateral portions of adjacent second and third preliminary gate structures 164 and 166.

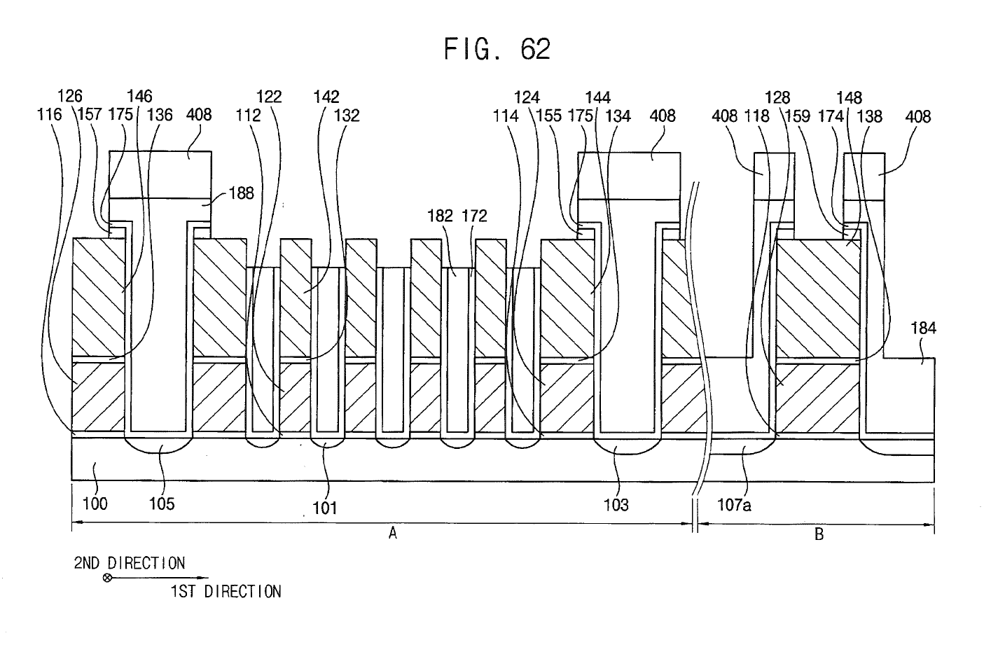

Referring to FIG. 62, upper portions of the sacrificial layer 180 and the first insulation layer 170 may be removed using the fourth mask 408 as an etching mask.

Thus, a first sacrificial layer pattern 182 and a first insulation layer pattern 172 may be formed in each string in the first region A, and a fourth sacrificial layer pattern 188 and a fifth sacrificial layer pattern 175 may be formed between the strings. Additionally, the second and third gate masks 154 and 156 may be partially removed to form second and third gate mask patterns 155 and 157, respectively. Thus, an upper portion of the first preliminary gate structure 162 and a top surface and a sidewall of each of the second and third preliminary gate structures 164 and 166 may be exposed.

The second and third gate mask patterns 155 and 157 may be formed on edge top surfaces of the second and third preliminary control gates 144 and 146, respectively, and the fifth insulation layer pattern 175 may be formed to cover sidewalls of the second and third tunnel insulation layer patterns 114 and 116, the second and third floating gates 124 and 126, the second and third dielectric layer patterns 134 and 136, and the second and third preliminary control gates 144 and 146, on top surfaces and portions of the sidewalls of the second and third gate mask patterns 155 and 157, and on a top surface of the substrate 100 between the strings.

Upper portions of the sacrificial layer 180 and the first insulation layer 170 in the second region B may be also removed to form a second sacrificial layer pattern 184 and a second insulation layer pattern 174, respectively, and the fourth gate mask 158 may be partially removed to form a fourth gate mask pattern 159. Thus, a top surface of the fourth preliminary control gate 148 may be exposed.

The fourth gate mask pattern 159 may be formed on an edge top surface of the fourth preliminary control gate 148, and the second insulation layer pattern 174 may be formed to cover sidewalls of the fourth tunnel insulation layer pattern 118, the fourth floating gate 128, the fourth dielectric layer pattern 138 and the fourth preliminary control gate 148, a top surface and a portion of a sidewall of the fourth gate mask pattern 159, and a top surface of the substrate 100 adjacent to the fourth preliminary gate structure 168.

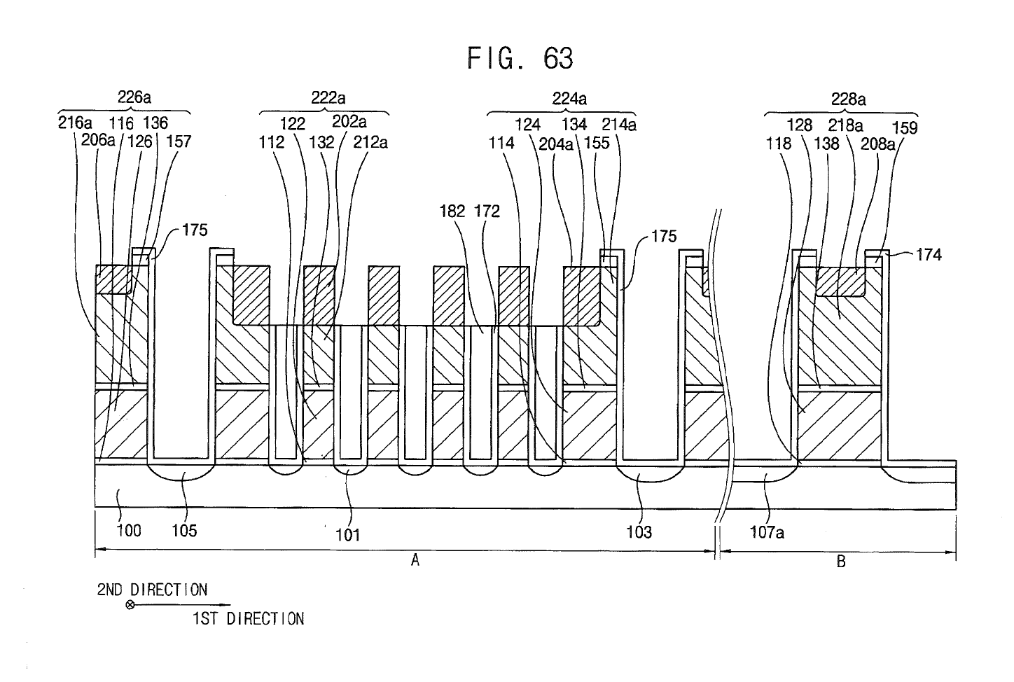

Referring to FIG. 63, processes substantially the same as or similar to those illustrated with reference to FIGS. 31 to 33 may be performed.

Thus, first through third upper conductive patterns 202a, 204a and 206a may be formed in the first region A, and a fourth upper conductive pattern 208a may be formed in the second region B.

Unlike the fourth conductive pattern 208a, only one lateral portion of each of the second and third upper conductive patterns 202a and 204a may be exposed.

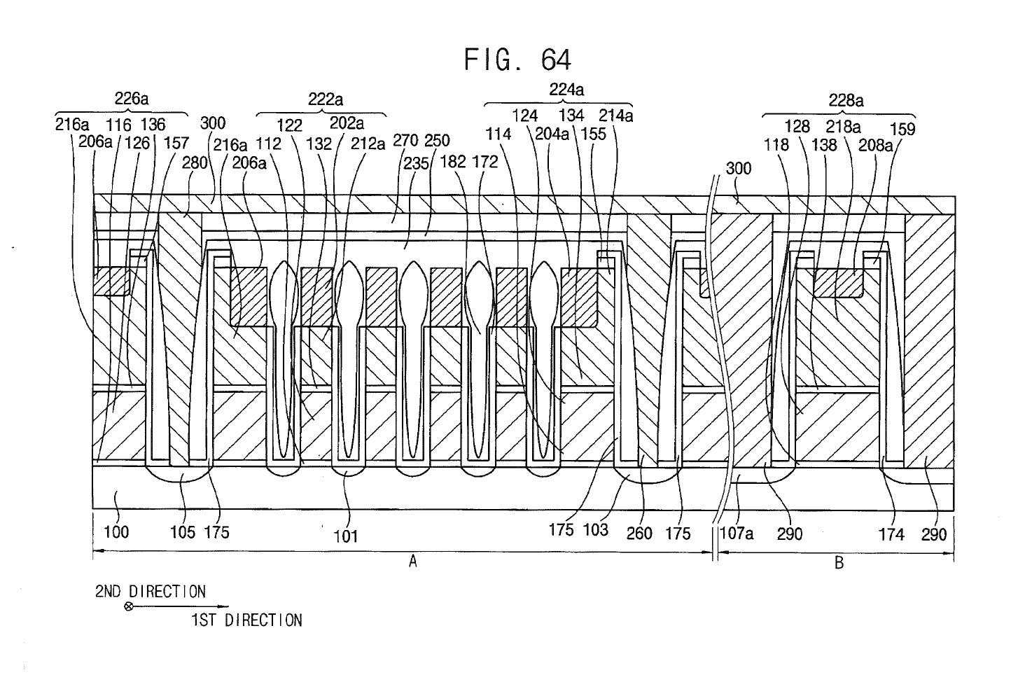

Referring to FIGS. 64, the process illustrated with reference to FIGS. 34 to 36 may be performed to manufacture the semiconductor device.

In the method of manufacturing the semiconductor device, unlike the method illustrated with reference to FIGS. 25 to 48, the fourth mask 408 partially overlapping not only the fourth preliminary gate structure 168 in the second region B but also the second and third preliminary gate structures 164 and 166 outside the strings in the first region A may be formed and serve as an etching mask. Thus, the first insulation layer 170 may not be removed excessively due to the relatively large distance between the strings in the etching process, so that the semiconductor device may not be short.

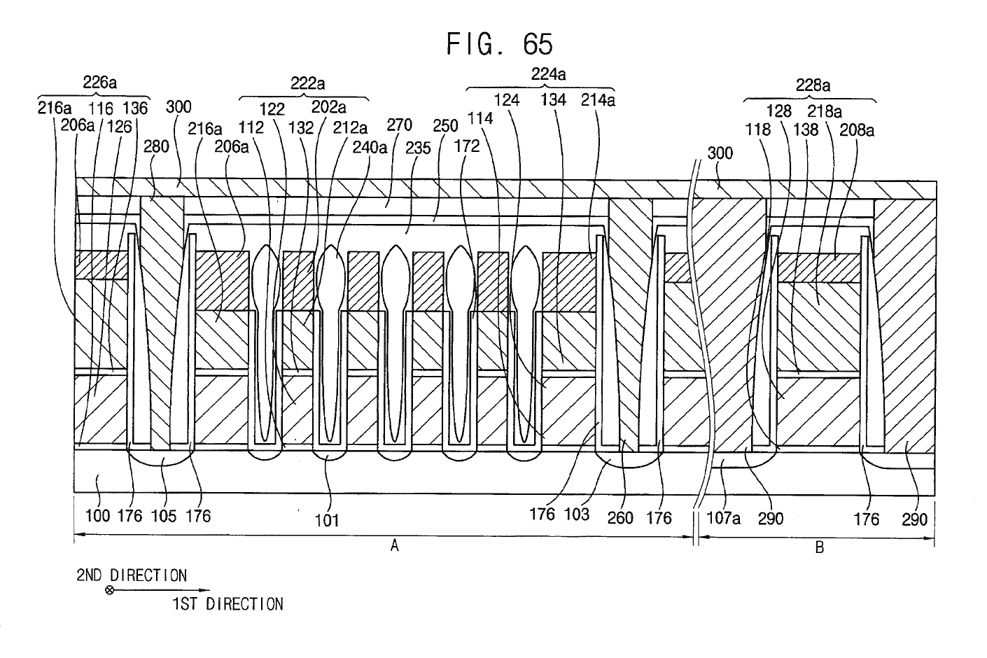

FIG. 65 is a cross-sectional view illustrating a method of manufacturing a semiconductor device in accordance with still other example embodiments. The method of manufacturing the semiconductor device may be substantially the same as or similar to that illustrated with reference to FIGS. 60 to 64 except for a mask and an insulation layer pattern. The process for forming the mask and the insulation layer pattern may be substantially the same as or similar to those illustrated with reference to FIGS. 49 to 54.

Referring to FIG. 65, a first insulation layer pattern 172 may be formed on portions of sidewalls of the first gate structures 222a, a portion of a first sidewall of each of the second and third gate structures 224a and 226a, and a top surface of the substrate 100 between the first through third gate structures 222a, 224a and 226a. A fourth insulation layer pattern 176 may be formed on a portion of a second sidewall of each of the second and third gate structures 224a and 226a, a top surface of the substrate 100 adjacent to the second and third gate structures 224a and 226a, sidewalls of the fourth gate structure 228a, and a top surface of the substrate 100 adjacent to the fourth gate structure 228a.

Thus, unlike the fourth upper conductive pattern 208a, a lateral portion of each of the second and third upper conductive patterns 202a and 204a may be exposed, thereby having a thickness larger than that of the fourth upper conductive pattern 208a.

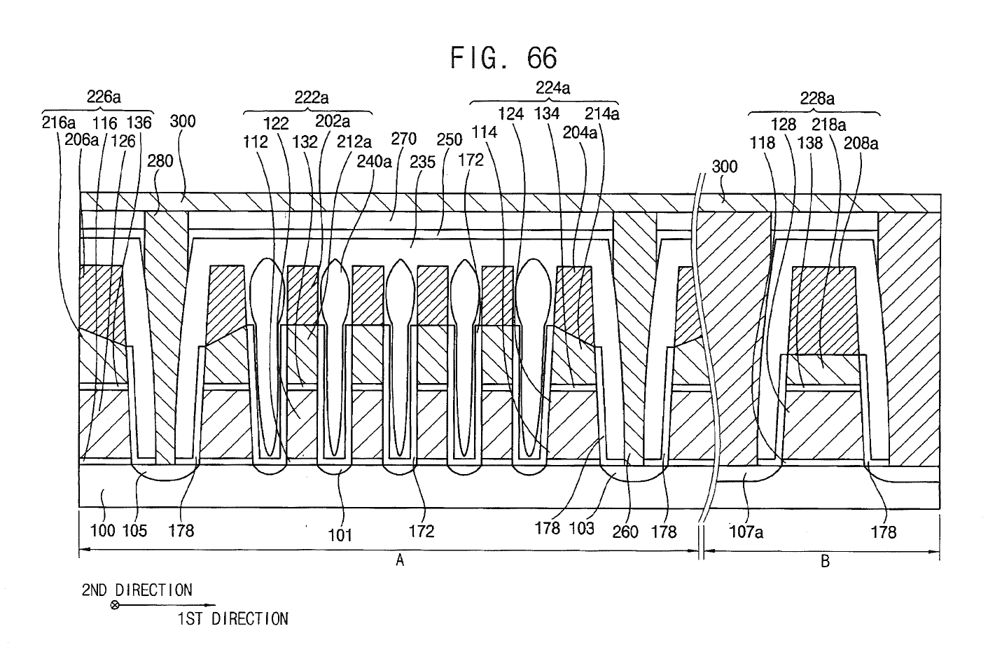

FIG. 66 is a cross-sectional view illustrating a method of manufacturing a semiconductor device in accordance with still other example embodiments. The method of manufacturing the semiconductor device may be substantially the same as or similar to that illustrated with reference to FIGS. 60 to 64 except for a mask and an insulation layer pattern. The process for forming the mask and the insulation layer pattern may be substantially the same as or similar to those illustrated with reference to FIGS. 55 to 59.

Referring to FIG. 66, second through fourth gate structures 222a, 224a, 226a and 228a may not be perpendicular but slanted with respect to a top surface of the substrate 100.

A first insulation layer pattern 172 may be formed on portions of sidewalls of the first through fourth gate structures 222a, 224a, 226a and 228a, and a top surface of the substrate 100 adjacent to the first through fourth gate structures 222a, 224a, 226a and 228a. However, a fourth portion of the first insulation layer pattern 172 on a sidewall of the fourth gate structure 228a may have a top surface different from, e.g., lower than, that of a first portion of the first insulation layer pattern 172 on a sidewall of the first gate structure 222a. A second portion of the first insulation layer pattern 172 on a first sidewall of each of the second and third gate structures 224a and 226a may have a top surface substantially coplanar with that of the first insulation layer pattern 172 on the sidewall of the first gate structure 222a. A third portion of the first insulation layer pattern 172 on a second sidewall of each of the second and third gate structures 224a and 226a may have a top surface substantially coplanar with that of the first insulation layer pattern 172 on the sidewall of the fourth gate structure 228a.

Thus, the fourth upper conductive pattern 208a may have a thickness larger than that of the first upper conductive pattern 202a, and the second and third upper conductive patterns 204a and 206a may have a bottom surface that is not parallel but slanted to the top surface of the substrate 100.

According to example embodiments, a reaction prevention layer may be formed on portions of sidewalls of gate structures spaced apart from each other, and a conductive layer may be formed on portions of the gate structures that are not covered by the reaction prevention layer. The gate structures may be reacted with the conductive layer by a heat treatment to form control gates having low resistance. An insulation layer having air gaps therein may be formed between the gate structures by a process having low step coverage, so that the parasitic capacitance may be reduced. The air gaps may be uniformly formed to have a top surface higher than those of the gate structures.

Particularly, in a manufacturing process for forming a semiconductor device including gate structures non-uniformly arranged, a mask may be formed on a sacrificial layer before removing the sacrificial layer and a reaction prevention layer on sidewalls of the gate structures, and thus the sacrificial layer and the reaction prevention layer may be prevented from over-etched due to the loading effect in a region in which the gate structures are arranged at a low density. Thus, a control gate and a floating gate, or the control gate and source/drain regions may not be electrically connected to each other via a metal silicide layer formed on the gate structures by a silicidation process.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A semiconductor device comprising:
a substrate having an active region and a field region, each of the active region and the field region extending in a first direction, and the active region and the field region being alternately and repeatedly arranged in a second direction substantially perpendicular to the first direction;
a plurality of gate structures spaced apart from each other in the first direction, each of the gate structures extending in the second direction;
a first insulation layer pattern on a portion of a sidewall of each gate structure; and
a second insulation layer pattern covering the gate structures and the first insulation layer pattern and having an air tunnel between the gate structures, the air tunnel extending in the second direction.

2. The semiconductor device of claim 1, wherein the air tunnel has a top surface higher than top surfaces of the gate structures.

3. The semiconductor device of claim 1, wherein the first insulation layer pattern is formed on a top surface of the substrate between the gate structures.

4. The semiconductor device of claim 1,
wherein each gate structure includes a tunnel insulation layer pattern, a floating gate, a dielectric layer pattern and a control gate sequentially stacked on the substrate,
wherein the tunnel insulation layer patterns have an island shape from each other in the active region, and the floating gates also have an island shape from each other in the active region,
and wherein each of the dielectric layer patterns and the control gates extends in the second direction and is formed on the floating gates and the field region.

5. The semiconductor device of claim 4, wherein the control gates include polysilicon, and wherein the first insulation layer pattern covers at least a sidewall of the tunnel insulation layer pattern, a sidewall of the floating gate and a sidewall of the dielectric layer pattern.

6. The semiconductor device of claim 5, wherein each control gate includes a lower conductive pattern and an upper conductive pattern sequentially stacked on the dielectric layer pattern, and wherein the lower and upper conductive patterns include polysilicon and a metal silicide, respectively.

7. The semiconductor device of claim 6, wherein the upper conductive pattern has a bottom surface substantially coplanar with a top surface of the first insulation layer pattern.

8. The semiconductor device of claim 7, wherein the upper conductive pattern includes cobalt.

9. The semiconductor device of claim 6, wherein the upper conductive pattern has a bottom surface lower than a top surface of the first insulation layer pattern.

10. The semiconductor device of claim 9, wherein the upper conductive pattern includes nickel.

11. The semiconductor device of claim 1,
wherein each gate structure includes a first tunnel insulation layer pattern, a floating gate, a dielectric layer pattern and a control gate sequentially stacked on the substrate,
wherein the first tunnel insulation layer patterns have an island shape from each other in the active region, and the floating gates have an island shape from each other in the active region,
and wherein each of the dielectric layer patterns and the control gates extends in the second direction and is formed on the floating gates and the field region,
further comprising a second tunnel insulation layer pattern on a portion of the active region that is not covered by the gate structures, the second tunnel insulation layer pattern being covered by the second insulation layer pattern and connected to the first tunnel insulation layer pattern.

12. The semiconductor device of claim 11, wherein the first and second tunnel insulation layer patterns include substantially the same material, and wherein the first tunnel insulation layer pattern has a thickness greater than that of the second tunnel insulation layer pattern.

13. The semiconductor device of claim 1, wherein each gate structure includes a tunnel insulation layer pattern, a charge trapping layer pattern, a blocking layer pattern and a gate electrode sequentially stacked on the substrate, and the gate electrodes include polysilicon,
and wherein the first insulation layer pattern covers at least a sidewall of the tunnel insulation layer pattern, a sidewall of the charge trapping layer pattern and a sidewall of the blocking layer pattern.

14. The semiconductor device of claim 1, wherein the air tunnel is defined only by the second insulation layer pattern.

15. The semiconductor device of claim 1, wherein the second insulation layer pattern partially covers the first insulation layer pattern, and the air tunnel is defined by both of the first and second insulation layer patterns.

16. A semiconductor device comprising:
a plurality of gate structures spaced apart from each other on a substrate;
a first insulation layer pattern on a portion of a sidewall of each gate structure; and
a second insulation layer pattern covering the gate structures and the first insulation layer pattern and having an air gap between the gate structures,
wherein the air gap includes a lower portion and an upper portion, the lower portion having a first width and being adjacent to the first insulation layer pattern, and the upper portion having a second width greater than the first width and being adjacent to a portion of the sidewall of each gate structure that is not covered by the first insulation layer pattern.

17. The semiconductor device of claim 16, wherein the lower portion of the air gap has a linear shape, and the upper portion of the air gap has an oval shape of which a top surface is sharp.

18. The semiconductor device of claim 16, wherein the air gap has a top surface higher than top surfaces of the gate structures.

19. The semiconductor device of claim 16, wherein the first insulation layer pattern is further formed on a portion of the substrate between the gate structures.

20. The semiconductor device of claim 16,
wherein each gate structure includes a tunnel insulation layer pattern, a floating gate, a dielectric layer pattern and a control gate sequentially stacked on the substrate, the control gate including polysilicon,
and wherein the first insulation layer pattern covers at least a sidewall of the tunnel insulation layer pattern, a sidewall of the floating gate and a sidewall of the dielectric layer pattern.

21. The semiconductor device of claim 20, wherein each control gate includes a lower conductive pattern and an upper conductive pattern sequentially stacked on the dielectric layer pattern, and wherein the lower and upper conductive patterns include polysilicon and a metal silicide, respectively.

22. The semiconductor device of claim 21, wherein the upper conductive pattern has a bottom surface substantially coplanar with a top surface of the first insulation layer pattern, and the upper conductive pattern includes cobalt.

23. The semiconductor device of claim 21, wherein the upper conductive pattern has a bottom surface lower than a top surface of the first insulation layer pattern, and the upper conductive pattern includes nickel.

24. The semiconductor device of claim 16,
wherein each gate structure includes a first tunnel insulation layer pattern, a floating gate, a dielectric layer pattern and a control gate sequentially stacked on the substrate,
further comprising a second tunnel insulation layer pattern on a portion of the substrate that is not covered by the gate structures, the second tunnel insulation layer pattern being covered by the second insulation layer pattern and having a thickness less than that of the first tunnel insulation layer pattern.

25. The semiconductor device of claim 16, wherein the air gap is defined only by the second insulation layer pattern.

26. The semiconductor device of claim 16, wherein the second insulation layer pattern partially covers the first insulation layer pattern, and the air tunnel is defined by both of the first and second insulation layer patterns.

27. A semiconductor device comprising:
a plurality of first gate structures spaced apart from each other on a substrate in a first direction at a first distance therebetween;
a second gate structure spaced apart from a first outermost of the first gate structures in the first direction at a second distance;
a third gate structure spaced apart from a second outermost of the first gate structures in a second direction opposite to the first direction at a third distance;
a first insulation layer pattern on a portion of each of the first, second and third gate structures; and
a second insulation layer pattern covering the first, second and third gate structures and the first insulation layer pattern and having a second air gap between the first outermost of the first gate structures and the second gate structure or between the second outermost of the first gate structures and the third gate structures.

28. The semiconductor device of claim 27, wherein the second and third distances are greater than the first distance, and wherein the first air gap has a width equal to or larger than that of the second air gap.

29. The semiconductor device of claim 28, wherein the first air gap has a lower portion and an upper portion, the lower portion having a first width and being adjacent to the first insulation layer pattern, and the upper portion having a second width greater than the first width and being adjacent to portions of sidewalls of the first through third gate structures that are not covered by the first insulation layer pattern.

30. The semiconductor device of claim 29, wherein the lower portion of the first air gap has a linear shape, and the upper portion of the first air gap has an oval shape of which a top surface is sharp.

31. The semiconductor device of claim 28, wherein the second insulation layer pattern includes Middle temperature oxide (MTO).

32-40. (canceled)

41. A semiconductor device comprising:
a plurality of first gate structures in a first region on a substrate, each of the gate structures having an upper portion including a metal silicide;
a second gate structure in a second region on the substrate, the second gate structure having an upper portion including a metal silicide;
a first insulation layer pattern on a portion of a sidewall of each gate structure;
a second insulation layer pattern covering a sidewall of the second gate structure, the second insulation layer pattern having a top surface higher than a top surface of the first insulation layer pattern; and
a third insulation layer pattern covering the first and second gate structures and the first and second insulation layer patterns, the third insulation layer pattern having an air gap between the first gate structures.

42. The semiconductor device of claim 41, wherein the first and second insulation layer patterns are further formed on a portion of the substrate adjacent to the first and second gate structures.

43. The semiconductor device of claim 41, wherein the second insulation layer pattern further covers a portion of the second gate structure.

44. The semiconductor device of claim 43,
wherein each first gate structure includes a first tunnel insulation layer pattern, a first floating gate, a first dielectric layer pattern and a first control gate sequentially stacked on the substrate,
wherein the second gate structure includes a second tunnel insulation layer pattern, a second floating gate, a second dielectric layer pattern, a second control gate and a gate mask sequentially stacked on the substrate,
and wherein the gate mask is formed on a portion of the second control gate, and the second insulation layer pattern covers a top surface of the gate mask.

45. The semiconductor device of claim 44, wherein the first control gate includes a first lower conductive pattern and an upper conductive pattern sequentially stacked on the first dielectric layer pattern, the second control gate includes a second lower conductive pattern and an upper conductive pattern sequentially stacked on the second dielectric layer pattern,
and wherein the first and second conductive patterns include polysilicon, and the first and second upper conductive patterns include a metal silicide.

46. The semiconductor device of claim 45, wherein the second conductive pattern is not covered by the gate mask and the second insulation layer pattern.

47. The semiconductor device of claim 41, wherein the second insulation layer pattern has a top surface higher than a top surface of the second gate structure.

48. The semiconductor device of claim 41,
wherein each first gate structure includes a first tunnel insulation layer pattern, a first floating gate, a first dielectric layer pattern and a first control gate sequentially stacked on the substrate, and the second gate structure includes a second tunnel insulation layer pattern, a second floating gate, a second dielectric layer pattern and a second control gate sequentially stacked on the substrate,
wherein the first control gate includes a first lower conductive pattern and a second upper conductive pattern sequentially stacked on the first dielectric layer pattern, and the second control gate includes a second lower conductive pattern and a second upper conductive pattern sequentially stacked on the second dielectric layer pattern,
and wherein the first and second upper conductive patterns include the metal silicide and the second upper conductive pattern has a thickness less than that of the first conductive pattern.

49. The semiconductor device of claim 41, wherein the first region is a cell region and the second region is a peripheral circuit region.

50. A semiconductor device comprising:
a plurality of first gate structures in a first region on a substrate, each of the gate structures having an upper portion including a metal silicide;
a second gate structure in a second region on the substrate, the second gate structure having an upper portion including a metal silicide and having a sidewall slanted to a top surface of the substrate;
a first insulation layer pattern on a portion of a sidewall of each gate structure;
a second insulation layer pattern covering a portion of the sidewall of the second gate structure, the second insulation layer pattern having a top surface higher than a top surface of the first insulation layer pattern; and
a third insulation layer pattern covering the first and second gate structures and the first and second insulation layer patterns, the third insulation layer pattern having an air gap between the first gate structures.

51. The semiconductor device of claim 50, wherein the second insulation layer pattern has a top surface lower than the top surface of the first insulation layer pattern.

52. The semiconductor device of claim 50,
wherein each first gate structure includes a first tunnel insulation layer pattern, a first floating gate, a first dielectric layer pattern and a first control gate sequentially stacked on the substrate, and the second gate structure includes a second tunnel insulation layer pattern, a second floating gate, a second dielectric layer pattern and a second control gate sequentially stacked on the substrate,
and wherein the second insulation layer pattern has a top surface higher than a top surface of the second dielectric layer pattern.

53. A semiconductor device comprising:
a plurality of first gate structures, a second gate structure and a third gate structure on a substrate in a cell region , the first gate structures between the second and third gate structures, and each of the first through third gate structures having an upper portion including a metal silicide;
a fourth gate structure on the substrate in a peripheral circuit region, the fourth gate structure including the metal silicide;
a first insulation layer pattern covering a portion of a sidewall of each gate structure and a portion of a first sidewall of each of the second and third gate structures;
a second insulation layer pattern covering a second sidewall of each of the second and third gate structures, the second insulation layer pattern having a top surface higher than that of the first insulation layer pattern;
a third insulation layer pattern covering a sidewall of the fourth gate structure, the third insulation layer pattern having a top surface higher than a top surface of the first insulation layer pattern; and
a fourth insulation layer pattern covering the first through fourth gate structures and the first through third insulation layer patterns, the fourth insulation layer pattern having an air gap between the first through third gate structures.

54. The semiconductor device of claim 53, wherein the second and third insulation layer patterns have a top surface substantially coplanar with each other.

55. The semiconductor device of claim 53, wherein the second and third insulation layer patterns further cover top surfaces of the second and third gate structures, respectively, and the fourth insulation layer pattern further covers a portion of a top surface of the fourth gate structure.

56. The semiconductor device of claim 53, wherein the second through fourth insulation layer patterns have top surfaces higher than top surfaces of the fourth gate structure.

57-60. (canceled)
